(19) United States
(12) Patent Application Publication
(10) Pub. No.: US 2026/0333994 A1
(43) Pub. Date: Oct. 22, 2026

(54) Light-Emitting Device

(71) Applicant: Semiconductor Energy Laboratory Co., Ltd., Kanagawa-ken (JP)

(72) Inventors: Nobuharu OHSAWA, Zama, Kanagawa (JP); Hiromi SEO, Sagamihara, Kanagawa (JP); Shinya FUKUZAKI, Atsugi, Kanagawa (JP)

(73) Assignee: Semiconductor Energy Laboratory Co., Ltd., Kanagawa-ken (JP)

(21) Appl. No.: 19/476,441

(22) PCT Filed: Apr. 15, 2024
(86) PCT No.: PCT/IB2024/053654

§ 371 Date: Oct. 17, 2025

(30) Foreign Application Priority Data
Apr. 21, 2023 (JP) 2023-069854

(51) Int. Cl. H10K 50/11; H10K 50/19; H10K 85/60; H10K 101/30; H10K 101/40

(52) U.S. Cl. CPC H10K 50/11; H10K 50/19; H10K 85/6572; H10K 2101/30; H10K 2101/40

(57) ABSTRACT

A tandem light-emitting device that can be applied to a high-resolution display apparatus and has high emission efficiency and high reliability is provided. The light-emitting device provided includes a first electrode, a second electrode, and an organic compound layer positioned between the first electrode and the second electrode; the organic compound layer includes a first light-emitting unit, an intermediate layer, and a second light-emitting unit in this order from the first electrode side; the first light-emitting unit includes a first light-emitting layer; the second light-emitting unit includes a second light-emitting layer; the intermediate layer includes a first layer, a second layer, and a third layer that are in the state of being in contact with each other in this order from the first electrode side; the spin density of the first layer is lower than or equal to a certain range; and the absolute value of a difference between the LUMO level of a material included in the second layer and the HOMO level of a first substance is greater than or equal to 2.10 eV.

### TECHNICAL FIELD

One embodiment of the present invention relates to a light-emitting device.

Note that one embodiment of the present invention is not limited to the above technical field. Examples of the technical field of one embodiment of the present invention include a semiconductor device, a display apparatus, a light-emitting apparatus, a power storage device, a memory device, an electronic appliance, a lighting device, an input device (e.g., a touch sensor), an input/output device (e.g., a touch panel), driving methods thereof, and manufacturing methods thereof.

### BACKGROUND ART

Display apparatuses are being developed into a variety of applications these days. For example, a television device for home use (also referred to as TV or television receiver), digital signage, and a PID (Public Information Display) are being developed as large-sized display apparatuses, and a smartphone and a tablet terminal each provided with a touch panel are being developed as small-sized display apparatuses.

At the same time, display apparatuses are also required to achieve higher resolution. As devices requiring high-resolution display apparatuses, for example, devices for virtual reality (VR), augmented reality (AR), substitutional reality (SR), and mixed reality (MR) have been actively developed.

Development is actively conducted on light-emitting devices (also referred to as light-emitting elements) as display elements used in display apparatuses. Light-emitting devices (also referred to as EL devices or EL elements) utilizing electroluminescence (hereinafter referred to as EL) phenomenon, specifically, organic EL devices using mainly organic compounds have features such as ease of reduction in thickness and weight, high-speed response to input signals, and driving with a constant DC voltage power source, thereby being suitable for display apparatuses.

In order to obtain a higher-resolution light-emitting apparatus using an organic EL device, patterning an organic layer by a photolithography method using a photoresist or the like, instead of an evaporation method using a metal mask, has been studied. With the use of the photolithography method, a high-resolution display apparatus in which a distance between EL layers is several micrometers can be obtained (see Patent Document 1, for example).

### REFERENCES

### Patent Documents

[Patent Document 1] Japanese Translation of PCT International Application No. 2018-521459
[Patent Document 2] PCT International Publication No. 2021/045178

### SUMMARY OF THE INVENTION

### Problems to be Solved by the Invention

It has been known that exposure of an EL layer in an organic EL device to atmospheric components such as water and oxygen affects initial characteristics or reliability, and thus it has been common knowledge that the EL layer is treated in a near-vacuum atmosphere. In particular, an electron-injection layer or an intermediate layer of a tandem light-emitting device, which includes a material having a donor property typified by an alkali metal, an alkaline earth metal, or a compound thereof highly reactive with water or oxygen, rapidly deteriorates and loses the function as the intermediate layer when the surface of the EL layer is exposed to atmospheric air.

However, processing steps by the aforementioned photolithography method inevitably involve exposure of the surface of the EL layer to atmospheric air. Favorable characteristics have been hard to obtain from light-emitting devices manufactured through processing with a photolithography technique.

In view of the above, an object of one embodiment of the present invention is to provide a novel light-emitting device having a tandem structure. An object of another embodiment of the present invention is to provide a highly efficient light-emitting device having a tandem structure. Alternatively, an object of one embodiment of the present invention is to provide a highly reliable light-emitting device having a tandem structure. An object of another embodiment of the present invention is to provide a highly reliable and highly efficient light-emitting device having a tandem structure.

Alternatively, an object of one embodiment of the present invention is to provide a novel light-emitting device having a tandem structure fabricated through a photolithography process. An object of another embodiment of the present invention is to provide a highly efficient light-emitting device having a tandem structure fabricated through a photolithography process. Alternatively, an object of one embodiment of the present invention is to provide a highly reliable light-emitting device having a tandem structure fabricated through a photolithography process. An object of another embodiment of the present invention is to provide a high-emission-efficiency and high-reliability light-emitting device having a tandem structure fabricated through a photolithography process.

Alternatively, an object of one embodiment of the present invention is to provide a novel light-emitting device having a tandem structure that can be used in a high-resolution display apparatus. An object of another embodiment of the present invention is to provide a highly efficient light-emitting device having a tandem structure that can be used in a high-resolution display apparatus. Alternatively, an object of one embodiment of the present invention is to provide a highly reliable light-emitting device having a tandem structure that can be used in a high-resolution display apparatus. An object of another embodiment of the present invention is to provide a high-emission-efficiency and high-reliability light-emitting device having a tandem structure that can be used in a high-resolution display apparatus.

An object of another embodiment of the present invention is to provide a highly reliable display apparatus. An object of another embodiment of the present invention is to provide a high-resolution display apparatus. An object of another embodiment of the present invention is to provide a high-resolution and high-reliability display apparatus.

Other objects are to provide a novel organic compound, a novel light-emitting apparatus, a novel display apparatus, a novel display module, and a novel electronic appliance.

### Means for Solving the Problems

One embodiment of the present invention is a light-emitting device including a first electrode, a second electrode, and an organic compound layer positioned between the first electrode and the second electrode. The organic compound layer includes a first light-emitting unit, an intermediate layer, and a second light-emitting unit in this order from a first electrode side. The first light-emitting unit includes a first light-emitting layer. The second light-emitting unit includes a second light-emitting layer. The intermediate layer includes a first layer, a second layer, and a third layer that are in a state of being in contact with each other in this order from the first electrode side. The first layer includes a first substance. The spin density of the first layer is lower than or equal to 1×10¹⁷ spins/cm³. The absolute value of a difference between the LUMO level of a material included in the second layer and the HOMO level of the first substance is greater than or equal to 2.10 eV.

Another embodiment of the present invention is the light-emitting device having the above structure, in which the absolute value of a difference between the LUMO level of a material included in the second layer and the HOMO level of the first substance is greater than or equal to 2.50 eV.

Another embodiment of the present invention is the light-emitting device having the above structure, in which the absolute value of a difference between the LUMO level of a material included in the second layer and the HOMO level of the first substance is greater than 2.60 eV.

Another embodiment of the present invention is a light-emitting device including a first electrode, a second electrode, and an organic compound layer positioned between the first electrode and the second electrode. The organic compound layer includes a first light-emitting unit, an intermediate layer, and a second light-emitting unit in this order from a first electrode side. The first light-emitting unit includes a first light-emitting layer. The second light-emitting unit includes a second light-emitting layer. The intermediate layer includes a first layer, a second layer, and a third layer that are in a state of being in contact with each other in this order from the first electrode side. The first layer includes a first substance. The spin density of the first layer is lower than or equal to 1×10¹⁷ spins/cm³. The LUMO level of a material included in the second layer is higher than −3.00 eV.

Another embodiment of the present invention is the light-emitting device having the above-described structure, in which the LUMO level of the material included in the second layer is lower than or equal to −2.00 eV.

Another embodiment of the present invention is the light-emitting device having the above-described structure, in which the LUMO level of the material included in the second layer is lower than or equal to −2.60 eV.

Another embodiment of the present invention is the light-emitting device having the above-described structure, in which the thickness of the second layer is greater than or equal to 1 nm and less than or equal to 10 nm.

Another embodiment of the present invention is the light-emitting device having the above-described structure, in which the acid dissociation constant pKa of the first substance is higher than or equal to 8.

Another embodiment of the present invention is the light-emitting device having the above-described structure, in which the first substance is an organic compound including any one of a pyrrolidine skeleton, a piperidine skeleton, and a hexahydropyrimydopyrimidine skeleton.

Another embodiment of the present invention is the light-emitting device having the above-described structure, in which the first substance is an organic compound including a 1,3,4,6,7,8-hexahydro-2H-pyrimido[1,2-a]pyrimidine skeleton.

Another embodiment of the present invention is the light-emitting device having the above-described structure, in which the first substance is an organic compound including one 1,3,4,6,7,8-hexahydro-2H-pyrimido[1,2-a]pyrimidine skeleton.

Another embodiment of the present invention is the light-emitting device having the above-described structure, in which the first layer includes a first substance and a second substance and the second substance is an organic compound having an electron-transport property.

Another embodiment of the present invention is the light-emitting device having the above-described structure, in which the absolute value of a difference between the LUMO level of the second substance and the LUMO level of the material included in the second layer is higher than or equal to 0.00 eV and lower than or equal to 0.30 eV.

Another embodiment of the present invention is the light-emitting device having the above-described structure, in which the second substance is the same organic compound as the material included in the second layer.

Another embodiment of the present invention is the light-emitting device having the above-described structure, in which the third layer includes an organic compound having a hole-transport property and a material having an acceptor property.

Another embodiment of the present invention is the light-emitting device having the above-described structure, in which the first layer has a hole mobility lower than or equal to 1×10⁻⁸ cm²/Vs when the square root of electric field strength [V/cm] is 600.

Another embodiment of the present invention is the light-emitting device having the above-described structure, in which the first layer has a hole mobility lower than or equal to 1×10⁻⁸ cm²/Vs when the square root of electric field strength [V/cm] is 600 and the first layer has an electron mobility higher than or equal to 1×10⁻⁸ cm²/Vs when the square root of electric field strength [V/cm] is 600.

Another embodiment of the present invention is the light-emitting device having the above-described structure, in which the HOMO level of the material included in the second layer is lower than the HOMO level of the first substance.

Another embodiment of the present invention is the light-emitting device having the above-described structure, in which the difference between the HOMO level of the material included in the second layer and the HOMO level of the first substance is greater than 0.2 eV.

Another embodiment of the present invention is the light-emitting device having the above-described structure, in which the HOMO level of the material included in the second layer is lower than the HOMO level of the organic compound having a hole-transport property.

Another embodiment of the present invention is the light-emitting device having the above-described structure, in which the difference between the HOMO level of the material included in the second layer and the HOMO level of the organic compound having a hole-transport property is greater than 0.2 eV.

Another embodiment of the present invention is a display apparatus including the above-described light-emitting device.

Another embodiment of the present invention is a display module including the above-described display apparatus and at least one of a connector and an integrated circuit.

Another embodiment of the present invention is an electronic appliance including the above-described display module and at least one of a housing, a battery, a camera, a speaker, and a microphone.

### Effect of the Invention

According to one embodiment of the present invention, a novel light-emitting device having a tandem structure can be provided. According to another embodiment of the present invention, a highly efficient light-emitting device having a tandem structure can be provided. Alternatively, according to one embodiment of the present invention, a highly reliable light-emitting device having a tandem structure can be provided. According to another embodiment of the present invention, a high-emission-efficiency and high-reliability light-emitting device having a tandem structure can be provided.

Alternatively, according to one embodiment of the present invention, a novel light-emitting device having a tandem structure fabricated through a photolithography process can be provided. According to another embodiment of the present invention, a highly efficient light-emitting device having a tandem structure fabricated through a photolithography process can be provided. Alternatively, according to one embodiment of the present invention, a highly reliable light-emitting device having a tandem structure fabricated through a photolithography process can be provided. According to another embodiment of the present invention, a high-emission-efficiency and high-reliability light-emitting device having a tandem structure fabricated through a photolithography process can be provided.

Alternatively, according to one embodiment of the present invention, a novel light-emitting device having a tandem structure that can be used in a high-resolution display apparatus can be provided. According to another embodiment of the present invention, a highly efficient light-emitting device having a tandem structure that can be used in a high-resolution display apparatus can be provided. Alternatively, according to one embodiment of the present invention, a highly reliable light-emitting device having a tandem structure that can be used in a high-resolution display apparatus can be provided. According to another embodiment of the present invention, a high-emission-efficiency and high-reliability light-emitting device having a tandem structure that can be used in a high-resolution display apparatus can be provided.

According to another embodiment of the present invention, a highly reliable display apparatus can be provided. According to another embodiment of the present invention, a high-resolution display apparatus can be provided. According to another embodiment of the present invention, a display apparatus having high resolution and high reliability can be provided.

Note that the description of these effects does not preclude the existence of other effects. One embodiment of the present invention does not necessarily need to have all of these effects. Other effects can be derived from the description of the specification, the drawings, and the claims.

### BRIEF DESCRIPTION OF THE DRAWINGS

FIG. 1A and FIG. 1B are band diagrams illustrating a light-emitting device of the present invention and a conventional light-emitting device.

FIG. 2A and FIG. 2B are band diagrams illustrating a driving mechanism of a light-emitting device of the present invention.

FIG. 3 is diagrams illustrating a light-emitting device.

FIG. 4 is a diagram illustrating light-emitting devices.

FIG. 5A and FIG. 5B are a top view and a cross-sectional view of a light-emitting apparatus.

FIG. 6A to FIG. 6E are cross-sectional views illustrating an example of a method for fabricating a display apparatus.

FIG. 7A to FIG. 7D are cross-sectional views illustrating the example of the method for fabricating the display apparatus.

FIG. 8A to FIG. 8D are cross-sectional views illustrating the example of the method for fabricating the display apparatus.

FIG. 9A to FIG. 9C are cross-sectional views illustrating the example of the method for fabricating the display apparatus.

FIG. 10A to FIG. 10C are cross-sectional views illustrating the example of the method for fabricating the display apparatus.

FIG. 11A to FIG. 11C are cross-sectional views illustrating the example of the method for fabricating the display apparatus.

FIG. 12A and FIG. 12B are perspective views illustrating a structure example of a display module.

FIG. 13A and FIG. 13B are cross-sectional views illustrating structure examples of display apparatuses.

FIG. 14 is a perspective view illustrating a structure example of a display apparatus.

FIG. 15 is a cross-sectional view illustrating a structure example of a display apparatus.

FIG. 16 is a cross-sectional view illustrating a structure example of a display apparatus.

FIG. 17 is a cross-sectional view illustrating a structure example of a display apparatus.

FIG. 18A to FIG. 18D are diagrams illustrating examples of electronic appliances.

FIG. 19A to FIG. 19F are diagrams illustrating examples of electronic appliances.

FIG. 20A to FIG. 20G are diagrams illustrating examples of electronic appliances.

FIG. 21 is a graph showing the current efficiency-luminance characteristics of a light-emitting device 1 and a comparative light-emitting device 1 to a comparative light-emitting device 3.

FIG. 22 is a graph showing the luminance-voltage characteristics of the light-emitting device 1 and the comparative light-emitting device 1 to the comparative light-emitting device 3.

FIG. 23 is a graph showing the current efficiency-current density characteristics of the light-emitting device 1 and the comparative light-emitting device 1 to the comparative light-emitting device 3.

FIG. 24 is a graph showing the current density-voltage characteristics of the light-emitting device 1 and the comparative light-emitting device 1 to the comparative light-emitting device 3.

FIG. 25 is a graph showing the luminance-current density characteristics of the light-emitting device 1 and a comparative light-emitting device 1-1 to a comparative light-emitting device 1-3.

FIG. 26 is a graph showing electroluminescence emission spectra of the light-emitting device 1 and the comparative light-emitting device 1-1 to the comparative light-emitting device 1-3.

FIG. 27 is a graph showing the normalized luminance-time change characteristics of the light-emitting device 1 and the comparative light-emitting device 11-1 to the comparative light-emitting device 1-3.

FIG. 28 is a graph showing the voltage change-time characteristics of the light-emitting device 1 and the comparative light-emitting device 1-1 to the comparative light-emitting device 1-3.

FIG. 29 is a graph showing current density-voltage characteristics.

FIG. 30 is a graph showing the luminance-current density characteristics of a light-emitting device 2-1, a light-emitting device 2-2, and a comparative light-emitting device 2.

FIG. 31 is a graph showing the luminance-voltage characteristics of the light-emitting device 2-1, the light-emitting device 2-2, and the comparative light-emitting device 2.

FIG. 32 is a graph showing the current efficiency-current density characteristics of the light-emitting device 2-1, the light-emitting device 2-2, and the comparative light-emitting device 2.

FIG. 33 is a graph showing the current density-voltage characteristics of the light-emitting device 2-1, the light-emitting device 2-2, and the comparative light-emitting device 2.

FIG. 34 is a graph showing electroluminescence spectra of the light-emitting device 2-1, the light-emitting device 2-2, and the comparative light-emitting device 2.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

In this specification and the like, a device fabricated using a metal mask or an FMM (a fine metal mask, a high-resolution metal mask) may be referred to as a device having an MM (a metal mask) structure. In addition, in this specification and the like, a device fabricated without using a metal mask or an FMM is sometimes referred to as a device having an MML (metal maskless) structure.

### Embodiment 1

A tandem light-emitting device including, between a pair of electrodes, a plurality of light-emitting units between which an intermediate layer generating charge is interposed, is capable of offering higher current efficiency than a normal light-emitting device including only one light-emitting unit between electrodes.

The intermediate layer in the tandem light-emitting device includes a charge-generation layer (Carrier Generation Layer: CGL). The CGL is a layer where electrons and holes are generated by charge separation caused by voltage application. The CGL preferably employs a stack of a layer including a material having a hole-transport property and a material having an electron-accepting property with respect to the material having a hole-transport property (P-type CGL) and a layer including a material having an electron-transport property and a material having a donor property with respect to the material having an electron-transport property (N-type CGL), in which case injection of holes or electrons into each light-emitting unit is facilitated and accordingly the driving voltage is reduced.

This is due to the following: holes generated in the P-type CGL are injected into a hole-transport layer of a light-emitting unit on a cathode side through the material having a hole-transport property in the P-type CGL and electrons generated in the N-type CGL are injected into an electron-transport layer of a light-emitting unit on an anode side through the material having an electron-transport property in the N-type CGL, so that barriers to the carrier injection can be lowered. Note that the N-type CGL may be a single film of a material having a donor property. In this case, charge separation occurs between the material having a donor property and the electron-transport material in the light-emitting unit on the anode side; therefore, the electrons can be regarded as being injected into the light-emitting unit at the time of the charge separation. Similarly, the P-type CGL may be a single film of a material having an electron-accepting property. In this case, charge separation occurs between the material having an acceptor property and the hole-transport material in the light-emitting unit on the cathode side; therefore, the holes can be regarded as being injected to the light-emitting unit at the time of the charge separation.

As a method for forming an organic compound film in a predetermined shape at a predetermined position, a vacuum evaporation method with a metal mask (mask vapor deposition) is widely used. However, in these days of higher density and higher resolution, mask vapor deposition has come close to the limit of increasing the resolution for various reasons such as the alignment accuracy and the distance between the substrate and the mask. Thus, shape processing of an organic compound film by a photolithography method is expected to achieve an organic semiconductor device with a finer pattern. Moreover, since a photolithography method achieves an increase in area more easily than mask vapor deposition, the processing of an organic compound film by a photolithography method is being researched.

Meanwhile, it has been known that exposure of an EL layer in an organic EL device to atmospheric components such as water and oxygen affects initial characteristics and reliability, and thus it has been common knowledge that the EL layer is treated in a near-vacuum atmosphere.

In particular, an electron-injection layer in a light-emitting device and an N-type CGL of an intermediate layer used in a light-emitting device having a tandem structure often uses, as a donor for carrier generation, a material having a donor property with respect to an electron-transport material (e.g., an alkali metal, an alkaline earth metal, or a compound thereof, which is also referred to as a Li compound or the like). However, such a Li compound or the like is highly reactive with water or oxygen; therefore, the electron-injection layer and the intermediate layer rapidly deteriorate to have their functions severely impaired due to not only direct contact with atmospheric air but also exposure of the surface of the EL layer to atmospheric air with the use of the Li compound or the like for the intermediate layer. Note that as the Li compound or the like, a material having a donor property such as tetrathianaphthacene (abbreviation: TTN), nickelocene, or decamethylnickelocene can be given as well as an alkali metal, an alkaline earth metal, a rare earth metal, a compound of the above metal (e.g., an alkali metal compound (including an oxide such as lithium oxide, a halide, and a carbonate such as lithium carbonate or cesium carbonate), an alkaline earth metal compound (including an oxide, a halide, and a carbonate), and a rare earth metal compound (including an oxide, a halide, and a carbonate)).

However, processing steps by the aforementioned photolithography method inevitably involve exposure of the surface of the EL layer to the air and cause a substantial loss of the electron-injection property in the electron-injection layer and the intermediate layer for which a Li compound or the like is used. In the case of an element having a stacked structure, the electron-injection layer can be formed after such processing. However, when the light-emitting layer existing in the light-emitting unit on the cathode side is processed by a photolithography method, an intermediate layer in contact with the anode side of the light-emitting unit is exhaustively subjected to the processing; therefore, having favorable characteristics has been difficult for the light-emitting device with a tandem structure that uses the intermediate layer including a Li compound or the like and is formed through processing by a photolithography method.

Here, the present inventors have confirmed that a light-emitting device that uses a strongly basic organic compound (also referred to as a strongly basic material) such as 1-(9,9′-spirobi[9H-fluoren]-2-yl)-1,3,4,6,7,8-hexahydro-2H-pyrimido[1,2-a]pyrimidine (abbreviation: 2hppSF), instead of a Li compound or the like, functions as a tandem light-emitting device.

Note that 2hppSF is a material that does not function as a donor with respect to a material having an electron-transport property. In a light-emitting device using 2hppSF instead of a Li compound or the like, a layer including 2hppSF instead of a Li compound or the like is a layer generating no charge (since the layer generating no charge is not a charge-generation layer (CGL), the layer that replaces the N-type CGL and includes an organic compound having strong basicity instead of a Li compound or the like is referred to as a layer including no donors (Donor-less layer: DLL)).

The layer generating no charge specifically refers to a layer having a spin density lower than or equal to 1×10¹⁷ spins/cm³, preferably lower than 1×10¹⁶ spins/cm³. The spin density of a film formed by co-evaporation of 2,2′-(1,3-phenylene)bis(9-phenyl-1,10-phenanthroline) (abbreviation: mPPhen2P) and lithium oxide at a weight ratio of 1:0.02, which is a film that can be used as the N-type CGL, is 4.8×10¹⁷ spins/cm³; a film having a spin density around this value can be used as the N-type CGL.

While a tandem light-emitting device using the N-type CGL including an alkali metal, an alkaline earth metal, or a compound thereof deteriorates when exposed to atmospheric air during processing by a photolithography method, the use of a layer generating no charge (DLL) instead of the N-type CGL can result in a light-emitting device that is less prone to deterioration due to exposure to atmospheric air. Even a tandem light-emitting device whose processing steps employ a photolithography method or the like involving exposure to atmospheric air is therefore unlikely to deteriorate due to the exposure to atmospheric air, and a light-emitting device of one embodiment of the present invention, which uses the layer generating no charge (DLL) instead of the N-type CGL, can be a light-emitting device with favorable characteristics.

However, the tandem light-emitting device that uses the layer generating no charge (DLL) instead of the N-type CGL has faced a unique problem: a contact between the P-type CGL and the DLL results in lower reliability.

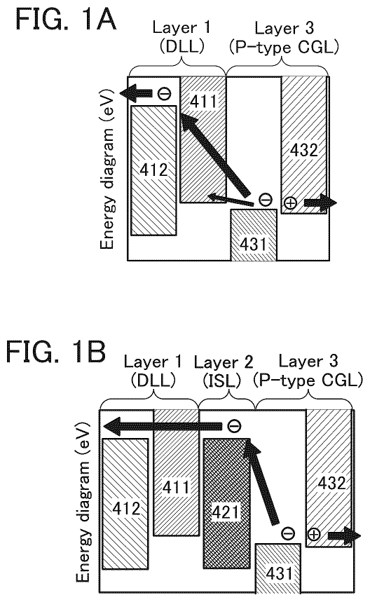

That might be mainly because, as shown in FIG. 1A, the lowest unoccupied molecular orbital (LUMO) level of a material 431 having an electron-accepting property in a layer 3 (P-type CGL) is positioned close to the highest occupied molecular orbital (HOMO) level of a strongly basic material 411 included in a layer 1 (DLL), causing electrons generated by charge separation between a material 432 having a hole-transport property and the material 431 having an acceptor property in the layer 3 (P-type CGL) to be injected into the HOMO level of the strongly basic material 411.

The present inventors have found that the reduction in reliability can be inhibited by forming a layer that inhibits interaction (layer 2: ISL) in contact with the anode side of the P-type CGL, as in FIG. 1B. The inventors have found that, in particular, the LUMO level of the material 421 included in the layer 2 (ISL) and the HOMO level of the strongly basic material 411 included in the layer 1 (DLL) are made to differ by an absolute value greater than or equal to 2.10 eV to effectively inhibit the injection of electrons into the HOMO level of the strongly basic material 411, whereby the light-emitting device can have higher reliability. Note that the absolute value of the difference between the LUMO level of the material 421 included in the layer 2 (ISL) and the HOMO level of the strongly basic material 411 included in the layer 1 (DLL) is preferably greater than or equal to 2.50 eV, further preferably greater than 2.60 eV.

In the light-emitting device of one embodiment of the present invention, while being inhibited from being injected into the HOMO level of the strongly basic material 411, electrons are injected into the LUMO level of the material 412 having an electron-transport property in the layer 1 (DLL), which is assumed to be a proper route (i.e., a route contributing to light emission), and transported to the light-emitting unit on the anode side, whereby the light-emitting device can have high emission efficiency.

The material 421 included in the layer 2 (ISL) is preferably a material with a LUMO level higher than −3.00 eV, further preferably a material with a LUMO level higher than or equal to −2.80 eV, in which case the difference between this LUMO level and the HOMO level of the strongly basic material 411 is large and accordingly the reliability is improved. Note that the LUMO level of the material 421 included in the layer 2 (ISL) is preferably lower than or equal to −2.00 eV, further preferably lower than or equal to −2.60 eV.

With the structure that hinders the injection of electrons into the HOMO level of the strongly basic material 411 included in the layer 1 (DLL) as described above, the light-emitting device of one embodiment of the present invention is inhibited from deteriorating and can have high reliability. The light-emitting device of one embodiment of the present invention can also have high emission efficiency.

The layer 1 (DLL) preferably includes the material 412 having an electron-transport property as well as the strongly basic material 411. By including the material 412 having an electron-transport property, the layer 1 can transport the injected electrons smoothly and inject the electrons into the light-emitting unit on the anode side.

In that case, the absolute value of the difference between the LUMO level of the material 421 included in the layer 2 (ISL) and the LUMO level of the material 412 having an electron-transport property is preferably greater than or equal to 0.00 eV and less than or equal to 0.30 eV, in which case electrons can be easily injected from the layer 2 (ISL) into the layer 1 (DLL). For the same reason, further preferably, the material 421 included in the layer 2 (ISL) and the material 412 having an electron-transport property are the same material.

When holes released from the light-emitting layer on the anode side of the intermediate layer reach the layer 3 (P-type CGL) through the layer 1 (DLL), the holes recombine with electrons generated by charge separation in the layer 3 (P-type CGL), which decreases the emission efficiency of the light-emitting device. To inhibit this, the layer 2 (ISL) that inhibits the interaction between the layer 1 (DLL) and the layer 3 (P-type CGL) is preferably provided.

In view of the above, the HOMO level of the material 421 included in the layer 2 (ISL) is preferably lower than the HOMO level of the strongly basic material 411 included in the layer 1 (DLL). The difference therebetween is preferably greater than 0.2 eV, further preferably greater than 0.4 eV in order that holes can be effectively blocked in the layer 2 (ISL).

The HOMO level of the material 421 included in the layer 2 (ISL) is preferably lower than the HOMO level of the hole-transport material 432 in the layer 3 (P-type CGL). The difference therebetween is preferably greater than 0.2 eV, further preferably greater than 0.4 eV in order that holes can be effectively blocked in the layer 2 (ISL).

The material 421 of the ISL is preferably a material having an electron-transport property. The electron-transport material is preferably an organic compound having a π-electron deficient heteroaromatic ring. Examples of the organic compound having a π-electron deficient heteroaromatic ring skeleton include an organic compound that includes a heteroaromatic ring having an azole skeleton, an organic compound that includes a heteroaromatic ring having a pyridine skeleton, an organic compound that includes a heteroaromatic ring having a diazine skeleton, and an organic compound that includes a heteroaromatic ring having a triazine skeleton. Among the above materials, the organic compound including a heteroaromatic ring having a diazine skeleton (a pyrimidine skeleton, a pyrazine skeleton, or a pyridazine skeleton) or the organic compound including a heteroaromatic ring having a pyridine skeleton has a high LUMO level, a high electron-transport property, and high reliability and thus are preferable.

Examples of the organic compound having a π-electron deficient heteroaromatic ring skeleton include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound having a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: Bphen), bathocuproine (abbreviation: BCP), 2,9-di(naphthalen-2-yl)-4,7-diphenyl-1,10-phenanthroline (abbreviation: NBphen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), or 2-[4-(2-triphenylenyl)phenyl]-1,10-phenanthroline (abbreviation: pTpPPhen); an organic compound having a diazine skeleton, such as 2-[3-(dibenzothiophen-4-yl)phenyl]dibenzo[f,h]quinoxaline (abbreviation: 2mDBTPDBq-II), 2-[3-(3′-dibenzothiophen-4-yl)biphenyl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP-PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), or 4-[3,5-bis(9H-carbazol-9-yl)phenyl]-2-phenyl-6-(biphenyl-4-yl)pyrimidine (abbreviation: 6BP-4Cz2PPm); and an organic compound having a heteroaromatic ring having a triazine skeleton, such as 2-{3-[3-(benzo[b]naphtho[1,2-d]furan-8-yl)phenyl]phenyl}-4,6-diphenyl-1,3,5-triazine (abbreviation: mBnfBPTzn), 2-[3′-(9,9-dimethyl-9H-fluoren-2-yl)biphenyl-3-yl]-4,6-diphenyl-1,3,5-triazine (abbreviation: mFBPTzn), 2-{3-[3-(dibenzothiophen-4-yl)phenyl]phenyl}-4,6-diphenyl-1,3,5-triazine (abbreviation: mDBtBPTzn), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), or 2-[3′-(triphenylen-2-yl)biphenyl-3-yl]-4,6-diphenyl-1,3,5-triazine (abbreviation: mTpBPTzn).

In particular, organic compounds having a phenanthroline skeleton, such as NBphen, mTpPPhen, PnNPhen, and mPPhen2P, are preferable; an organic compound having a phenanthroline dimeric structure, such as mPPhen2P, has excellent stability and is further preferable. A material having a pyridine skeleton or a phenanthroline skeleton, which has a high pKa, has a high hole-blocking property and thus is preferably used particularly for the ISL of the light-emitting device of one embodiment of the present invention.

For example, a metal complex such as bis(2-methyl-8-quinolinolato)(4-phenylphenolato)aluminum(III) (abbreviation: BAlq), bis(8-quinolinolato)zinc(II) (abbreviation: Znq), or bis[2-(2-benzoxazolyl)phenolato]zinc(II) (abbreviation: ZnPBO) can be used.

As the excessively thick ISL increases the driving voltage, its thickness is preferably greater than or equal to 1 nm and less than or equal to 10 nm, further preferably greater than or equal to 2 nm and less than or equal to 5 nm.

The P-type CGL is preferably formed using a composite material containing the above material having an electron-accepting property and the organic compound having a hole-transport property.

As the substance having an electron-accepting property, an organic compound having an electron-withdrawing group (a halogen group, a cyano group, or the like) can be used, and examples thereof include 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylen-1,3,4,5,6,8,9,10-octafluoro-7H-pyren-2-ylidene)malononitrile. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a significantly high electron-accepting property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an electron-accepting property, a transition metal oxide such as molybdenum oxide, vanadium oxide, ruthenium oxide, tungsten oxide, or manganese oxide can be used, other than the above-described organic compounds.

As the organic compound having a hole-transport property used in the composite material, any of a variety of organic compounds such as aromatic amine compounds, heteroaromatic compounds, aromatic hydrocarbons, and high molecular compounds (e.g., oligomers, dendrimers, and polymers) can be used. Note that the organic compound having a hole-transport property used in the composite material is preferably an organic compound having a hole mobility of 1×10⁶ cm²/Vs or higher. The organic compound having a hole-transport property used in the composite material is preferably a compound having a condensed aromatic hydrocarbon ring or a π-electron rich heteroaromatic ring. As the condensed aromatic hydrocarbon ring, an anthracene ring, a naphthalene ring, or the like is preferable. As the Tc-electron rich heteroaromatic ring, a condensed aromatic ring having at least one of a pyrrole skeleton, a furan skeleton, and a thiophene skeleton is preferable; specifically, a carbazole ring, a dibenzothiophene ring, or a ring in which an aromatic ring or a heteroaromatic ring is further condensed to a carbazole ring or a dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that includes a naphthalene ring, or an aromatic monoamine in which a 9-fluorenyl group is bonded to nitrogen of amine through an arylene group may be used. Note that the organic compound having a hole-transport property preferably a substance having an N,N-bis(4-biphenyl)amino group to enable fabricating a light-emitting device having a long lifetime.

Specific examples of the above-described organic compound having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBij3NB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

For another aromatic amine compound as the material having a hole-transport property, N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), or the like can also be used.

The material having an electron-acceptor property in the P-type CGL preferably has an electron-accepting property. The material having an electron-acceptor property preferably has a property of accepting electrons from the organic compound having a hole-transport property. When the material having an acceptor property has an electron-accepting property, charge separation is caused in the P-type CGL, so that the P-type CGL can function as a charge-generation layer and can thus function as an intermediate layer in a tandem light-emitting device. Furthermore, the signal observed by electron spin resonance in the P-type CGL is preferably observable. For example, the density of spins attributed to a signal observed at a g-factor of approximately 2.00 is preferably higher than or equal to 1×10¹⁶ spins/cm³, more preferably higher than or equal to 1×10¹⁷ spins/cm³, further preferably higher than or equal to 1×10¹⁸ spins/cm³, still further preferably higher than or equal to 1×10¹⁹ spins/cm³.

The DLL is preferably a layer in which a weak signal or no signal is observed by electron spin resonance. For example, the spin density attributed to a signal observed at a g-factor of approximately 2.00 is preferably lower than or equal to 1×10¹⁷ spins/cm³, further preferably lower than 1×10¹⁶ spins/cm³.

Moreover, it is preferable that the DLL include a substance having strong basicity with an acid dissociation constant pKa of 8 or more and that the substance having strong basicity do not have a property of donating electrons to the material having an electron-transport property. In the case where the substance having strong basicity has an electron-donating property, the substance easily reacts with atmospheric components such as water and oxygen and becomes poor in stability.

Even when the substance having strong basicity does not have an electron-donating property, inclusion of the substance having strong basicity and the material having an electron-transport property can significantly reduce the hole-transport property of the DLL, which enables fabrication of a tandem light-emitting device without a significant increase in drive voltage. Thus, an intermediate layer and a tandem light-emitting device that are stable with respect to an atmospheric component such as water and oxygen can be fabricated.

It is preferable that the organic compound having strong basicity not have an electron-transport skeleton in order to lower the probability of recombination with electrons in the DLL.

Note that 2hppSF is a substance which has strong basicity with an acid dissociation constant pKa of 13.95, does not have an electron-donating property with respect to a material having an electron-transport property, and does not have an electron-transport skeleton.

The hole-blocking function of a material with a large acid dissociation constant pKa derives from a large dipole moment of the material with a large pKa. The dipole moment mutually interacts with holes, whereby the DLL containing the material with a large acid dissociation constant pKa can block holes.

Another reason for the appearance of the hole-blocking function is high nucleophilicity of the material with a large acid dissociation constant pKa. A material with high nucleophilicity reacts with a molecule that has become a cation radical by receiving a hole to generate a new molecule or intermediate state, in some cases. This reaction consumes holes and significantly reduces the hole-transport property in the DLL, in some cases.

As the acid dissociation constant pKa of the basic skeleton, the acid dissociation constant value of the organic compound formed by substituting hydrogen for part of the skeleton can be used. As an indicator of acidity of an organic compound having a basic skeleton, the acid dissociation constant pKa of the basic skeleton can be used. As for an organic compound having a plurality of basic skeletons, the acid dissociation constant pKa of the basic skeleton having the highest acid dissociation constant pKa can be used as the indicator of acidity of the organic compound. As the acid dissociation constant pKa, a value measured using water as a solvent is preferably employed.

Alternatively, the acid dissociation constant pKa of an organic compound may be calculated in the following manner.

First, the initial molecular structure of a molecule serving as a calculation model is set to the most stable structure (singlet ground state) obtained from first-principles calculation.

For the first-principles calculation, Jaguar, which is the quantum chemical computational software produced by Schrödinger, Inc., is used, and the most stable structure in the singlet ground state is calculated by the density functional theory (DFT). As a basis function, 6-31G** is used, and as a functional, B3LYP-D3 was used. The structure subjected to quantum chemical calculation is sampled by conformational analysis in Mixed torsional/Low-mode sampling with Maestro GUI produced by Schrödinger, Inc.

In the calculation of pKa, one or more atoms in each molecule are designated as basic sites, Macro Model is used to search for the stable structure of the protonated molecule in water, conformational search is performed with OPLS2005 force field, and a conformational isomer having the lowest energy is used. Jaguar's pKa calculation module is used. After structure optimization is performed by B3LYP/6-31G*, single point calculation is performed by cc-pVTZ(+) and the pKa value is calculated using empirical correction for functional group(s). For the molecule with one or more atoms designated as basic sites, the largest pKa value among the obtained results is employed.

As an organic compound having a high acid dissociation constant pKa, an organic compound having a pyrrolidine skeleton, a piperidine skeleton, or a hexahydropyrimidopyrimidine skeleton is preferable. Alternatively, an organic compound having a guanidine skeleton is preferable. As specific examples, organic compounds having any of basic skeletons represented by Structural Formulae (120) to (123) below can be given.

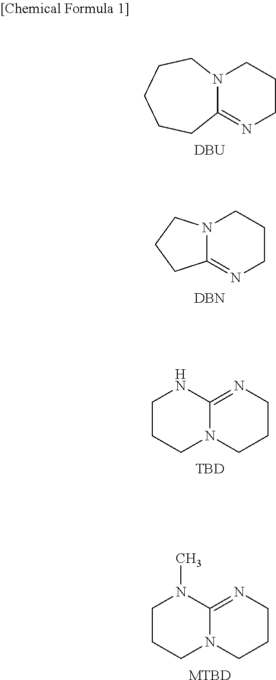

It is preferable that the organic compound with an acid dissociation constant pKa of 8 or more be specifically an organic compound which has a bicyclo ring structure having 2 or more nitrogen atoms in the ring and a heteroaromatic hydrocarbon ring having 2 to 30 carbon atoms in the ring or an aromatic hydrocarbon ring having 6 to 30 carbon atoms in the ring, and more specifically be an organic compound which has a 1,3,4,6,7,8-hexahydro-2H-pyrimido[1,2-a]pyrimidine skeleton and a heteroaromatic hydrocarbon ring having 2 to 30 carbon atoms in the ring or an aromatic hydrocarbon ring having 6 to 30 carbon atoms in the ring. Note that an organic compound which has a bicyclo ring structure having 2 or more nitrogen atoms in the ring and a heteroaromatic hydrocarbon ring having 2 to 30 carbon atoms in the ring, more specifically an organic compound which has a 1,3,4,6,7,8-hexahydro-2H-pyrimido[1,2-a]pyrimidine skeleton and a heteroaromatic hydrocarbon ring having 2 to 30 carbon atoms in the ring is further preferable.

Further specifically, an organic compound represented by General Formula (G1) below is preferable.

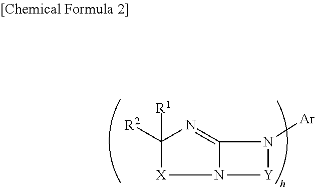

In the organic compound represented by General Formula (G1) above, X is a group represented by General Formula (G1-1) below, and Y is a group represented by General Formula (G1-2) below. R¹ and R² each independently represent hydrogen or deuterium, h represents an integer of 1 to 6, and Ar represents a substituted or unsubstituted heteroaromatic hydrocarbon ring having 2 to 30 carbon atoms in the ring or a substituted or unsubstituted aromatic hydrocarbon ring having 6 to 30 carbon atoms in the ring. Note that Ar is preferably the substituted or unsubstituted heteroaromatic hydrocarbon ring having 2 to 30 carbon atoms in the ring.

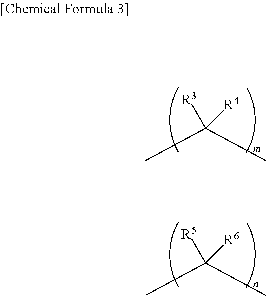

In General Formulae (G1-1) and (G1-2) above, R³ to R⁶ each independently represent hydrogen or deuterium, m represents an integer of 0 to 4, n represents an integer of 1 to 5, and m+1≥n is satisfied. Note that in the case where m or n is 2 or more, R³s to R⁶s may be the same or different from each other.

The organic compound represented by General Formula (G1) above is preferably any one of General Formulae (G2-1) to (G2-6) below.

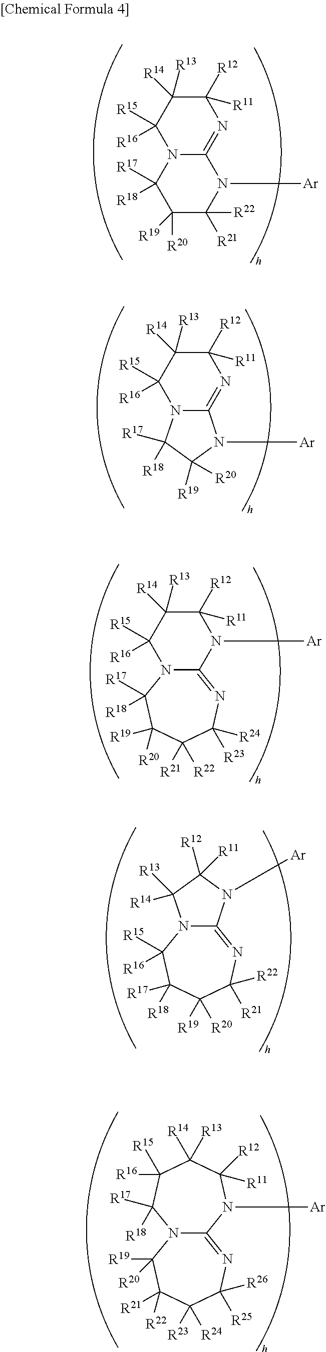

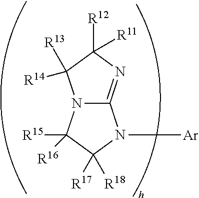

Note that R¹¹ to R²⁶ each independently represent hydrogen or deuterium, h represents an integer of 1 to 6, and Ar represents a substituted or unsubstituted heteroaromatic hydrocarbon ring having 2 to 30 carbon atoms in the ring or a substituted or unsubstituted aromatic hydrocarbon ring having 6 to 30 carbon atoms in the ring. Note that Ar is preferably the substituted or unsubstituted heteroaromatic hydrocarbon ring having 2 to 30 carbon atoms in the ring.

Note that specific examples of the substituted or unsubstituted heteroaromatic hydrocarbon ring having 2 to 30 carbon atoms in the ring or the substituted or unsubstituted aromatic hydrocarbon ring having 6 to 30 carbon atoms in the ring, which is represented by Ar in General Formula (G1) and General Formulae (G2-1) to (G2-6) above, include a pyridine ring, a bipyridine ring, a pyrimidine ring, a bipyrimidine ring, a pyrazine ring, a bipyrazine ring, a triazine ring, a quinoline ring, an isoquinoline ring, a benzoquinoline ring, a phenanthroline ring, a quinoxaline ring, a benzoquinoxaline ring, a dibenzoquinoxaline ring, an azofluorene ring, a diazofluorene ring, a carbazole ring, a benzocarbazole ring, a dibenzocarbazole ring, a dibenzofuran ring, a benzonaphthofuran ring, a dinaphthofuran ring, a dibenzothiophene ring, a benzonaphthothiophene ring, a dinaphthothiophene ring, a benzofuropyridine ring, a benzofuropyrimidine ring, a benzothiopyridine ring, a benzothiopyrimidine ring, a naphthofuropyridine ring, a naphthofuropyrimidine ring, a naphthothiopyridine ring, a naphthothiopyrimidine ring, an acridine ring, a xanthene ring, a phenothiazine ring, a phenoxazine ring, a phenazine ring, a triazole ring, an oxazole ring, an oxadiazole ring, a thiazole ring, a thiadiazole ring, an imidazole ring, a benzimidazole ring, a pyrazole ring, and a pyrrole ring. Specific examples of the substituted or unsubstituted heteroaromatic hydrocarbon ring having 6 to 30 carbon atoms in the ring, which is represented by Ar in General Formula (G1) and General Formulae (G2-1) to (G2-6) above, include a benzene ring, a naphthalene ring, a fluorene ring, a dimethylfluorene ring, a diphenylfluorene ring, a spirofluorene ring, an anthracene ring, a phenanthrene ring, a triphenylene ring, a pyrene ring, a tetracene ring, a chrysene ring, and a benzo[a]anthracene ring. Among the above rings, any one of Structural Formulae (Ar-1) to (Ar-27) below is preferable.

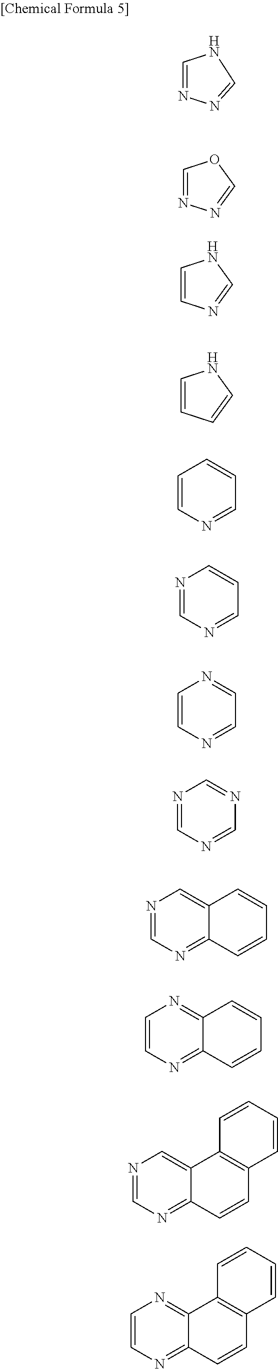

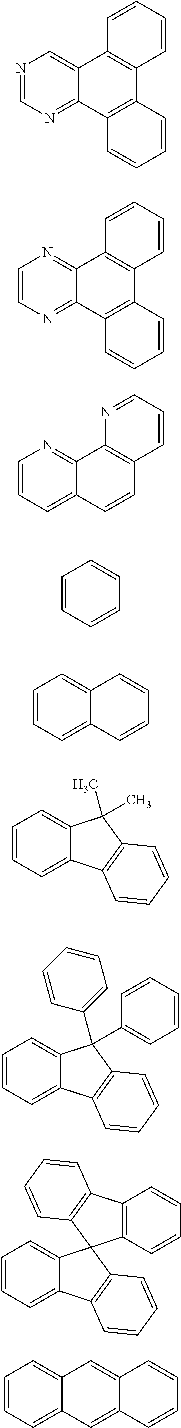

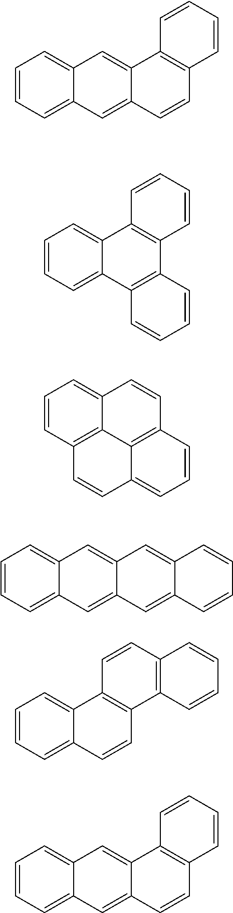

Note that Ar preferably has a nitrogen atom in its ring and is preferably bonded to the skeleton within parentheses in General Formula (G1) by a bond of the nitrogen atom or a carbon atom adjacent to the nitrogen atom.

Specific examples of the organometallic compounds represented by General Formula (G1) above and General Formulae (G2-1) to (G2-6) include organic compounds represented by Structural Formulae (101) to (117) below, such as 1,1′-(9,9′-spirobi[9H-fluorene]-2,7-diyl)bis(1,3,4,6,7,8-hexahydro-2H-pyrimido[1,2-a]pyrimidine) (abbreviation: 2,7hpp2SF) (Structural Formula 108) and 1-(9,9′-spirobi[9H-fluoren]-2-yl)-1,3,4,6,7,8-hexahydro-2H-pyrimido[1,2-a]pyrimidine (abbreviation: 2hppSF) (Structural Formula 109).

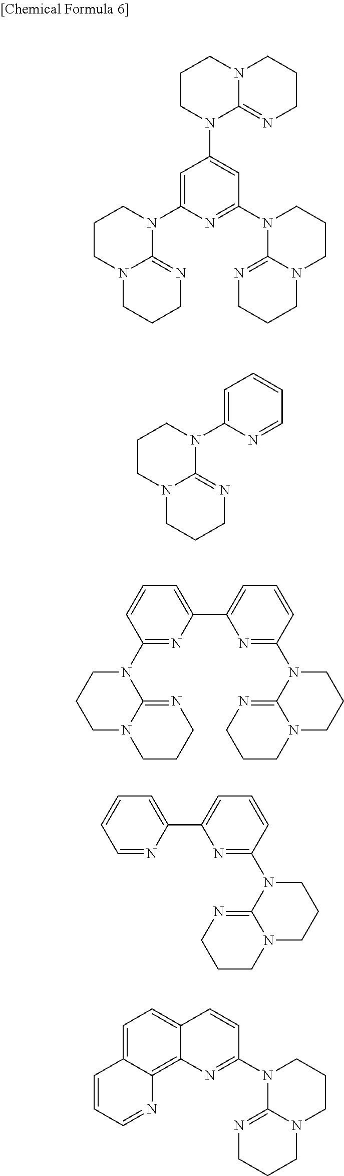

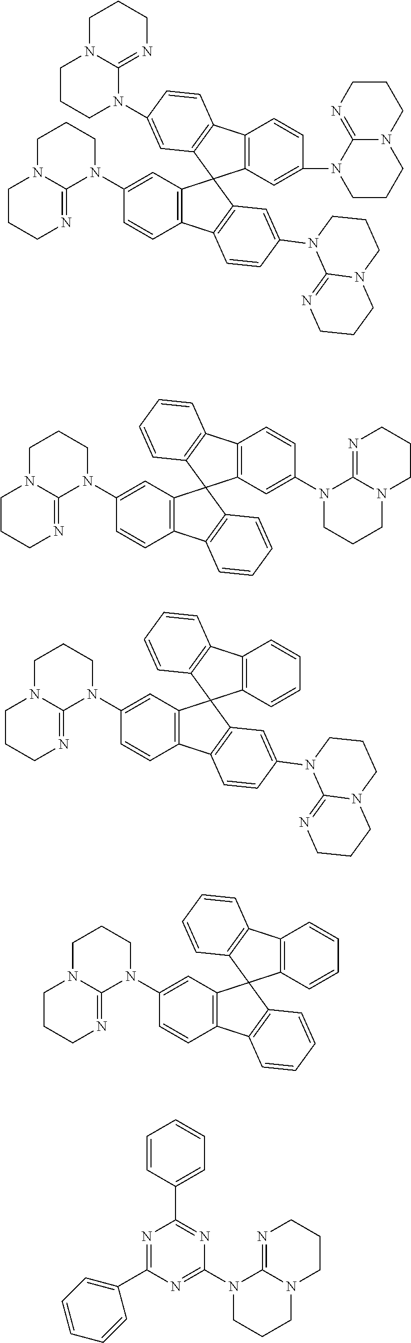 [SMILES: c1cc2c(cc1N1CCCN3CCCN=C31)C1(c3cc(N4CCCN5CCCN=C54)ccc3-2)c2cc(N3CCCN4CCCN=C43)ccc2-c2ccc(N3CCCN4CCCN=C43)cc21 ; c1ccc2c(c1)-c1ccc(N3CCCN4CCCN=C43)cc1C21c2ccccc2-c2ccc(N3CCCN4CCCN=C43)cc21 ; c1ccc2c(c1)-c1ccccc1C21c2cc(N3CCCN4CCCN=C43)ccc2-c2ccc(N3CCCN4CCCN=C43)cc21 ; c1ccc2c(c1)-c1ccccc1C21c2ccccc2-c2ccc(N3CCCN4CCCN=C43)cc21 ; c1ccc(-c2nc(-c3ccccc3)nc(N3CCCN4CCCN=C43)n2)cc1]

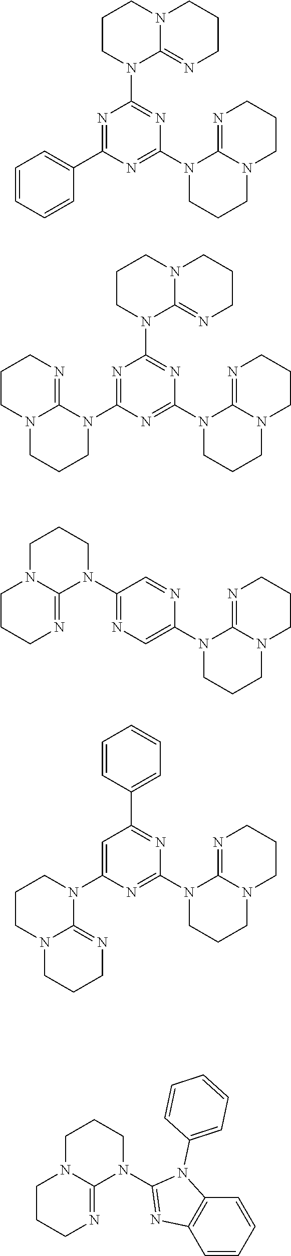

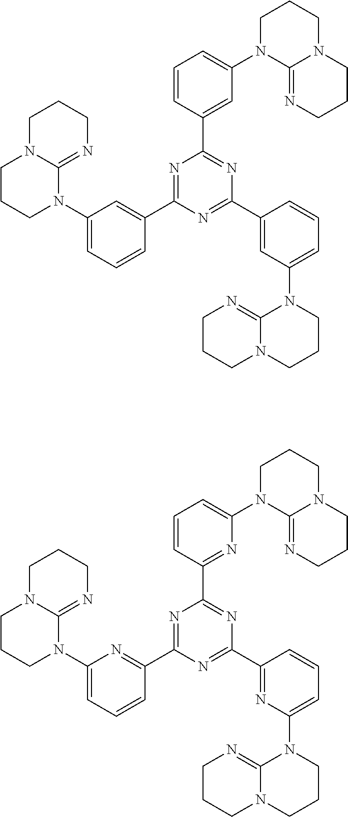 [SMILES: c1cc(-c2nc(-c3cccc(N4CCCN5CCCN=C54)c3)nc(-c3cccc(N4CCCN5CCCN=C54)c3)n2)cc(N2CCCN3CCCN=C32)c1 ; c1cc(-c2nc(-c3cccc(N4CCCN5CCCN=C54)n3)nc(-c3cccc(N4CCCN5CCCN=C54)n3)n2)nc(N2CCCN3CCCN=C32)c1]

Note that it is preferable that the substance having strong basicity with a pKa of 8 or more not have an electron-transport skeleton from the viewpoint of inhibiting recombination of the injected electrons and blocked holes in the substance having strong basicity with a pKa of 8 or more. As the substance having strong basicity with a pKa of 8 or more, an organic compound such as 1-(9,9′-spirobi[9H-fluoren]-2-yl)-1,3,4,6,7,8-hexahydro-2H-pyrimido[1,2-a]pyrimidine (abbreviation: 2hppSF), 2,9-bis(1,3,4,6,7,8-hexahydro-2H-pyrimido[1,2-a]pyrimidin-1-yl)-1,10-phenanthroline (abbreviation: 2,9hpp2Phen), 4,7-di-1-pyrrolidinyl-1,10-phenanthroline (abbreviation: Pyrrd-Phen), or 8,8′-pyridin-2,6-diyl-bis(5,6,7,8-tetrahydroimidazo[1,2-a]pyrimidine) (abbreviation: 2,6tip2Py) can specifically be used.

Furthermore, the DLL preferably contains a material having an electron-transport property in addition to the material having strong basicity with a pKa of 8 or more. As the material having an electron-transport property, for example, a metal complex such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound having a π-electron deficient heteroaromatic ring is preferable. Examples of the organic compound having a π-electron deficient heteroaromatic ring skeleton include an organic compound that has a heteroaromatic ring having a polyazole skeleton, an organic compound that has a heteroaromatic ring having a pyridine skeleton, an organic compound that has a heteroaromatic ring having a diazine skeleton, and an organic compound that has a heteroaromatic ring having a triazine skeleton.

Among the above organic compounds, the organic compound that has a heteroaromatic ring having a diazine skeleton (a pyrimidine skeleton, a pyrazine skeleton, or a pyridazine skeleton), the organic compound that has a heteroaromatic ring having a pyridine skeleton, and the organic compound that has a heteroaromatic ring having a triazine skeleton are preferable because of their high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high reliability.

Examples of the organic compound having a π-electron deficient heteroaromatic ring skeleton include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound having a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: Bphen), bathocuproine (abbreviation: BCP), 2,9-di(naphthalen-2-yl)-4,7-diphenyl-1,10-phenanthroline (abbreviation: NBphen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), or 2-[4-(2-triphenylenyl)phenyl]-1,10-phenanthroline (abbreviation: pTpPPhen); an organic compound having a diazine skeleton, such as 2-[3-(dibenzothiophen-4-yl)phenyl]dibenzo[f,h]quinoxaline (abbreviation: 2mDBTPDBq-II), 2-[3-(3′-dibenzothiophen-4-yl)biphenyl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[(3′-dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP-PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); and an organic compound having a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris(3′-(pyridin-3-yl)biphenyl-3-yl)-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), or 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn). The organic compound having a heteroaromatic ring having a diazine skeleton, the organic compound having a heteroaromatic ring having a pyridine skeleton, and the organic compound having a heteroaromatic ring having a triazine skeleton have high reliability and thus are preferable.

In particular, the organic compound that has a heteroaromatic ring having a diazine skeleton, the organic compound that has a heteroaromatic ring having a pyridine skeleton, and the organic compound that has a heteroaromatic ring having a triazine skeleton are preferable because of their high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. An organic compound having a phenanthroline skeleton, such as mTpPPhen, PnNPhen, or mPPhen2P, is especially preferable, and an organic compound having a phenanthroline dimer structure, such as mPPhen2P, is further preferable because of its excellent stability. Furthermore, a material having a pyridine skeleton or a phenanthroline skeleton, which has a high pKa and thus has a high hole-blocking property, is particularly preferable as an electron-transport material used in the DLL of the light-emitting device of one embodiment of the present invention.

The LUMO level of the material having an electron-transport property in the DLL is preferably greater than or equal to −3.00 eV and less than or equal to −2.00 eV in order to lower a barrier to electron injection into the light-emitting layer.

Note that the thickness of the DLL is preferably small; however, too large a thickness increases driving voltage and too small a thickness worsens characteristics, particularly reliability. Therefore, the thickness of the DLL is preferably greater than or equal to 2 nm and less than or equal to 13 nm, further preferably greater than or equal to 5 nm and less than or equal to 10 nm.

The DLL is preferably a layer having a function of blocking holes or a layer having an extremely low hole-transport property. The DLL needs to transport and inject, to the light-emitting unit on the anode side (first light-emitting unit), electrons injected from the P-type CGL and thus is a layer having an electron-transport property.

Whether the DLL is a layer having a function of blocking holes or a layer having an extremely low hole-transport property can be determined by fabricating an electronic device that makes only holes flow (hereinafter referred to as a hole-only device) and measuring the relation between current density and voltage. For example, in the case where the current density of a hole-only device shown in Table 1, in which a target layer is sandwiched, is extremely low, specifically in the case where the current density of the measurement device shown in Table 1, in which the target layer is sandwiched, at a voltage of 10 V applied between electrodes is lower than or equal to 0.01 mA/cm², the target layer can be regarded as a layer that blocks holes.

TABLE 1

| | Thickness | |
|---|---|---|
| | (nm) | |
| Second electrode | 100 | Aluminum |
| Fifth layer | 5 | Molybdenum oxide |
| Fourth layer | 50 | PCBBiF |
| Third layer | 10 | Measurement target layer |
| Second layer | 50 | PCBBiF |
| First layer | 10 | PCBBiF:OCHD003 |
| | | (1:0.15) |
| First electrode | 70 | ITSO |

In the table, ITSO represents indium tin oxide containing silicon oxide, PCBBiF represents N-(biphenyl-4-yl)-N-[4-(9-phenyl-9H-carbazol-3-yl)phenyl]-9,9-dimethyl-9H-fluoren-2-amine, and OCHD-003 represents a fluorine-containing material having an electron-accepting property with a molecular weight of 672.

The relation between current density and voltage is compared between such a device in which a third layer is not formed and a device in which a 10-nm-thick target layer is formed as the third layer. In the case where measurement is performed with the 10-nm-thick target layer serving as the third layer sandwiched, the layer offering a current density at 10 V of lower than or equal to 0.01 mA/cm² can be regarded as a layer that blocks holes.

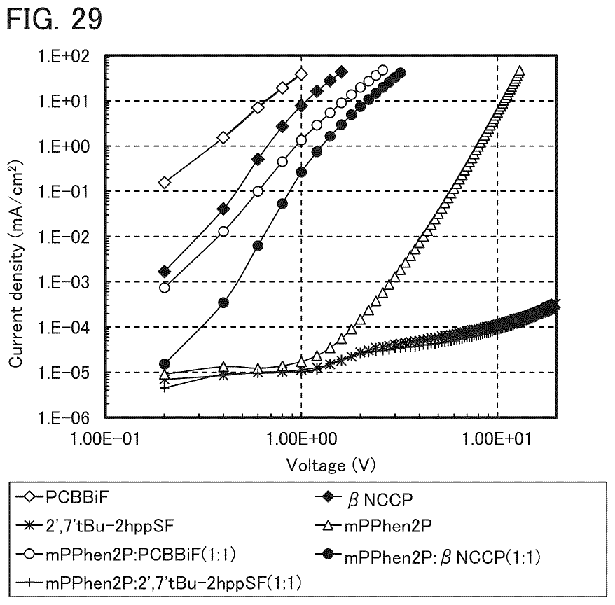

FIG. 29 shows a measurement example using such a device. FIG. 29 shows results of the hole-only measurement devices in which films of N-(biphenyl-4-yl)-N-[4-(9-phenyl-9H-carbazol-3-yl)phenyl]-9,9-dimethyl-9H-fluoren-2-amine (abbreviation: PCBBiF), 9-(2-naphthyl)-9′-phenyl-9H,9′H-3,3′-bicarbazole (abbreviation: PNCCP), 1-(2′,7′-di-tert-butyl-9,9′-spirobi[9H-fluoren]-2-yl)-1,3,4,6,7,8-hexahydro-2H-pyrimido[1,2-a]pyrimidine (abbreviation: 2′,7′tBu-2hppSF), 2,2′-(1,3-phenylene)bis(9-phenyl-1,10-phenanthroline) (abbreviation: mPPhen2P), mPPhen2P:PCBBiF (1:1, weight ratio), mPPhen2P:PNCCP (1:1, weight ratio), and mPPhen2P:2′,7′tBu-2hppSF (1:1, weight ratio) are formed as the third layers.

From the graph, the layers formed of PCBBiF, PNCCP, mPPhen2P, mPPhen2P:PCBBiF (1:1, weight ratio), and mPPhen2P:PNCCP (1:1, weight ratio) can be regarded as layers that do not block holes, and the layers formed of mPPhen2P:2′,7′tBu-hppSF (1:1, weight ratio) and 2′,7′tBu-2hppSF can be regarded as layers that block holes.

In the case where the layer desired to be measured is a mixed layer of Material A and Material B, the hole-only device in which the mixed layer is provided as the measurement target layer (Device A) and the hole-only device in which a single layer of Material A or Material B, whichever has a deeper HOMO level, is provided as the measurement target layer (Device B) are manufactured; in the case where the voltage at 1 mA/cm² of Device A is higher than that of Device B by greater than or equal to 1 V, the mixed layer can be referred to as a layer that blocks holes.

The hole mobility in the DLL is preferably lower than or equal to 1×10⁻⁸ cm²/Vs under the conditions where the square root of electric field strength [V/cm] is 600. The electron mobility in the DLL is preferably higher than or equal to 1×10⁻⁷ cm²/Vs under the conditions where the square root of electric field strength [V/cm] is 600. The electron mobility is preferably higher than or equal to 1000 times, further preferably 10000 times the hole mobility under the conditions where the square root of electric field strength [V/cm] is 600.

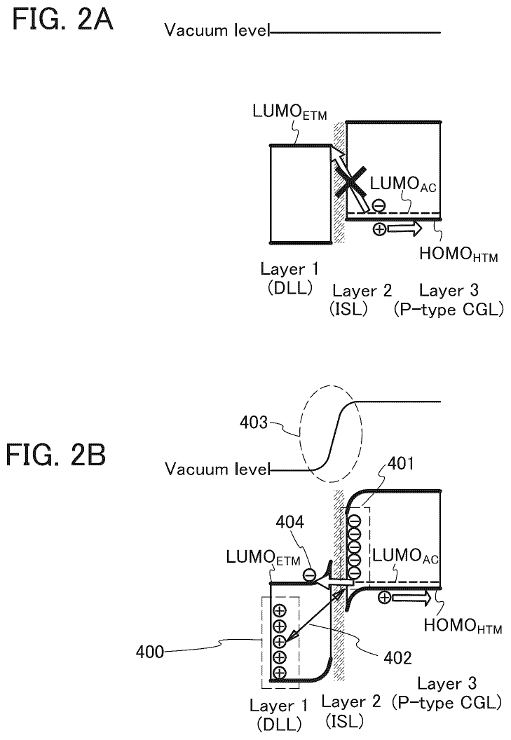

The mechanism of a tandem light-emitting device using the layer generating no charge (DLL) instead of the N-type CGL and the light-emitting device of one embodiment of the present invention are described below with reference to FIG. 2.

In a typical tandem light-emitting device, a Li compound used in the N-type CGL acts as a donor, and generates carriers by charge separation between an electron-transport material and the Li compound. However, the DLL (layer 1) is a layer that does not cause charge separation and does not generate charge.

By contrast, the P-type CGL (layer 3) generates carriers (holes and electrons) by voltage application even in the case where the DLL does not generate charge. Usually, however, the large difference between the lowest unoccupied molecular orbital (LUMO) level (LUMO_{ETM}) of the material having an electron-transport property and the LUMO level (LUMO_{AC}) of the material having an acceptor property makes a large potential gap in LUMO level between the material having an acceptor property of the P-type CGL and the material having an electron-transport property of the DLL, which hinders the injection of electrons generated in the P-type CGL into the DLL (FIG. 2A).

Therefore, even when the P-type CGL generates electrons, the DLL that does not generate charge hinders electron injection into a first electron-transport layer of the first light-emitting unit, so that it is difficult to obtain light emission from a first light-emitting layer of the first light-emitting unit. Note that holes generated in the P-type CGL can be injected into a second light-emitting unit without any problems because the HOMO level (HOMO_{HTM}) of the material having a hole-transport property of the P-type CGL can be the same as or close to the HOMO level of a material having a hole-transport property a second hole-transport layer of in the second light-emitting unit.

Although the DLL does not function as a charge-generation layer in the tandem light-emitting device which uses the DLL instead of the N-type CGL, the device using the DLL instead of the N-type CGL functions as a tandem light-emitting device; the reason for this result can be explained by the driving mechanism of the tandem light-emitting device, that is, generation of electric dipole due to accumulation of charges and the resulting shift of the vacuum level.

In the tandem light-emitting device using the DLL instead of the N-type CGL, application of a voltage in the above-described manner does not make the DLL generate charge because the DLL does not function as a CGL. Meanwhile, since an electron-transport layer usually blocks holes or has a low hole-transport property, holes injected into the first light-emitting unit from the anode are accumulated near the interface on the DLL side in the first light-emitting layer or the first electron-transport layer. In this case, the DLL is preferably a layer that blocks holes or a layer that has an extremely low hole mobility in order that the first light-emitting layer can efficiently emit light. In the case where the DLL includes a strongly basic organic compound, holes are accumulated in the vicinity of the interface on the first electron-transport layer side in the DLL (400 in FIG. 2B).

Although holes and electrons are induced from the P-type CGL by the voltage application and the hole accumulation, the electrons induced in the P-type CGL are accumulated in the vicinity of the interface on the DLL side in the P-type CGL (401 in FIG. 2B) without being injected into the DLL since the difference in LUMO level between the material having an electron-accepting property included in the P-type CGL and the material having an electron-transport property included in the DLL is large in the initial state as described above (in the case where the DLL does not include the material having an electron-transport property, that is, where the DLL is a single film of the strongly basic organic compound, electrons generated in the P-type CGL are accumulated on the side of the single film of the strongly basic organic compound). The accumulated electrons and the holes accumulated in the first light-emitting layer, the first electron-transport layer, or the DLL form an electric double layer and generate electric dipole (402 in FIG. 2B).

Consequently, the vacuum level shifts (403 in FIG. 2B) and the LUMO level of the material having an electron-accepting property included in the P-type CGL and the LUMO level of the material having an electron-transport property in the DLL become closer to each other, so that the electrons generated in the P-type CGL start to be injected into the DLL (404 in FIG. 2B). Then, the electrons injected into the DLL are further injected into the first light-emitting unit and reach the first light-emitting layer, where they recombine to produce light emission in the first light-emitting unit; thus, the light-emitting device of one embodiment of the present invention in which the DLL is used instead of the N-type CGL can function as a tandem light-emitting device.

While a light-emitting device using the N-type CGL including an alkali metal, an alkaline earth metal, or a compound thereof deteriorates when exposed to atmospheric air, the light-emitting device using a layer generating no charge (DLL) instead of the N-type CGL is less prone to deterioration due to exposure to atmospheric air. Even a light-emitting device whose processing steps employ a photolithography method involving exposure to atmospheric air is therefore unlikely to deteriorate due to the exposure to atmospheric air, and a light-emitting device of one embodiment of the present invention, which uses the layer generating no charge (DLL) instead of the N-type CGL, can be a light-emitting device with favorable characteristics.

The light-emitting device of one embodiment of the present invention having the above-described structure can have high current efficiency, high reliability, and a suppressed increase in driving voltage.

The highly reliable light-emitting device can be provided by the existence of the layer 2 that is the ISL. The following has been found: the LUMO level of the material 421 included in the layer 1 (ISL) and the HOMO level of the strongly basic material 411 included in the layer 1 (DLL) are made to differ by an absolute value greater than or equal to 2.10 eV, preferably greater than or equal to 2.50 eV, further preferably greater than 2.60 eV, to effectively inhibit the injection of electrons into the HOMO level of the strongly basic material 411, whereby the light-emitting device can have higher reliability. In the light-emitting device of one embodiment of the present invention, while being inhibited from being injected into the HOMO level of the strongly basic material 411, electrons are injected into the LUMO level of the material 412 having an electron-transport property in the layer 1, which is assumed to be a proper route (i.e., a route contributing to light emission), and transported to the light-emitting unit on the anode side, whereby the light-emitting device can have high emission efficiency.

Note that the light-emitting device of one embodiment of the present invention is particularly suitable for a light-emitting device fabricated through a photolithography process and also contributes to cost reduction in fabrication of light-emitting devices not through a photolithography process because high stability in atmospheric air increases yield and eliminates the need for too strictly managing the atmosphere in the fabrication process.

### Embodiment 2

In this embodiment, a light-emitting device of one embodiment of the present invention will be described in detail.

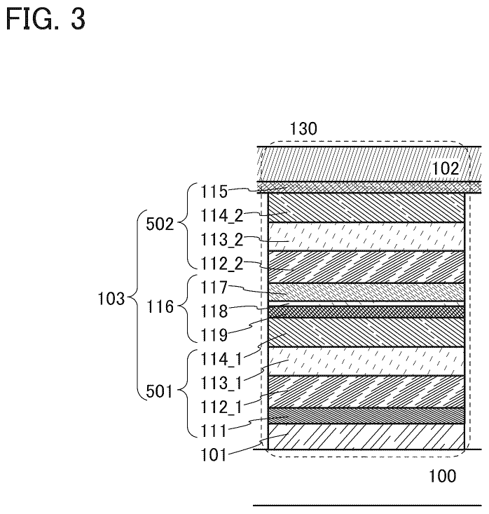

FIG. 3 shows schematic views of light-emitting devices of one embodiment of the present invention. The light-emitting device includes a first electrode 101 over an insulator 100, and an organic compound layer 103 between the first electrode 101 and a second electrode 102. As described in Embodiment 1, the organic compound layer 103 includes a plurality of light-emitting units (a first light-emitting unit 501 and a second light-emitting unit 502 in FIG. 3) and an intermediate layer 116.

The first light-emitting unit 501 includes at least a first light-emitting layer 113_1 and a first electron-transport layer 114_1, and the second light-emitting unit 502 includes at least a second light-emitting layer 113_2. The light-emitting layer 113_1 and the light-emitting layer 113_2 are each a layer containing a light-emitting substance and emits light when voltage is applied between the first electrode 101 and the second electrode 102.

The first light-emitting unit 501 preferably includes, in addition to the above-described layers, functional layers such as a hole-injection layer 111 and a first hole-transport layer 112_1 as illustrated in FIG. 3. In addition to the above, a functional layer other than the above-described functional layers, such as an electron-blocking layer or an exciton-blocking layer, may be included. Alternatively, any of the above-described layers may be omitted.

The second light-emitting unit 502 preferably includes, in addition to the above-described layers, functional layers such as a second hole-transport layer 112_2, a second electron-transport layer 114_2, and an electron-injection layer 115 as illustrated in FIG. 3. In addition to the above, a functional layer other than the above-described functional layers, such as a hole-blocking layer, an electron-blocking layer, or an exciton-blocking layer, may be included. Alternatively, any of the above-described layers may be omitted.

Furthermore, the intermediate layer 116 includes at least a first layer 119 (the DLL in Embodiment 1), a second layer 118 (the ISL in Embodiment 1), and a third layer 117 (the P-type CGL in Embodiment 1) from the anode (the first electrode 101 in FIG. 3) side. The first layer 119 is a layer containing an organic compound having strong basicity as described in Embodiment 1. The first layer 119 may further contain an organic compound having an electron-transport property. The third layer 117 is a layer which generates charge by voltage application. The third layer 117 is preferably a layer containing an organic compound having a hole-transport property and a substance having an electron-accepting property with respect to the organic compound. The second layer 118 is formed using a material with a specific LUMO level as described in Embodiment 1, and providing the second layer can inhibit a reduction in the reliability of the light-emitting device. In addition, the emission efficiency of the light-emitting device can be improved.

Since the structures of the first layer 119, the second layer 118, and the third layer 117 have been specifically described in detail as the structures of the DLL, the P-type CGL, and the ISL in Embodiment 1, repetitive descriptions thereof are omitted.

The first electrode 101 includes an anode and the second electrode 102 includes a cathode in this embodiment. The first electrode 101 and the second electrode 102 may each be formed as a single-layer structure or a stacked-layer structure. In the case of the stacked-layer structure, a layer in contact with the organic compound layer 103 serves as an anode or a cathode. In the case where the electrodes each have the stacked-layer structure, there is no limitation on work functions of layers other than the layer in contact with the organic compound layer 103, and the materials can be selected in accordance with required properties such as a resistance value, processing easiness, reflectivity, light-transmitting property, and stability.

The anode is preferably formed using a metal, an alloy, a conductive compound, or a mixture thereof each having a high work function (specifically, higher than or equal to 4.0 eV), for example. Specific examples include indium oxide-tin oxide (ITO: Indium Tin Oxide), indium oxide-tin oxide containing silicon or silicon oxide (ITSO: Indium Tin Silicon Oxide), indium oxide-zinc oxide, and indium oxide containing tungsten oxide and zinc oxide (IWZO). Films of such conductive metal oxides are usually formed by a sputtering method, but may be fabricated by a sol-gel method or the like. An example of the fabrication method is a method in which indium oxide-zinc oxide is formed by a sputtering method using a target in which 1 to 20 wt % zinc oxide is added to indium oxide. Furthermore, indium oxide containing tungsten oxide and zinc oxide (IWZO) can be formed by a sputtering method using a target in which 0.5 to 5 wt % tungsten oxide and 0.1 to 1 wt % zinc oxide are added to indium oxide. Other examples of materials used for the anode include gold (Au), platinum (Pt), nickel (Ni), tungsten (W), chromium (Cr), molybdenum (Mo), iron (Fe), cobalt (Co), copper (Cu), palladium (Pd), titanium (Ti), aluminum (Al), and nitride of a metal material (e.g., titanium nitride). The anode may be a stack of layers of any of these materials. For example, a film in which Al, Ti, and ITSO are stacked in this order over Ti is preferable because the film has high efficiency owing to high reflectivity and enables a high resolution of several thousand ppi. Alternatively, graphene can also be used as a material for the anode. Note that when a composite material described later, which can be contained in the hole-injection layer 111, is used for a layer (typically, a hole-injection layer) that is in contact with the anode, an electrode material can be selected regardless of its work function.

The hole-injection layer 111 is provided in contact with the anode and has a function of facilitating injection of holes into the organic compound layer 103. The hole-injection layer 111 can be formed using phthalocyanine (abbreviation: H₂Pc) or a phthalocyanine-based compound or complex such as copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N-(3-methylphenyl)-N-phenylamino]phenyl}-N-phenylamino)biphenyl (abbreviation: DNTPD), a high molecular compound such as poly(3,4-ethylenedioxythiophene)/(polystyrenesulfonic acid) (abbreviation: PEDOT/PSS), or the like.

The hole-injection layer 111 may be formed using a substance having an electron-acceptor property. As the substance having an electron-accepting property, an organic compound having an electron-withdrawing group (a halogen group, a cyano group, or the like) can be used, and examples thereof include 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylen-1,3,4,5,6,8,9,10-octafluoro-7H-pyren-2-ylidene)malononitrile. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a significantly high electron-accepting property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an electron-accepting property, a transition metal oxide such as molybdenum oxide, vanadium oxide, ruthenium oxide, tungsten oxide, or manganese oxide can be used, other than the above-described organic compounds.

The hole-injection layer 111 is preferably formed using a composite material containing the above substance having an electron-accepting property and the organic compound having a hole-transport property.

As the organic compound having a hole-transport property used in the composite material, any of a variety of organic compounds such as aromatic amine compounds, heteroaromatic compounds, aromatic hydrocarbons, and high molecular compounds (e.g., oligomers, dendrimers, and polymers) can be used. Note that the organic compound having a hole-transport property used in the composite material is preferably an organic compound having a hole mobility of 1×10⁻⁶ cm²/Vs or higher. The organic compound having a hole-transport property used in the composite material is preferably a compound having a condensed aromatic hydrocarbon ring or a π-electron rich heteroaromatic ring. As the condensed aromatic hydrocarbon ring, an anthracene ring, a naphthalene ring, or the like is preferable. As the π-electron rich heteroaromatic ring, a condensed aromatic ring having at least one of a pyrrole skeleton, a furan skeleton, and a thiophene skeleton in the ring is preferable; specifically, a carbazole ring, a dibenzothiophene ring, or a ring in which an aromatic ring or a heteroaromatic ring is further condensed to a carbazole ring or a dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that includes a naphthalene ring, or an aromatic monoamine in which a 9-fluorenyl group is bonded to nitrogen of amine through an arylene group may be used. Note that the organic compound having a hole-transport property preferably a substance having an N,N-bis(4-biphenyl)amino group to enable fabricating a light-emitting device having a long lifetime.

Specific examples of the above-described organic compound having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

For another aromatic amine compound as the material having a hole-transport property, N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), or the like can also be used.

The formation of the hole-injection layer 111 can improve the hole-injection property, whereby a light-emitting device having a low driving voltage can be obtained.

Among substances having an electron-accepting property, an organic compound having an electron-accepting property is easy to use because it is easily formed as a film by vapor deposition.

The hole-transport layer 112 is formed to contain an organic compound having a hole-transport property. The organic compound having a hole-transport property preferably has a hole mobility of 1×10⁻⁶ cm²/Vs or higher.

Examples of the above-described material having a hole-transport property include a compound having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]-9,9′-spirobi[9H-fluoren]-2-amine (abbreviation: PCBASF); a compound having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 9,9′-diphenyl-9H,9′H-3,3′-bicarbazole (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-9H,9′H-3,3′-bicarbazole (abbreviation: PNCCP), 9-(3-biphenyl)-9′-(2-naphthyl)-3,3′-bi-9H-carbazole (abbreviation: PNCCmBP), 9-(4-biphenyl)-9′-(2-naphthyl)-3,3′-bi-9H-carbazole (abbreviation: RNCCBP), 9,9′-di-2-naphthyl-3,3′-9H,9′H-bicarbazole (abbreviation: BisPNCz), 9-(2-naphthyl)-9′-[1,1′:4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′:3′,1″-terphenyl]-5′-yl-3,3′-9H,9′H-bicarbazole, 9-(2-naphthyl)-9′-[1,1′:4′,1″-terphenyl]-4-yl-3,3′-9H,9′H-bicarbazole, 9-(2-naphthyl)-9′-[1,1′:3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′:3′,1″-terphenyl]-4-yl-3,3′-9H,9′H-bicarbazole, or 9-[4-(9-phenyl-9H-carbazol-3-yl)phenyl]phenanthrene (abbreviation: PCPPn); a compound having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above compounds, the compound having an aromatic amine skeleton and the compound having a carbazole skeleton are preferable because these compounds are highly reliable and have a high hole-transport property to contribute to a reduction in driving voltage. Note that any of the substances given as examples of the material having a hole-transport property used for the composite material for the hole-injection layer 111 can also be suitably used as the material contained in the hole-transport layer 112.

The light-emitting layer 113 is a layer containing a light-emitting substance and preferably contains a light-emitting substance and a host material. Note that the light-emitting layer may additionally contain other materials. Alternatively, the light-emitting layer may be a stack of two layers with different compositions.

The light-emitting substance may be a fluorescent substance, a phosphorescent substance, a substance exhibiting thermally activated delayed fluorescence (TADF), or another light-emitting substance.

Examples of the material that can be used as a fluorescent substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis[N,N,N′-triphenyl-1,4-phenylenediamine](abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N″″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-diphenyl-N,N′-(1,6-pyrene-diyl)bis[(6-phenylbenzo[b]naphtho[1,2-d]furan)-8-amine](abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Condensed aromatic diamine compounds typified by pyrenediamine compounds such as 1,6FLPAPrn, 1,6mMemFLPAPm, and 1,6BnfAPrn-03 are particularly preferable because of their high hole-trapping property, high emission efficiency, or high reliability. Condensed aromatic diamine compounds typified by pyrenediamine compounds such as 1,6FLPAPrn, 1,6mMemFLPAPrn, and 1,6BnfAPrn-03 are particularly preferable because of their high hole-trapping property, high emission efficiency, or high reliability.

A condensed heteroaromatic compound containing nitrogen and boron, especially a compound having a diaza-boranaphtho-anthracene skeleton, exhibits a narrow emission spectrum, emits blue light with high color purity, and can thus be suitably used. Examples of the compound include 5,9-diphenyl-5,9-diaza-13b-boranaphtho[3,2,1-de]anthracene (abbreviation: DABNA1), 9-(biphenyl-3-yl)-N,N,5,11-tetraphenyl-5H,9H-[1,4]benzazaborino[2,3,4-kl]phenazaborin-3-amine (abbreviation: DABNA2), 2,12-di(tert-butyl)-5,9-di(4-tert-butylphenyl)-N,N-diphenyl-5H,9H-[1,4]benzazaborino[2,3,4-kl]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H-[1,4]benzazaborino[2,3,4-kl]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-kl][1,4]benzazaborino[4′,3′,2′:4,5][1,4]benzazaborino[3,2-b]phenazaborine-7,13-diamine (abbreviation: v-DABNA), and 2-(4-tert-butylphenyl)benz[5,6]indolo[3,2,1-jk]benzo[b]carbazole (abbreviation: tBuPBibc).

Besides the above compounds, 9,10,11-tris[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-G), 9,11-bis[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-Y), or the like can be suitably used.

Examples of the material that can be used when a phosphorescent substance is used as the light-emitting substance in the light-emitting layer are as follows.

The examples include an organometallic iridium complex having a 4H-triazole skeleton, such as tris{2-[5-(2-methylphenyl)-4-(2,6-dimethylphenyl)-4H-1,2,4-triazol-3-yl-κN2]phenyl-κC}iridium(III) (abbreviation: [Ir(mpptz-dmp)₃]) or tris(5-methyl-3,4-diphenyl-4H-1,2,4-triazolato)iridium(III) (abbreviation: [Ir(Mptz)₃]); an organometallic iridium complex having a 1H-triazole skeleton, such as tris[3-methyl-1-(2-methylphenyl)-5-phenyl-TH-1,2,4-triazolato]iridium(III) (abbreviation: [Ir(Mptzl-mp)₃]) or tris(1-methyl-5-phenyl-3-propyl-TH-1,2,4-triazolato)iridium(III) (abbreviation: [Ir(Prptzl-Me)₃]); an organometallic iridium complex having an imidazole skeleton, such as fac-tris[1-(2,6-diisopropylphenyl)-2-phenyl-TH-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), or tris(2-{1-[2,6-bis(1-methylethyl)phenyl]-1H-imidazol-2-yl-kN3}-4-cyanophenyl-kC} (abbreviation: CNImIr); an organometallic complex having a benzimidazolidene skeleton, such as tris[(6-tert-butyl-3-phenyl-2H-imidazo[4,5-b]pyrazin-1-yl-κC2)phenyl-κC]iridium(III) (abbreviation: [Ir(cb)₃]); and an organometallic iridium complex in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), or bis[2-(4′,6′-difluorophenyl)pyridinato-N,C^{2′}]iridium(III) acetylacetonate (abbreviation: FIracac). These compounds exhibit blue phosphorescent light and have an emission peak in the wavelength range of 450 nm to 520 nm.

Other examples include an organometallic iridium complex having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), or (acetylacetonato)bis(4,6-diphenylpyrimidinato)iridium(III) (abbreviation: [Ir(dppm)₂(acac)]); an organometallic iridium complex having a pyrazine skeleton, such as (acetylacetonato)bis(3,5-dimethyl-2-phenylpyrazinato)iridium(III) (abbreviation: [Ir(mppr-Me)₂(acac)]) or (acetylacetonato)bis(5-isopropyl-3-methyl-2-phenylpyrazinato)iridium(III) (abbreviation: [Ir(mppr-iPr)₂(acac)]); an organometallic iridium complex having a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), [2-d3-methyl-8-(2-pyridinyl-κN)benzofuro[2,3-b]pyridine-κC]bis[2-(5-d3-methyl-2-pyridinyl-κN2)phenyl-κC]iridium(III) (abbreviation: [Ir(5mppy-d₃)₂(mbfpypy-d₃)]), [2-d₃-methyl-(2-pyridinyl-KN)benzofuro[2,3-b]pyridine-κC]bis[2-(2-pyridinyl-κN)phenyl-κC]iridium(III) (abbreviation: [Ir(ppy)₂(mbfpypy-d₃)]), [2-(4-d3-methyl-5-phenyl-2-pyridinyl-κN2)phenyl-κC]bis[2-(5-d3-methyl-2-pyridinyl-κN2)phenyl-κC]iridium(III) (abbreviation: [Ir(5mppy-d₃)₂(mdppy-d₃)]), [2-methyl-(2-pyridinyl-κN)benzofuro[2,3-b]pyridine-κC]bis[2-(2-pyridinyl-N)phenyl-κC]iridium(III) (abbreviation: [Ir(ppy)₂(mbfpypy)]), or [2-(4-methyl-5-phenyl-2-pyridinyl-κN)phenyl-κC]bis[2-(2-pyridinyl-κN)phenyl-κC]iridium (abbreviation: [Ir(ppy)₂(mdppy)]); and a rare earth metal complex such as tris(acetylacetonato)(monophenanthroline)terbium(III) (abbreviation: [Tb(acac)3(Phen)]). These compounds mainly exhibit green phosphorescent light and have an emission peak in the wavelength range of 500 nm to 600 nm. Note that organometallic iridium complexes having a pyrimidine skeleton have distinctively high reliability or emission efficiency and thus are particularly preferable.

Other examples include an organometallic iridium complex having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), or bis[4,6-di(naphthalen-1-yl)pyrimidinato](dipivaloylmethanato)iridium(III) (abbreviation: [Ir(d1npm)₂(dpm)]); an organometallic iridium complex having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), or (acetylacetonato)bis[2,3-bis(4-fluorophenyl)quinoxalinato]iridium(III) (abbreviation: [Ir(Fdpq)₂(acac)]); an organometallic iridium complex having a pyridine skeleton, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), (3,7-diethyl-4,6-nonanedionato-κO4,κO6)bis[2,4-dimethyl-6-[7-(1-methylethyl)-1-isoquinolinyl-κN]phenyl-κC]iridium(III), or (3,7-diethyl-4,6-nonanedionato-κO4,κO6)bis[2,4-dimethyl-6-[5-(1-methylethyl)-2-quinolinyl-κN]phenyl-κC]iridium(III); a platinum complex such as 2,3,7,8,12,13,17,18-octaethyl-21H,23H-porphyrinplatinum(II) (abbreviation: PtOEP); and a rare earth metal complex such as tris(1,3-diphenyl-1,3-propanedionato)(monophenanthroline)europium(III) (abbreviation: [Eu(DBM)₃(Phen)]) or tris[1-(2-thenoyl)-3,3,3-trifluoroacetonato](monophenanthroline)europium(III) (abbreviation: [Eu(TTA)₃(Phen)]). These compounds exhibit red phosphorescent light and have an emission peak in the wavelength range of 600 nm to 700 nm. Organometallic iridium complexes having a pyrazine skeleton can provide red light emission with favorable chromaticity.

Besides the above-described phosphorescent compounds, known phosphorescent compounds may be selected and used.

As the TADF material, a fullerene, a derivative thereof, an acridine, a derivative thereof, an eosin derivative, or the like can be used. Furthermore, a metal-containing porphyrin, such as a porphyrin containing magnesium (Mg), zinc (Zn), cadmium (Cd), tin (Sn), platinum (Pt), indium (In), or palladium (Pd), can be given as an example. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

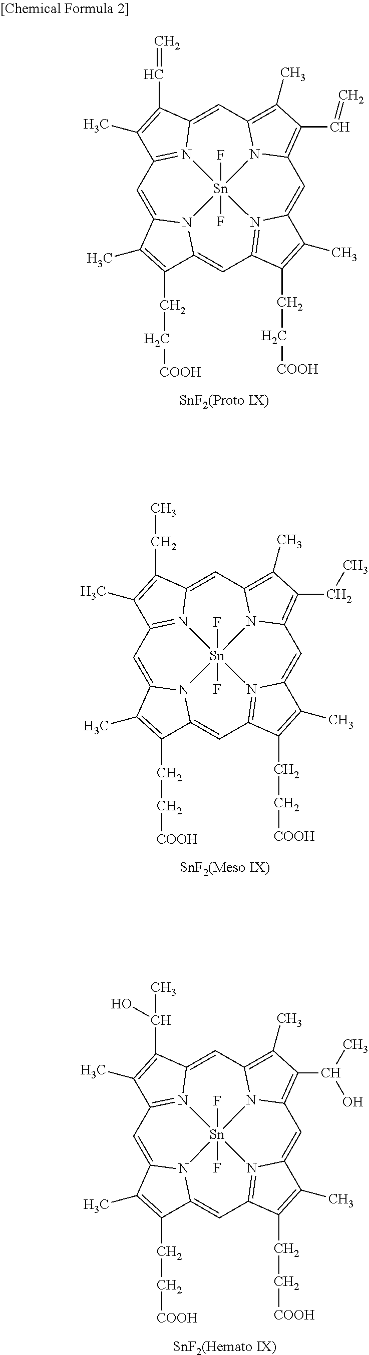

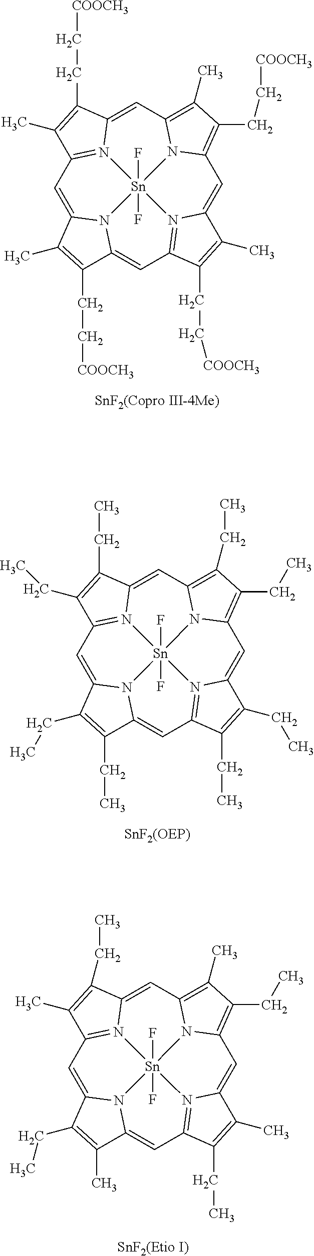

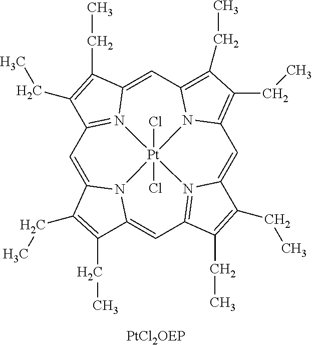

Alternatively, a heterocyclic compound having one or both of a π-electron rich heteroaromatic ring and a π-electron deficient heteroaromatic ring that is represented by the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA) can be used. Such a heterocyclic compound is preferable because of having excellent electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high electron-accepting property and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. Note that a dibenzofuran skeleton and a dibenzothiophene skeleton are preferable as a furan skeleton and a thiophene skeleton, respectively. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferable because the electron-donating property of the π-electron rich heteroaromatic ring and the electron-accepting property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring having a cyano group or a nitrile group such as benzonitrile or cyanobenzene, a heteroaromatic ring, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

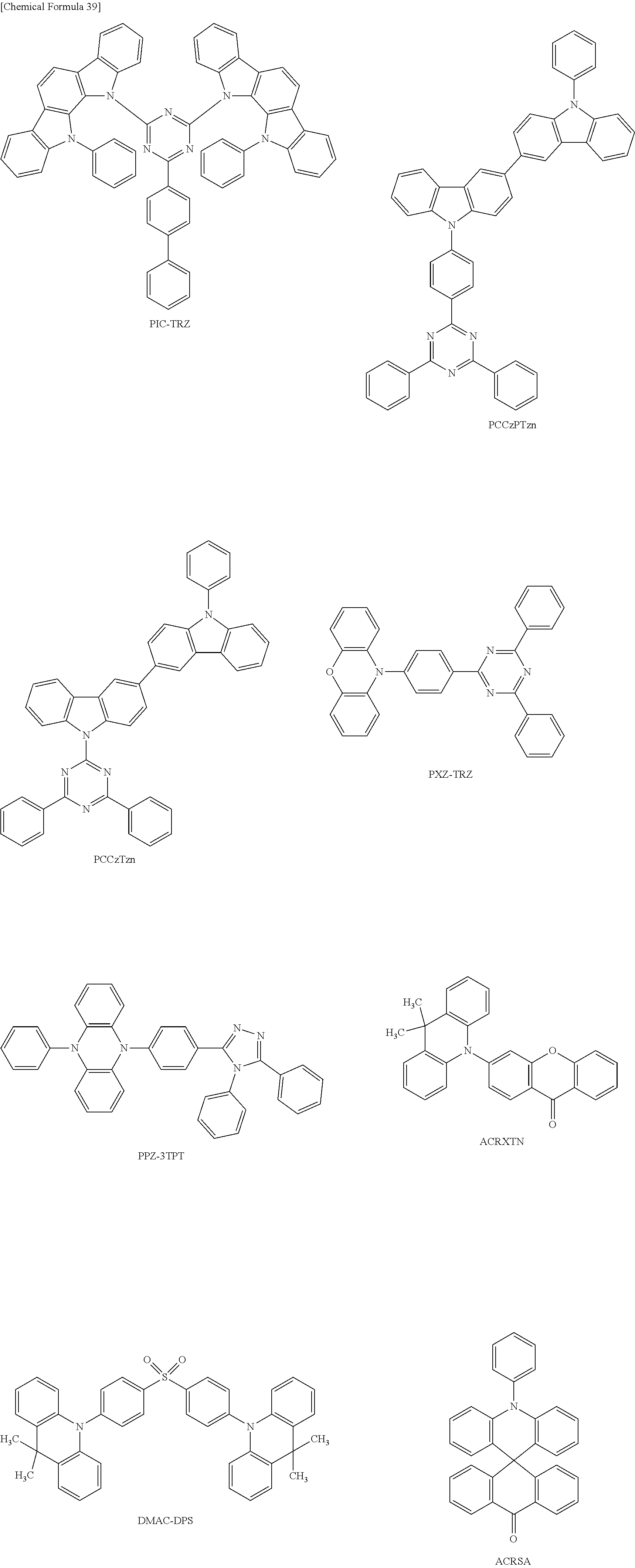

Note that the TADF material is a material having a small difference between the S₁ level and the T₁ level and having a function of converting triplet excitation energy into singlet excitation energy by reverse intersystem crossing. Thus, it is possible to upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small difference between the S₁ level and the T₁ level and has a function of the TADF material capable of converting triplet excitation energy into singlet excitation energy.

Note that a phosphorescence spectrum observed at a low temperature (e.g., 77 K to 10 K) is used for an index of the T₁ level. When the level of energy with a wavelength of a line obtained by extrapolating a tangent to the fluorescence spectrum at a tail on the short wavelength side is the S₁ level and the level of energy with a wavelength of a line obtained by extrapolating a tangent to the phosphorescence spectrum at a tail on the short wavelength side is the T₁ level, the difference between the S₁ level and the T₁ level of the TADF material is preferably smaller than or equal to 0.3 eV, further preferably smaller than or equal to 0.2 eV.

When the TADF material is used as the light-emitting substance, the S₁ level of the host material is preferably higher than the S₁ level of the TADF material. In addition, the T₁ level of the host material is preferably higher than the T₁ level of the TADF material.

As the host material in the light-emitting layer, various carrier-transport materials such as materials having an electron-transport property and/or materials having a hole-transport property, and the TADF materials can be used.

The material having a hole-transport property is preferably an organic compound having an amine skeleton, a π-electron rich heteroaromatic ring skeleton, or the like. As the Tn-electron rich heteroaromatic ring, a condensed aromatic ring having at least one of an acridine skeleton, a phenoxazine skeleton, a phenothiazine skeleton, a furan skeleton, a thiophene skeleton, and a pyrrole skeleton in the ring is preferable; specifically, a carbazole ring, a dibenzothiophene ring, or a ring in which an aromatic ring or a heteroaromatic ring is further condensed to the carbazole ring or the dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that includes a naphthalene ring, or an aromatic monoamine in which a 9-fluorenyl group is bonded to nitrogen of amine through an arylene group may be used. Note that the organic compound having a hole-transport property preferably a substance having an N,N′-bis(4-biphenyl)amino group to enable fabricating a light-emitting device having a long lifetime.

Examples of such an organic compound include a compound having an aromatic amine skeleton, such as 4,4′-bis[N-(1-naphthyl)-N-phenylamino]biphenyl (abbreviation: NPB), N,N′-diphenyl-N,N′-bis(3-methylphenyl]-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]-9,9′-spirobi[9H-fluoren]-2-amine (abbreviation: PCBASF); a compound having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 9,9′-diphenyl-9H,9′H-3,3′-bicarbazole (abbreviation: PCCP); a compound having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above compounds, the compound having an aromatic amine skeleton and the compound having a carbazole skeleton are preferable because these compounds are highly reliable and have a high hole-transport property to contribute to a reduction in driving voltage. In addition, the organic compounds given as examples of the material having a hole-transport property that can be used for the hole-transport layer can also be used.

As the material having an electron-transport property, for example, a metal complex such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound having a π-electron deficient heteroaromatic ring is preferable. Examples of the organic compound having a π-electron deficient heteroaromatic ring skeleton include an organic compound that has a heteroaromatic ring having a polyazole skeleton, an organic compound that has a heteroaromatic ring having a pyridine skeleton, an organic compound that has a heteroaromatic ring having a diazine skeleton, and an organic compound that has a heteroaromatic ring having a triazine skeleton.

Among the above organic compounds, the organic compound that has a heteroaromatic ring having a diazine skeleton (a pyrimidine skeleton, a pyrazine skeleton, or a pyridazine skeleton), the organic compound that has a heteroaromatic ring having a pyridine skeleton, and the organic compound that has a heteroaromatic ring having a triazine skeleton are preferable because of their high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high electron-accepting property and high reliability.

Examples of the organic compound having a π-electron deficient heteroaromatic ring skeleton include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound having a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: Bphen), bathocuproine (abbreviation: BCP), 2,9-di(naphthalen-2-yl)-4,7-diphenyl-1,10-phenanthroline (abbreviation: NBphen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), or 2-[4-(2-triphenylenyl)phenyl]-1,10-phenanthroline (abbreviation: pTpPPhen); an organic compound having a diazine skeleton, such as 2-[3-(dibenzothiophen-4-yl)phenyl]dibenzo[f,h]quinoxaline (abbreviation: 2mDBTPDBq-II), 2-[3-(3′-dibenzothiophen-4-yl)biphenyl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[(3′-dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP-PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); and an organic compound having a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), or 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn). The organic compound having a heteroaromatic ring having a diazine skeleton, the organic compound having a heteroaromatic ring having a pyridine skeleton, and the organic compound having a heteroaromatic ring having a triazine skeleton have high reliability and thus are preferable. In particular, the organic compound having a heteroaromatic ring having a diazine (pyrimidine or pyrazine) skeleton and the organic compound having a heteroaromatic ring having a triazine skeleton have a high electron-transport property to contribute to a reduction in driving voltage.

As the TADF material that can be used as the host material, any of the materials given above as examples of the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S₁ level of the TADF material is preferably higher than the S₁ level of the fluorescent substance in order that high emission efficiency be achieved. Furthermore, the T₁ level of the TADF material is preferably higher than the S₁ level of the fluorescent substance. Thus, the T₁ level of the TADF material is preferably higher than the T₁ level of the fluorescent substance.

It is also preferable to use a TADF material that emits light whose wavelength overlaps with the wavelength of the lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protecting group around a luminophore (a skeleton which causes light emission) of the fluorescent substance. As the protecting group, a substituent having no π bond and a saturated hydrocarbon are preferable. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protecting groups. The substituents having no π bond are poor in carrier-transport performance; thus, the TADF material and the luminophore of the fluorescent substance can be made away from each other with little influence on carrier transportation or carrier recombination. Here, the luminophore refers to an atomic group (skeleton) that causes light emission in a fluorescent substance. The luminophore is preferably a skeleton having a π bond, further preferably has an aromatic ring, and still further preferably has a condensed aromatic ring or a condensed heteroaromatic ring. Examples of the luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an anthracene skeleton is suitably used as the host material. The use of a substance having an anthracene skeleton as the host material for the fluorescent substance makes it possible to obtain a light-emitting layer with high emission efficiency and high durability. As the substance having an anthracene skeleton that is used as the host material, a substance having a diphenylanthracene skeleton, in particular, a substance having a 9,10-diphenylanthracene skeleton, is chemically stable and thus is preferable. The host material preferably has a carbazole skeleton, in which case the hole-injection and hole-transport properties are improved; further preferably, the host material has a benzocarbazole skeleton in which a benzene ring is further condensed to a carbazole skeleton, in which case the HOMO level thereof is shallower than that of the host material having a carbazole skeleton by approximately 0.1 eV and thus holes enter the host material easily. In particular, the host material preferably has a dibenzocarbazole skeleton, in which case the HOMO level thereof is shallower than that of the host material having a carbazole skeleton by approximately 0.1 eV, so that holes enter the host material easily, the hole-transport property is improved, and the heat resistance is increased. Accordingly, a substance that has both a 9,10-diphenylanthracene skeleton and a carbazole skeleton (or a benzocarbazole skeleton or a dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: αN-βNPAnth), 9-(1-naphthyl)-10-(2-naphthyl)anthracene (abbreviation: α,βADN), 2-(10-phenylanthracen-9-yl)dibenzofuran, 2-(10-phenyl-9-anthracenyl)benzo[b]naphtho[2,3-d]furan (abbreviation: Bnf(II)PhA), 9-(2-naphthyl)-10-[3-(2-naphthyl)phenyl]anthracene (abbreviation: PN-mPNPAnth), and 1-{4-[10-(biphenyl-4-yl)-9-anthracenyl]phenyl}-2-ethyl-1H-benzimidazole (abbreviation: EtBImPBPhA). In particular, CzPA, cgDBCzPA, 2mBnfPPA, and PCzPA are preferably selected because they exhibit highly favorable characteristics.

Note that the host material may be a mixture of a plurality of kinds of substances; in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The weight ratio of the content of the material having a hole-transport property to the content of the material having an electron-transport property may be 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

An exciplex may be formed of these mixed materials. These mixed materials are preferably selected so as to form an exciplex that exhibits light emission whose wavelength overlaps with the wavelength of the lowest-energy-side absorption band of the light-emitting substance, in which case energy can be transferred smoothly and light emission can be obtained efficiently. The use of such a structure is preferable because the driving voltage can also be reduced.

Note that at least one of the materials forming an exciplex may be a phosphorescent substance. In this case, triplet excitation energy can be efficiently converted into singlet excitation energy by reverse intersystem crossing.

A combination of a material having an electron-transport property and a material having a hole-transport property whose HOMO level is higher than or equal to the HOMO level of the material having an electron-transport property is preferable for forming an exciplex efficiently. In addition, the LUMO level of the material having a hole-transport property is preferably higher than or equal to the LUMO level of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

Note that the formation of an exciplex can be confirmed by a phenomenon in which the emission spectrum of the mixed film in which the material having a hole-transport property and the material having an electron-transport property are mixed is shifted to the longer wavelength side than the emission spectrum of each of the materials (or has another peak on the longer wavelength side) observed by comparison of the emission spectrum of the material having a hole-transport property, the emission spectrum of the material having an electron-transport property, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than the transient PL lifetime of each of the materials, observed by comparison of the transient PL of the material having a hole-transport property, the transient PL of the material having an electron-transport property, and the transient PL of the mixed film of these materials. The transient PL can be rephrased as transient electroluminescence (EL). That is, the formation of an exciplex can also be confirmed by a difference in transient response observed by comparison of the transient EL of the material having a hole-transport property, the transient EL of the material having an electron-transport property, and the transient EL of the mixed film of these materials.

The first electron-transport layer 114_1 and the second electron-transport layer 114_2 are each a layer including a material having an electron-transport property. The material having an electron-transport property is preferably a substance having an electron mobility higher than or equal to 1×10⁻⁷ cm²/Vs, further preferably higher than or equal to 1×10⁻⁶ cm²/Vs in the case where the square root of the electric field strength [V/cm] is 600. Note that any other substance can also be used as long as the substance has an electron-transport property higher than a hole-transport property. Note that an organic compound having a π-electron deficient heteroaromatic ring is preferable as the above organic compound. The organic compound having a π-electron deficient heteroaromatic ring skeleton is preferably one or more of an organic compound that has a heteroaromatic ring having a polyazole skeleton, an organic compound that has a heteroaromatic ring having a pyridine skeleton, an organic compound that has a heteroaromatic ring having a diazine skeleton, and an organic compound that has a heteroaromatic ring having a triazine skeleton, for example.

As the organic compounds having an electron-transport property that can be used in the first electron-transport layer 114_1 and the second electron-transport layer 114_2, the aforementioned organic compound that can be used as the organic compound having an electron-transport property in the first light-emitting layer 1131 and the second light-emitting layer 113_2 can be used. Among the above materials, the organic compound that has a heteroaromatic ring having a diazine skeleton, the organic compound that has a heteroaromatic ring having a pyridine skeleton, and the organic compound that has a heteroaromatic ring having a triazine skeleton are preferable because of their high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. An organic compound having a phenanthroline skeleton, such as mTpPPhen, PnNPhen, or mPPhen2P, is especially preferable, and an organic compound having a phenanthroline dimer structure, such as mPPhen2P, is further preferable because of its excellent stability.

The first electron-transport layer 114_1 preferably has a bipolar property, that is, is preferably an electron-transport layer having a relatively high hole-transport property. Accordingly, the HOMO level of the organic compound contained in the first electron-transport layer 114_1 is preferably greater than or equal to −5.90 eV and less than or equal to −5.00 eV, further preferably greater than or equal to −5.80 eV and less than or equal to −5.00 eV, still further preferably greater than or equal to −5.70 eV and less than or equal to −5.15 eV. Since the first electron-transport layer also needs to have a high electron-transport property as a matter of course, the LUMO level of the organic compound contained in the electron-transport layer is preferably greater than or equal to −3.15 eV and less than or equal to −2.50 eV, further preferably greater than or equal to −3.00 eV and less than or equal to −2.70 eV.

The first electron-transport layer 114_1 may be a layer formed of a plurality of organic compounds. In the case where a plurality of organic compounds are contained in the first electron-transport layer, the HOMO level of the organic compound having the highest HOMO level is preferably within the above-described range. In the case where a plurality of organic compounds are contained in the first electron-transport layer, the LUMO level of the organic compound having the lowest LUMO level is preferably within the above-described range. In the case where the first electron-transport layer is formed of a plurality of organic compounds, at least one of the organic compounds is preferably an organic compound having an electron-transport property and at least one of the organic compounds is preferably an organic compound having a hole-transport property.

Note that the electron-transport organic compound and the hole-transport organic compound are preferably a single organic compound. In other words, it is preferable that the first electron-transport layer contain an organic compound having both an electron-transport property and a hole-transport property because of facilitating formation of a light-emitting device with favorable characteristics.

The organic compound having an electron-transport property or the organic compound having both an electron-transport property and a hole-transport property is preferably a substance having an electron mobility higher than or equal to 1×10⁷ cm²/Vs, further preferably higher than or equal to 1×10⁻⁶ cm²/Vs in the case where the square root of the electric field strength [V/cm] is 600. The organic compound having a hole-transport property or the organic compound having both an electron-transport property and a hole-transport property is preferably a substance having a hole mobility higher than or equal to 1×10⁻⁷ cm²/Vs, further preferably higher than or equal to 1×10⁻⁶ cm²/Vs in the case where the square root of the electric field strength [V/cm] is 600.

The first electron-transport layer preferably contains an organic compound having an electron-transport property with an acid dissociation constant pKa of 4 or less.

The first electron-transport layer preferably contains an organic compound having an electron-transport skeleton and an organic compound having a hole-transport skeleton. Note that the organic compound having an electron-transport skeleton and the organic compound having a hole-transport skeleton are preferably a single organic compound. In other words, it is preferable that the first electron-transport layer contain an organic compound having both an electron-transport skeleton and a hole-transport skeleton because of facilitating formation of a light-emitting device with favorable characteristics.

The first electron-transport layer 114_1 and the second electron-transport layer 114_2 may each have a stacked-layer structure. In the case where the first electron-transport layer 114_1 has a stacked-layer structure, all the stacked layers preferably have the structure described in Embodiment 1. In the case where the second electron-transport layer 114_2 has a stacked-layer structure, the layer in contact with the second light-emitting layer 113_2 may function as a hole-blocking layer. In the case where the electron-transport layer in contact with the light-emitting layer functions as a hole-blocking layer, the electron-transport layer is preferably formed using a material having a deeper HOMO level than the HOMO level of a material contained in the light-emitting layer by more than or equal to 0.5 eV.

A layer including an alkali metal, an alkaline earth metal, or a compound thereof such as lithium oxide (Li₂O), lithium fluoride (LiF), cesium fluoride (CsF), calcium fluoride (CaF₂), or 8-hydroxyquinolinato-lithium (Liq) may be provided as the electron-injection layer 115 between the second electron-transport layer 114_2 and the second electrode 102. An electride or a layer that is formed using a substance having an electron-transport property and that contains an alkali metal, an alkaline earth metal, or a compound thereof may be used as the electron-injection layer 115. Examples of the electride include a substance in which electrons are added at high concentration to calcium oxide-aluminum oxide. The organic compounds given as examples of the strongly basic organic compound in Embodiment 1 can be used.

The electron-injection layer 115 may be formed using any of the above substances alone, or any of the above substances contained in a layer containing a substance having an electron-transport property.

Note that as the electron-injection layer 115, it is possible to use a layer that contains a substance having an electron-transport property (preferably an organic compound having a bipyridine skeleton) and including a fluoride of the alkali metal or the alkaline earth metal at a concentration higher than or equal to that at which the electron-injection layer 115 becomes in a microcrystalline state (50 wt % or higher). Since the layer has a low refractive index, a light-emitting device having higher external quantum efficiency can be provided.

The second electrode 102 is an electrode including a cathode. The second electrode 102 may have a stacked-layer structure, in which case a layer in contact with the organic compound layer 103 functions as a cathode. As a substance for forming the cathode, a metal, an alloy, an electrically conductive compound, or a mixture thereof each having a low work function (specifically, lower than or equal to 3.8 eV) or the like can be used. Specific examples of such a cathode material include elements belonging to Group 1 or Group 2 of the periodic table, e.g., alkali metals such as lithium (Li) and cesium (Cs), magnesium (Mg), calcium (Ca), and strontium (Sr), alloys containing these elements (such as MgAg and AlLi), compounds containing these elements (such as lithium fluoride (LiF), cesium fluoride (CsF), and calcium fluoride (CaF₂)), rare earth metals such as europium (Eu) and ytterbium (Yb), and alloys containing these rare earth metals. However, when the electron-injection layer 115 or a thin film including any of the above materials with a low work function is provided between the second electrode 102 and the electron-transport layer, a variety of conductive materials such as Al, Ag, ITO, and indium oxide-tin oxide containing silicon or silicon oxide can be used for the cathode regardless of the work function.

In the case where the second electrode 102 is formed using a material having a visible light transmitting property, the light-emitting device can emit light from the second electrode 102 side. In the case where the first electrode 101 is formed using a material having a visible light transmitting property, the light-emitting device can emit light from the first electrode 101 side.

Films of these conductive materials can be formed by a dry process such as a vacuum evaporation method or a sputtering method, an ink-jet method, a spin coating method, or the like. Alternatively, a wet process using a sol-gel method or a wet process using a paste of a metal material may be employed for the formation.

Any of a variety of methods can be used for forming the organic compound layer 103, regardless of whether it is a dry process or a wet process. For example, a vacuum evaporation method, a gravure printing method, an offset printing method, a screen printing method, an ink-jet method, a spin coating method, or the like may be used.

Different film formation methods may be used to form the electrodes or the layers described above.

The light-emitting device having two light-emitting units is described with reference to FIG. 3; however, the same can also be applied to a light-emitting device in which three or more light-emitting units are stacked. With a plurality of light-emitting units partitioned by the intermediate layer 116 between a pair of electrodes as in the light-emitting device of this embodiment, it is possible to provide a long-life element that can emit high-luminance light with the current density kept low. A light-emitting apparatus that can be driven at a low voltage and has low power consumption can be achieved.

When the emission colors of the light-emitting units are different, light emission of a desired color can be obtained from the light-emitting device as a whole. For example, in a light-emitting device having two light-emitting units, the emission colors of the first light-emitting unit may be red and green and the emission color of the second light-emitting unit may be blue, so that the light-emitting device can emit white light as the whole.

The organic compound layer 103, the first light-emitting unit 501, the second light-emitting unit 502, and the layers such as the charge-generation layer, and the electrodes that are described above can be formed by a method such as an evaporation method (including a vacuum evaporation method), a droplet discharge method (also referred to as an ink-jet method), a coating method, or a gravure printing method, for example. A low molecular material, a middle molecular material (including an oligomer and a dendrimer), or a high molecular material may be contained in the above components.

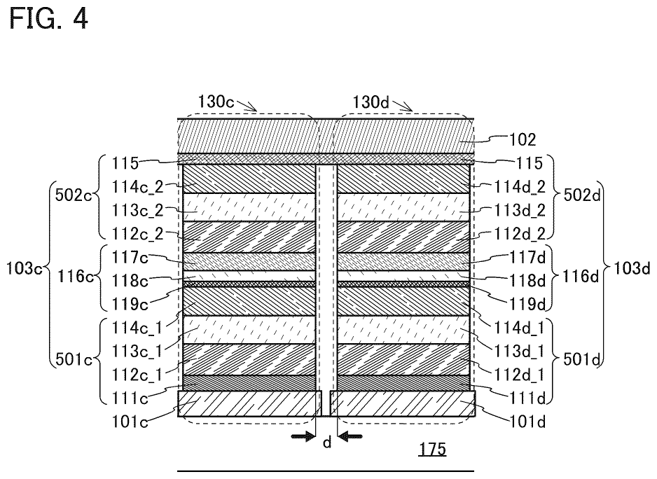

FIG. 4 illustrates a diagram of two adjacent tandem light-emitting devices (a light-emitting device 130c and a light-emitting device 130d) fabricated by a photolithography method.

The light-emitting device 130c includes an organic compound layer 103c between a first electrode 101c and the second electrode 102 over the insulating layer 175. The organic compound layer 103c has a structure in which a first light-emitting unit 501c and a second light-emitting unit 502c are stacked with an intermediate layer 116c therebetween. Although two light-emitting units are stacked in the example illustrated in FIG. 4, three or more light-emitting units may be stacked. The first light-emitting unit 501c includes a hole-injection layer 111c, a first hole-transport layer 112c_1, a first light-emitting layer 113c_1, and a first electron-transport layer 114c_1. The intermediate layer 116c includes a third layer 117c, a second layer 118c, and a first layer 119c. The second light-emitting unit 502c includes a second hole-transport layer 112c_2, a second light-emitting layer 113c_2, a second electron-transport layer 114c_2, and an electron-injection layer 115.

The light-emitting device 130d includes an organic compound layer 103d between a first electrode 101d and the second electrode 102 over the insulating layer 175. The organic compound layer 103d has a structure in which a first light-emitting unit 501d and a second light-emitting unit 502d are stacked with an intermediate layer 116d therebetween. Although two light-emitting units are stacked in the example illustrated in FIG. 4, three or more light-emitting units may be stacked. The first light-emitting unit 501d includes a hole-injection layer 111d, a first hole-transport layer 112d_1, a first light-emitting layer 113d_1, and a first electron-transport layer 114d_1. The intermediate layer 116d includes a third layer 117d, a second layer 118d, and a first layer 119d. The second light-emitting unit 502d includes a second hole-transport layer 112d_2, a second light-emitting layer 113d_2, a second electron-transport layer 114d_2, and an electron-injection layer 115.

In the light-emitting device 130c and the light-emitting device 130d, the intermediate layer 116c, the intermediate layer 116d, the first electron-transport layer 114c_1, and the first electron-transport layer 114d_1 preferably have the structures described in Embodiment 1.

Note that the electron-injection layer 115 and the second electrode 102 are each preferably one continuous layer shared by the light-emitting device 130c and the light-emitting device 130d. The organic compound layer 103c and the organic compound layer 103d, except for the electron-injection layer 115, are independent of each other because processing by a photolithography method is performed after the second electron-transport layer 114c_2 and the second electron-transport layer 114c_2 are formed. End portions (outlines) in the organic compound layer 103c except for the electron-injection layer 115 are substantially aligned with each other in the direction perpendicular to the substrate because of processing by a photolithography method. End portions (outlines) in the organic compound layer 103d except for the electron-injection layer 115 are substantially aligned with each other in the direction perpendicular to the substrate because of processing by a photolithography method.

The space d is present between the organic compound layer 103c and the organic compound layer 103d because of processing by a photolithography method. Since the organic compound layers are processed by a photolithography method, the distance between the first electrode 101c and the first electrode 101d can be made small, greater than or equal to 2 μm and less than or equal to 5 μm, compared with the case where mask vapor deposition is performed.

The light-emitting device of one embodiment of the present invention having the above-described structure can have high current efficiency, high reliability, and a suppressed increase in driving voltage.

The existence of the second layer 118 that is the ISL can inhibit a reduction in reliability and allows a highly reliable light-emitting device to be provided.

Note that the light-emitting device of one embodiment of the present invention is particularly suitable for a light-emitting device fabricated through a photolithography process and also contributes to cost reduction in fabrication of light-emitting devices not through a photolithography process because high stability in atmospheric air increases yield and eliminates the need for too strictly managing the atmosphere in the fabrication process.

### Embodiment 3

Described in this embodiment is a mode in which the light-emitting device of one embodiment of the present invention is used as a display element of a display apparatus.

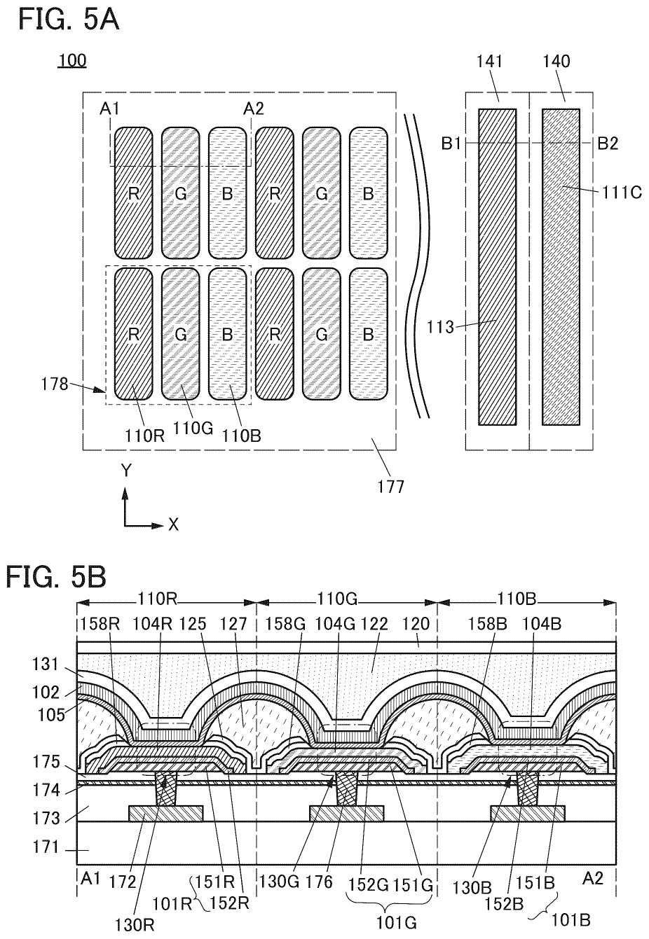

As illustrated in FIG. 5A and FIG. 5B, a plurality of light-emitting devices 130 are formed over the insulating layer 175 to constitute a display apparatus.

A display apparatus includes a pixel portion 177 in which a plurality of pixels 178 are arranged in matrix. The pixel 178 includes a subpixel 110R, a subpixel 110G, and a subpixel 110B.

In this specification and the like, for example, description common to the subpixel 110R, the subpixel 110G, and the subpixel 110B is sometimes made using the term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 1101B emits blue light. Thus, an image can be displayed on the pixel portion 177. Note that in this embodiment, description is made using subpixels of three colors of red (R), green (G), and blue (B) as examples; however, subpixels of a different combination of colors may be employed. The number of subpixels is not limited to three, and may be four or more. Examples of four subpixels include subpixels of four colors of R, G, B, and white (W), subpixels of four colors of R, G, B, and Y, and four subpixels of R, G, B, and infrared light (IR).

In this specification and the like, the row direction and the column direction are sometimes referred to as the X direction and the Y direction, respectively. The X direction and the Y direction intersect with each other and are perpendicular to each other, for example.

FIG. 5A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. The region 141 is provided between the pixel portion 177 and the connection portion 140. The organic compound layer 103 is provided in the region 141. A conductive layer 151C is provided in the connection portion 140.

Although FIG. 5A illustrates an example where the region 141 and the connection portion 140 are positioned on the right side of the pixel portion 177, the positions of the region 141 and the connection portion 140 are not particularly limited. The number of regions 141 and the number of connection portions 140 can each be one or more.

FIG. 5B is an example of a cross-sectional view along the dashed-dotted line A1-A2 in FIG. 5A. As illustrated in FIG. 5A, the display apparatus includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layer 175, the insulating layer 174, and the insulating layer 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 is bonded to the protective layer 131 with a resin layer 122. An inorganic insulating layer 125 and an insulating layer 127 over the inorganic insulating layer 125 are preferably provided between the adjacent light-emitting devices 130.

Although FIG. 5B shows cross sections of a plurality of the inorganic insulating layers 125 and a plurality of the insulating layers 127, the inorganic insulating layers 125 are preferably connected to each other and the insulating layers 127 are preferably connected to each other when the display apparatus is seen from above. In other words, the insulating layer 127 is preferably an insulating layer having an opening portion over a first electrode.

In FIG. 5B, a light-emitting device 130R, a light-emitting device 130G, and a light-emitting device 130B are illustrated as the light-emitting devices 130. The light-emitting device 130R, the light-emitting device 130G, and the light-emitting device 130B emit light of different colors. For example, the light-emitting device 130R can emit red light, the light-emitting device 130G can emit green light, and the light-emitting device 130B can emit blue light. Alternatively, the light-emitting device 130R, the light-emitting device 130G, or the light-emitting device 130B may emit visible light of another color or infrared light.

The display apparatus of one embodiment of the present invention can be, for example, a top-emission display apparatus where light is emitted in the direction opposite to a substrate over which light-emitting devices are formed. Note that the display apparatus of one embodiment of the present invention may be of a bottom emission type.

The light-emitting device 130R has the structure described in Embodiment 1 and Embodiment 2. The light-emitting device 130R includes a first electrode 101R (pixel electrode) including a conductive layer 151R and a conductive layer 152R, a first EL layer 104R over the first electrode 101R, an organic compound layer (a second EL layer 105 over the first EL layer 104R), and the second electrode 102 (common electrode) 102 over the second EL layer 105. The second EL layer 105 is preferably positioned closer to the second electrode 102 (common electrode) side than the light-emitting layer is, and is preferably a hole-block layer, a second electron-transport layer, an electron-injection layer, or stacked layers thereof. Such a structure can reduce damage to the light-emitting layer or an active layer during a photolithography process, which promises favorable film quality and electrical characteristics. Furthermore, a plurality of layers such as an electron-injection layer may be provided as common layers in contact with the second electrode 102 (common electrode).

The light-emitting device 130G has the structure described in Embodiment 1 and Embodiment 2. The light-emitting device 130G includes a first electrode 101G (pixel electrode) including a conductive layer 151G and a conductive layer 152G, a first EL layer 104G over the first electrode 1G, the second EL layer 105 over the first EL layer 104G, and the second electrode 102 (common electrode) over the second EL layer 105. The second EL layer 105 is preferably a hole-block layer, a second electron-transport layer, an electron-injection layer, or stacked layers thereof.

The light-emitting device 130B has the structure described in Embodiment 1 and Embodiment 2. The light-emitting device 130B includes a first electrode 101B (pixel electrode) including a conductive layer 151B and a conductive layer 152B, a first EL layer 104B over the first electrode 101B, the second EL layer 105 over the first EL layer 104B, and the second electrode 102 (common electrode) over the second EL layer 105. The second EL layer 105 is preferably a hole-block layer, a second electron-transport layer, an electron-injection layer, or stacked layers thereof.

In the light-emitting device, one of the pixel electrode (first electrode) and the common electrode (second electrode) functions as an anode and the other functions as a cathode. In this embodiment, description is made on the assumption that the pixel electrode functions as the anode and the common electrode functions as the cathode unless otherwise specified.

The first EL layer 104R, the first EL layer 104G, and the first EL layer 104B are island-shaped layers that are independent of each other; alternatively, a first EL layer of the light-emitting devices of one emission color may be independent of a first EL layer of the light-emitting devices of another emission color. Note that it is preferable that the first EL layer 104R, the first EL layer 104G, and the first EL layer 104B not overlap with one another. Providing the island-shaped first EL layer 104 in each of the light-emitting devices 130 can suppress leakage current between the adjacent light-emitting devices 130 even in a high-resolution display apparatus. This can prevent crosstalk, so that a display apparatus with extremely high contrast can be obtained. Specifically, a display apparatus having high current efficiency at low luminance can be obtained.

The island-shaped first EL layer 104 is formed by forming an EL film and processing the EL by a photolithography method.

The first EL layer 104 is preferably provided to cover the top surface and the side surface of the first electrode 101 (pixel electrode) of the light-emitting device 130. In this case, the aperture ratio of the display apparatus can be easily increased as compared to the structure where an end portion of the first EL layer 104 is positioned inward from an end portion of the pixel electrode. Covering the side surface of the pixel electrode of the light-emitting device 130 with the first EL layer 104 can inhibit the pixel electrode from being in contact with the second electrode 102; hence, a short circuit of the light-emitting device 130 can be inhibited.

In the display apparatus of one embodiment of the present invention, the first electrode 101 (pixel electrode) of the light-emitting device preferably has a stacked-layer structure. For example, in the example illustrated in FIG. 5B, the first electrode 101 of the light-emitting device 130 has a stacked-layer structure of the conductive layer 151 provided on the insulating layer 171 side and the conductive layer 152 provided on the organic compound layer side.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a high work function, for example, a work function higher than or equal to 4.0 eV.

The conductive layer 151 may have a stack-layer structure of a plurality of layers containing different materials, and the conductive layer 152 may have a stacked-layer structure of a plurality of layers containing different materials. In that case, the conductive layer 151 may include a layer formed using a material that can be used for the conductive layer 152, such as a conductive oxide, and the conductive layer 152 may include a layer formed using a material that can be used for the conductive layer 151, such as a metal material. In the case where the conductive layer 151 has a stack-layer structure of two or more layers, for example, a layer in contact with the conductive layer 152 can be a layer formed using a material that can be used for the conductive layer 152.

Note that the conductive layer 151 preferably has a tapered end portion. Specifically, the conductive layer 151 preferably has a tapered end portion with a taper angle of less than 90°. In that case, the conductive layer 152 provided along the side surface of the conductive layer 151 also has a tapered shape. When the side surface of the conductive layer 152 has a tapered shape, coverage with the first EL layer 104 provided along the side surface of the conductive layer 152 can be improved.

Since the light-emitting device 130 has the structure described in Embodiment 1 and Embodiment 2, the display apparatus of one embodiment of the present invention can have high reliability.

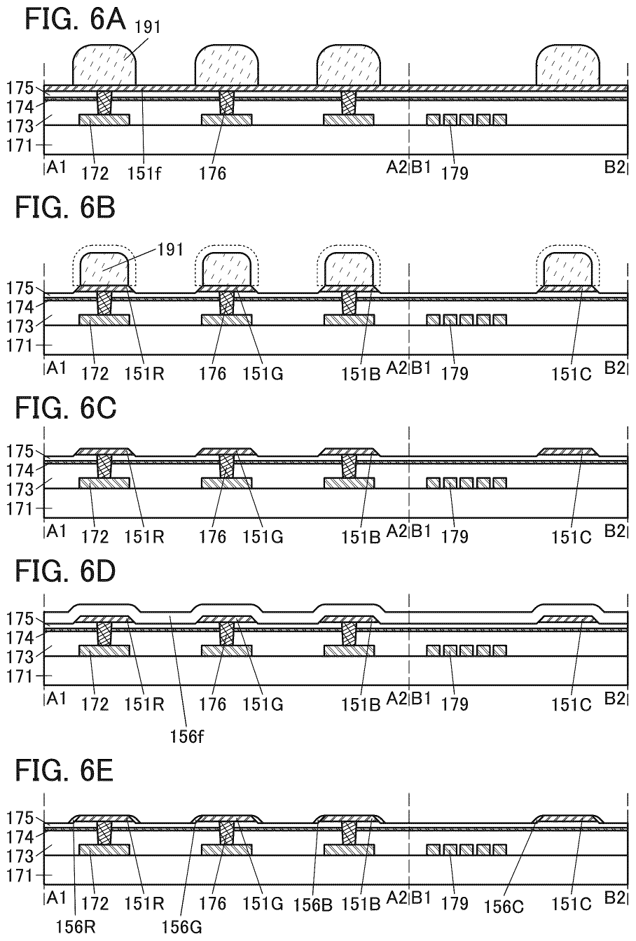

Next, a method for manufacturing the display apparatus having the structure illustrated in FIG. 5A is described with reference to FIG. 6 to FIG. 11.

### Fabrication Method Example 1

Thin films included in the display apparatus (e.g., insulating films, semiconductor films, and conductive films) can be formed by a sputtering method, a chemical vapor deposition (CVD) method, a vacuum evaporation method, a pulsed laser deposition (PLD) method, an atomic layer deposition (ALD) method, or the like.

Thin films included in the display apparatus (e.g., insulating films, semiconductor films, and conductive films) can also be formed by a wet film formation process such as spin coating, dipping, spray coating, ink-jetting, dispensing, screen printing, offset printing, doctor blade coating, slit coating, roll coating, curtain coating, or knife coating.

Thin films included in the display apparatus can be processed by a photolithography method, for example.

As light used for exposure in the photolithography method, for example, an i-line (wavelength: 365 nm), a g-line (wavelength: 436 nm), an h-line (wavelength: 405 nm), or light in which these lines are mixed can be used. Alternatively, ultraviolet rays, KrF laser light, ArF laser light, or the like can be used. Exposure may be performed by a liquid immersion exposure technique. As the light used for exposure, extreme ultraviolet (EUV) light or X-rays may also be used. Furthermore, instead of the light used for exposure, an electron beam can be used.

For etching of thin films, a dry etching method, a wet etching method, a sandblast method, or the like can be used.

First, as illustrated in FIG. 6A, the insulating layer 171 is formed over a substrate (not illustrated). Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate that has heat resistance high enough to withstand at least heat treatment performed later can be used. For example, it is possible to use a glass substrate; a quartz substrate; a sapphire substrate; a ceramic substrate; an organic resin substrate; or a semiconductor substrate such as a single crystal semiconductor substrate or a polycrystalline semiconductor substrate of silicon, silicon carbide, or the like, a compound semiconductor substrate of silicon germanium or the like, or an SOI substrate.

Next, as illustrated in FIG. 6A, openings reaching the conductive layer 172 are formed in the insulating layer 175, the insulating layer 174, and the insulating layer 173. Then, the plugs 176 are formed to fill the openings.

Next, as illustrated in FIG. 6A, a conductive film 151f to be the conductive layer 151R, the conductive layer 151G, the conductive layer 151B, and the conductive layer 151C is formed over the plugs 176 and the insulating layer 175. A metal material can be used for the conductive film 151f, for example.

Then, a resist mask 191 is formed over the conductive film 151f as illustrated in FIG. 6A. The resist mask 191 can be formed by application of a photosensitive material (photoresist), light exposure, and development.

Subsequently, as illustrated in FIG. 6B, the conductive film 151f in a region not overlapping with the resist mask 191 is removed, for example. In this manner, the conductive layer 151 is formed.

Next, the resist mask 191 is removed as illustrated in FIG. 6C. The resist mask 191 can be removed by ashing using oxygen plasma, for example.

Then, as illustrated in FIG. 6D, an insulating film 156f to be an insulating layer 156R, an insulating layer 156G, an insulating layer 156B, and an insulating layer 156C is formed over the conductive layer 151R, the conductive layer 151G, the conductive layer 151B, the conductive layer 151C, and the insulating layer 175.

As the insulating film 156f, an inorganic insulating film such as an oxide insulating film, a nitride insulating film, an oxynitride insulating film, or a nitride oxide insulating film, e.g., silicon oxynitride, can be used.

Subsequently, as illustrated in FIG. 6E, the insulating film 156f is processed to form the insulating layer 156R, the insulating layer 156G, the insulating layer 156B, and the insulating layer 156C.

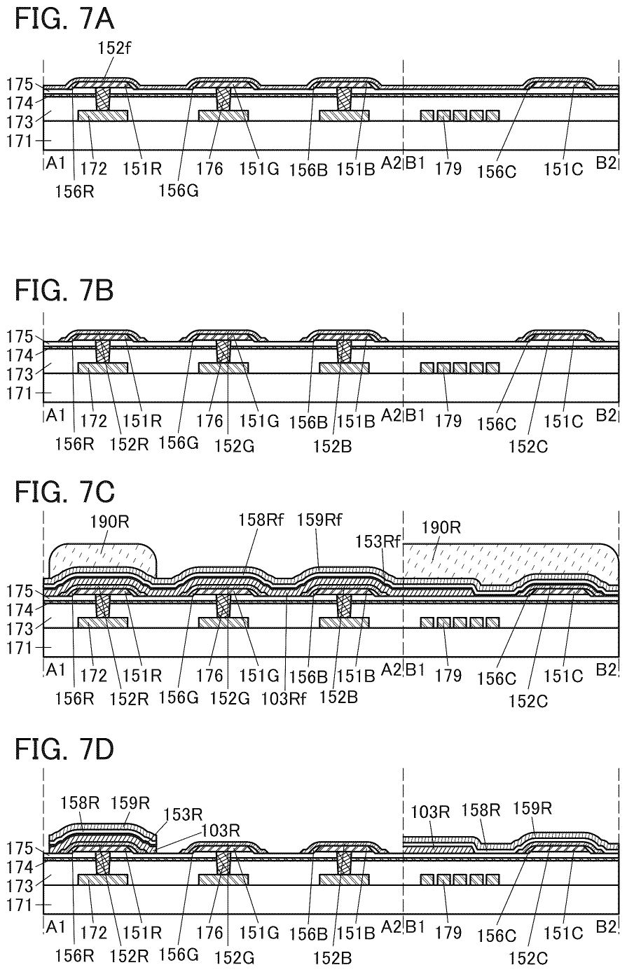

Next, as illustrated in FIG. 7A, a conductive film 152f is formed over the conductive layer 151R, the conductive layer 151G, the conductive layer 151B, the conductive layer 151C, the insulating layer 156R, the insulating layer 156G, the insulating layer 156B, the insulating layer 156C, and the insulating layer 175.

A conductive oxide can be used for the conductive film 152f, for example. The conductive film 152f may have a stacked-layer structure.

Then, as illustrated in FIG. 7B, the conductive film 152f is processed to form the conductive layer 152R, the conductive layer 152G, the conductive layer 152B, and the conductive layer 152C.

Next, as illustrated in FIG. 7C, an organic compound film 103Rf is formed over the conductive layer 152R, the conductive layer 152G, the conductive layer 152B, and the insulating layer 175. As illustrated in FIG. 7C, the organic compound film 103Rf is not formed over the conductive layer 152C.

Then, as illustrated in FIG. 7C, a sacrificial film 158Rf and a mask film 159Rf are formed.

Providing the sacrificial film 158Rf over the organic compound film 103Rf can reduce damage to the organic compound film 103Rf in the fabrication process of the display apparatus, resulting in an increase in the reliability of the light-emitting device.

As the sacrificial film 158Rf, a film that is highly resistant to the process conditions for the organic compound film 103Rf, specifically, a film having high etching selectivity with respect to the organic compound film 103Rf is used. As the mask film 159Rf, a film having high etching selectivity with respect to the sacrificial film 158Rf is used.

The sacrificial film 158Rf and the mask film 159Rf are formed at a temperature lower than the upper temperature limit of the organic compound film 103Rf. The typical substrate temperatures in formation of the sacrificial film 158Rf and the mask film 159Rf are each higher than or equal to 100 °C and lower than or equal to 200 °C, preferably higher than or equal to 100 °C and lower than or equal to 150 °C, and further preferably higher than or equal to 100 °C and lower than or equal to 120 °C.

As the sacrificial film 158Rf and the mask film 159Rf, films that can be removed by a wet etching method or a dry etching method are preferably used.

Note that the sacrificial film 158Rf that is formed over and in contact with the organic compound film 103Rf is preferably formed by a formation method that is less likely to damage the organic compound film 103Rf than a formation method of the mask film 159Rf. For example, an ALD method or a vacuum evaporation method is preferable to a sputtering method.

As each of the sacrificial film 158Rf and the mask film 159Rf, one or more kinds of a metal film, an alloy film, a metal oxide film, a semiconductor film, an organic insulating film, and an inorganic insulating film, for example, can be used.

For each of the sacrificial film 158Rf and the mask film 159Rf, a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials can be used, for example. It is particularly preferable to use a low-melting-point material such as aluminum or silver. It is preferable to use a metal material that can block ultraviolet rays for one or both of the sacrificial film 158Rf and the mask film 159Rf, in which case the organic compound film 103Rf can be inhibited from being irradiated with ultraviolet rays in patterning light exposure, and deterioration of the organic compound film 103Rf can be inhibited.

The sacrificial film 158Rf and the mask film 159Rf can each be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In the above metal oxide, in place of gallium, an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

The sacrificial film 158Rf and the mask film 159Rf are preferably formed using a semiconductor material such as silicon or germanium for excellent compatibility with a semiconductor manufacturing process. Alternatively, a compound containing the above semiconductor material can be used.

As each of the sacrificial film 158Rf and the mask film 159Rf, any of a variety of inorganic insulating films can be used. In particular, an oxide insulating film is preferable because its adhesion to the organic compound film 103Rf is higher than that of a nitride insulating film.

Subsequently, a resist mask 190R is formed as illustrated in FIG. 7C. The resist mask 190R can be formed by application of a photosensitive material (photoresist), light exposure, and development.

The resist mask 190R is provided at a position overlapping with the conductive layer 152R. The resist mask 190R is preferably provided also at a position overlapping with the conductive layer 152C. This can inhibit the conductive layer 152C from being damaged in the fabrication process of the display apparatus.

Next, as illustrated in FIG. 7D, part of the mask film 159Rf is removed using the resist mask 190R, so that a mask layer 159R is formed. The mask layer 159R remains over the conductive layer 152R and the conductive layer 152C. After that, the resist mask 190R is removed. Then, part of the sacrificial film 158Rf is removed using the mask layer 159R as a mask (also referred to as a hard mask), so that a sacrificial layer 158R is formed.

The use of a wet etching method can reduce damage to the organic compound film 103Rf in processing of the sacrificial film 158Rf and the mask film 159Rf, as compared to the case of using a dry etching method. In the case of using a wet etching method, it is preferable to use an alkaline aqueous solution such as a developer or a tetramethylammonium hydroxide (TMAH) aqueous solution, or an acid aqueous solution such as dilute hydrofluoric acid, oxalic acid, phosphoric acid, acetic acid, nitric acid, or a chemical solution containing a mixed solution of any of these acids, for example.

In the case of using a dry etching method to process the sacrificial film 158Rf, deterioration of the organic compound film 103Rf can be inhibited by not using a gas containing oxygen as the etching gas.

The resist mask 190R can be removed by a method similar to that for the resist mask 191.

Next, as illustrated in FIG. 7D, the organic compound film 103Rf is processed to form the organic compound layer 103R. For example, part of the organic compound film 103Rf is removed using the mask layer 159R and the sacrificial layer 158R as a hard mask, whereby the organic compound layer 103R is formed.

Accordingly, as illustrated in FIG. 7D, the stacked-layer structure of the organic compound layer 103R, the sacrificial layer 158R, and the mask layer 159R remains over the conductive layer 152R. The conductive layer 152G and the conductive layer 152B are exposed.

The organic compound film 103Rf is preferably processed by anisotropic etching. Anisotropic dry etching is particularly preferable. Alternatively, wet etching may be used.

In the case of using a dry etching method, deterioration of the organic compound film 103Rf can be inhibited by not using a gas containing oxygen as the etching gas.

Alternatively, a gas containing oxygen may be used as the etching gas. When the etching gas contains oxygen, the etching rate can be increased. Therefore, the etching can be performed under a low-power condition while an adequately high etching rate is maintained. Accordingly, damage to the organic compound film 103Rf can be reduced. Furthermore, a defect such as attachment of a reaction product generated during the etching can be inhibited.

In the case of using a dry etching method, it is preferable to use a gas containing at least one kind of H₂, CF₄, C₄F₈, SF₆, CHF₃, Cl₂, H₂O, BCl₃, and a Group 18 element such as He or Ar as the etching gas, for example. Alternatively, a gas containing oxygen and at least one kind of the above is preferably used as the etching gas. Alternatively, an oxygen gas may be used as the etching gas.

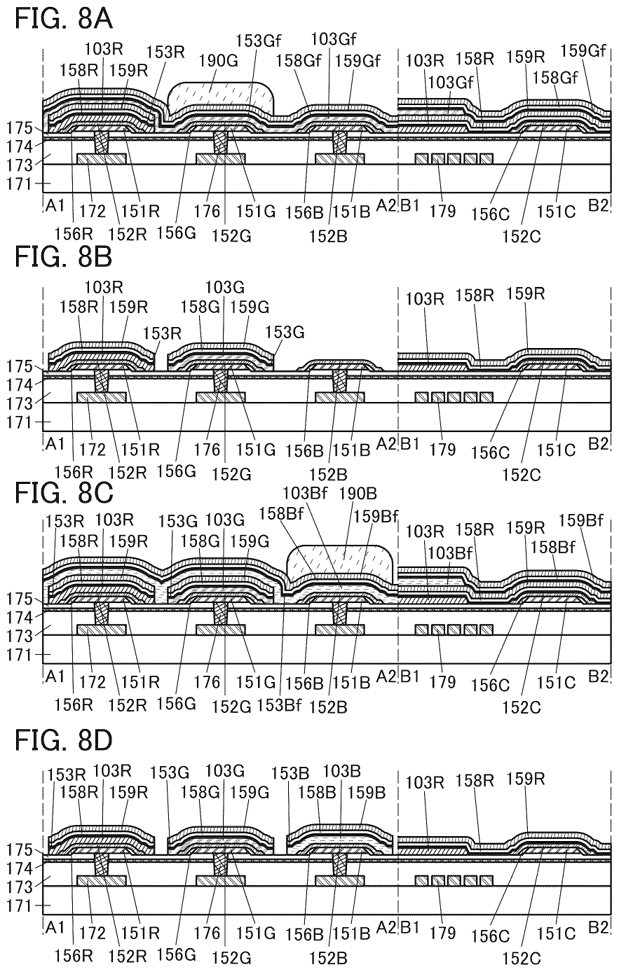

Then, as illustrated in FIG. 8A, an organic compound film 103Gf to be the organic compound layer 103G is formed.

The organic compound film 103Gf can be formed by a method similar to the method that can be used for forming the organic compound film 103Rf. The organic compound film 103Gf can have a structure similar to that of the organic compound film 103Rf.

Subsequently, as illustrated in FIG. 8A, a sacrificial film 158Gf and a mask film 159Gf are formed in this order. After that, a resist mask 190G is formed. The materials and the formation methods of the sacrificial film 158Gf and the mask film 159Gf are similar to conditions applicable to the sacrificial film 158Rf and the mask film 159Rf. The material and the formation method of the resist mask 190G are similar to conditions applicable to the resist mask 190R.

The resist mask 190G is provided at a position overlapping with the conductive layer 152G.

Subsequently, as illustrated in FIG. 8B, part of the mask film 159Gf is removed using the resist mask 190G, so that a mask layer 159G is formed. The mask layer 159G remains over the conductive layer 152G. After that, the resist mask 190G is removed. Then, part of the sacrificial film 158Gf is removed using the mask layer 159G as a mask, so that a sacrificial layer 158G is formed. Next, the organic compound film 103Gf is processed to form the organic compound layer 103G. Accordingly, as illustrated in FIG. 8B, the stacked-layer structure of the organic compound layer 103G, the sacrificial layer 158G, and the mask layer 159G remains over the conductive layer 152G. The mask layer 159R and the conductive layer 152B are exposed.

Then, an organic compound film 103Bf is formed as illustrated in FIG. 8C.

The organic compound film 103Bf can be formed by a method similar to the method that can be used for forming the organic compound film 103Rf. The organic compound film 103Bf can have a structure similar to that of the organic compound film 103Rf.

Subsequently, a sacrificial film 158Bf and a mask film 159Bf are formed in this order as illustrated in FIG. 8C. After that, a resist mask 190B is formed. The materials and the formation methods of the sacrificial film 158Bf and the mask film 159Bf are similar to conditions applicable to the sacrificial film 158Rf and the mask film 159Rf. The material and the formation method of the resist mask 190B are similar to conditions applicable to the resist mask 190R.

The resist mask 190B is provided at a position overlapping with the conductive layer 152B.

Subsequently, as illustrated in FIG. 8D, part of the mask film 159Bf is removed using the resist mask 190B, so that a mask layer 159B is formed. The mask layer 159B remains over the conductive layer 152B. After that, the resist mask 190B is removed. Then, part of the sacrificial film 158Bf is removed using the mask layer 159B as a mask, so that a sacrificial layer 158B is formed. Next, the organic compound film 103Bf is processed to form the organic compound layer 103B. For example, part of the organic compound film 103Bf is removed using the mask layer 159B and the sacrificial layer 158B as a hard mask, whereby the organic compound layer 103B is formed.

Accordingly, the stacked-layer structure of the organic compound layer 103B, the sacrificial layer 158B, and the mask layer 159B remains over the conductive layer 152B as illustrated in FIG. 8D. The mask layer 159R and the mask layer 159G are exposed.

Note that the side surfaces of the organic compound layer 103R, the organic compound layer 103G, and the organic compound layer 103B are preferably perpendicular or substantially perpendicular to their formation surfaces. For example, the angle between the formation surfaces and these side surfaces is preferably greater than or equal to 600 and less than or equal to 90°.

The distance between two adjacent layers among the organic compound layer 103R, the organic compound layer 103G, and the organic compound layer 103B, which are formed by a photolithography method as described above, can be reduced to less than or equal to 8 m, less than or equal to 5 μm, less than or equal to 3 μm, less than or equal to 2 μm, or less than or equal to 1 pm. Here, the distance can be specified, for example, by the distance between facing end portions of two adjacent layers among the organic compound layer 103R, the organic compound layer 103G, and the organic compound layer 103B. Reducing the distance between the island-shaped organic compound layers makes it possible to provide a display apparatus having high resolution and a high aperture ratio. In addition, the distance between the first electrodes of adjacent light-emitting devices can also be reduced to, for example, less than or equal to 10 μm, less than or equal to 8 μm, less than or equal to 5 μm, less than or equal to 3 μm, or less than or equal to 2 μm. Note that the distance between the first electrodes of adjacent light-emitting devices is preferably greater than or equal to 2 μm and less than or equal to 5 μm.

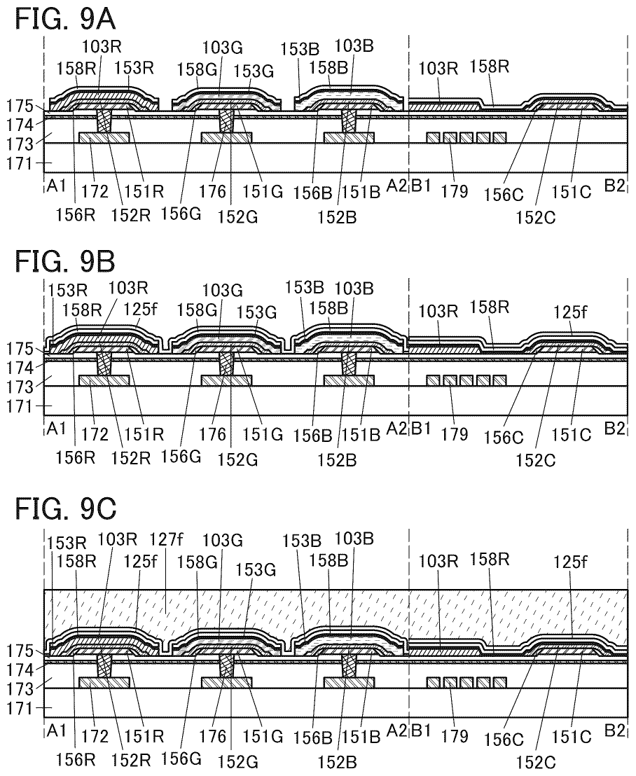

Next, the mask layer 159R, the mask layer 159G, and the mask layer 159B are preferably removed as illustrated in FIG. 9A.

The step of removing the mask layers can be performed by a method similar to that for the step of processing the mask layers. Specifically, by using a wet etching method, damage caused to the organic compound layer 103 at the time of removing the mask layers can be reduced as compared to the case of using a dry etching method.

The mask layers may be removed by being dissolved in a polar solvent such as water or an alcohol. Examples of an alcohol include ethyl alcohol, methyl alcohol, isopropyl alcohol (IPA), and glycerin.

After the mask layers are removed, drying treatment may be performed in order to remove water adsorbed on surfaces. For example, heat treatment in an inert gas atmosphere or a reduced-pressure atmosphere can be performed. The heat treatment can be performed at a substrate temperature higher than or equal to 50 °C and lower than or equal to 200 °C, preferably higher than or equal to 60 °C and lower than or equal to 150 °C, and further preferably higher than or equal to 70 °C and lower than or equal to 120 °C. A reduced-pressure atmosphere is preferable, in which case drying at a lower temperature is possible.

Next, an inorganic insulating film 125f is formed as illustrated in FIG. 9B.

Then, as illustrated in FIG. 9C, an insulating film 127f to be the insulating layer 127 is formed over the inorganic insulating film 125f.

The substrate temperature at the time of forming the inorganic insulating film 125f and the insulating film 127f is preferably higher than or equal to 60 °C, higher than or equal to 80 °C, higher than or equal to 100 °C, or higher than or equal to 120 °C and lower than or equal to 200 °C, lower than or equal to 180 °C, lower than or equal to 160 °C, lower than or equal to 150 °C, or lower than or equal to 140 °C.

As the inorganic insulating film 125f, an insulating film having a thickness of 3 nm or more, 5 nm or more, or 10 nm or more and 200 nm or less, 150 nm or less, 100 nm or less, or 50 nm or less is preferably formed at a substrate temperature in the above-described range.

The inorganic insulating film 125f is preferably formed by an ALD method, for example. An ALD method is preferably used, in which case film formation damage can be reduced and a film with good coverage can be formed. As the inorganic insulating film 125f, an aluminum oxide film is preferably formed by an ALD method, for example.

The insulating film 127f is preferably formed by the aforementioned wet film formation process. For example, the insulating film 127f is preferably formed by spin coating using a photosensitive material, and specifically preferably formed using a photosensitive resin composition containing an acrylic resin.

Then, light exposure is performed to expose part of the insulating film 127f to visible light or ultraviolet rays. The insulating layer 127 is formed in regions that are sandwiched between any two of the conductive layer 152R, the conductive layer 152G, and the conductive layer 152B and around the conductive layer 152C.

The width of the insulating layer 127 formed later can be controlled in accordance with the exposed region of the insulating film 127f. In this embodiment, processing is performed such that the insulating layer 127 includes a portion overlapping with the top surface of the conductive layer 151.

Light used for the exposure preferably includes the i-line (wavelength: 365 nm). Furthermore, light used for the exposure may include at least one of the g-line (wavelength: 436 nm) and the h-line (wavelength: 405 nm).

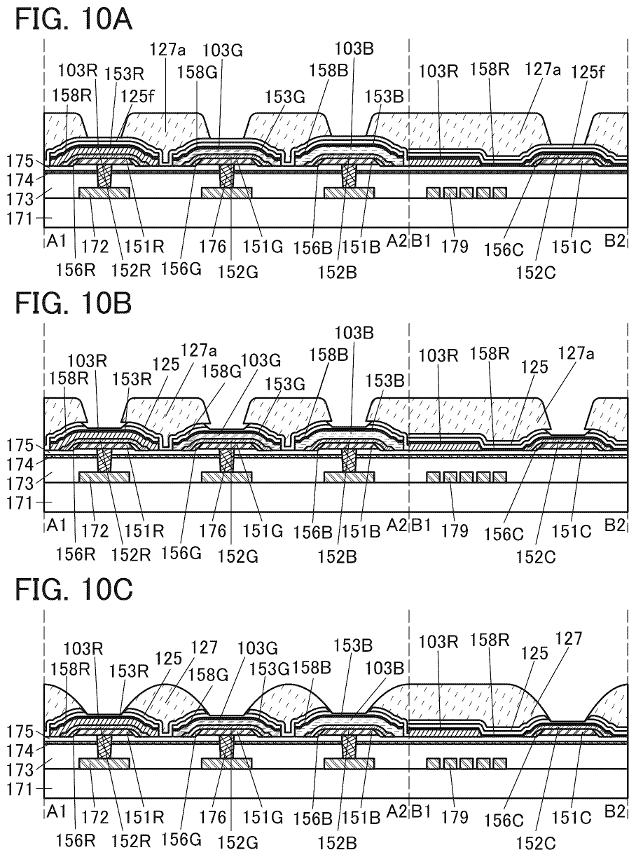

Next, the region of the insulating film 127f exposed to light is removed by development as illustrated in FIG. 10A, so that an insulating layer 127a is formed.

Next, as illustrated in FIG. 10B, etching treatment is performed with the insulating layer 127a as a mask to remove part of the inorganic insulating film 125f and reduce the thickness of part of the sacrificial layer 158R, the sacrificial layer 158G, and the sacrificial layer 158B. Thus, the inorganic insulating layer 125 is formed under the insulating layer 127a. Moreover, the surfaces of the thin portions of the sacrificial layer 158R, the sacrificial layer 158G, and the sacrificial layer 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that of the sacrificial layer 158R, the sacrificial layer 158G, and the sacrificial layer 158B, in which case the first etching treatment can be performed concurrently.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. By the dry etching, the thin regions of the sacrificial layer 158R, the sacrificial layer 158G, and the sacrificial layer 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used.

The first etching treatment is preferably performed by wet etching. The use of a wet etching method can reduce damage to the organic compound layer 103R, the organic compound layer 103G, and the organic compound layer 103B, as compared to the case of using a dry etching method. Wet etching can be performed using an alkaline solution, for example. For instance, TMAH, which is an alkaline solution, can be used for the wet etching of an aluminum oxide film. Alternatively, an acid solution containing fluoride can also be used. In this case, puddle wet etching can be performed. Note that the inorganic insulating film 125f is preferably formed using a material similar to that of the sacrificial layer 158R, the sacrificial layer 158G, and the sacrificial layer 158B, in which case the above etching treatment can be performed concurrently.

The sacrificial layer 158R, the sacrificial layer 158G, and the sacrificial layer 158B are not completely removed by the first etching treatment, and the etching treatment is stopped when the thickness thereof is reduced. The corresponding sacrificial layer 158R, sacrificial layer 158G, and sacrificial layer 158B remain over the organic compound layer 103R, the organic compound layer 103G, and the organic compound layer 103B in this manner, whereby the organic compound layer 103R, the organic compound layer 103G, and the organic compound layer 103B can be prevented from being damaged by treatment in a later step.

Next, light exposure is preferably performed on the entire substrate so that the insulating layer 127a is irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a into a tapered shape.

Here, when a barrier insulating layer against oxygen (e.g., an aluminum oxide film) exists as each of the sacrificial layer 158R, the sacrificial layer 158G, and the sacrificial layer 158B, diffusion of oxygen into the organic compound layer 103R, the organic compound layer 103G, and the organic compound layer 103B can be suppressed.

Then, heat treatment (also referred to as post-baking) is performed. The heat treatment can change the insulating layer 127a into the insulating layer 127 having a tapered side surface (FIG. 10C). The heat treatment is conducted at a temperature lower than the upper temperature limit of the organic compound layer. The heat treatment can be performed at a substrate temperature higher than or equal to 50 °C and lower than or equal to 200 °C, preferably higher than or equal to 60 °C and lower than or equal to 150 °C, and further preferably higher than or equal to 70 °C and lower than or equal to 130 °C. The heating atmosphere may be an air atmosphere or an inert gas atmosphere. Moreover, the heating atmosphere may be an atmospheric-pressure atmosphere or a reduced-pressure atmosphere. Accordingly, adhesion between the insulating layer 127 and the inorganic insulating layer 125 can be improved, and corrosion resistance of the insulating layer 127 can be increased.

When the sacrificial layer 158R, the sacrificial layer 158G, and the sacrificial layer 158B are not completely removed by the first etching treatment and the thinned sacrificial layer 158R, sacrificial layer 158G, and sacrificial layer 158B are left, the organic compound layer 103R, the organic compound layer 103G, and the organic compound layer 103B can be prevented from being damaged and deteriorating in the heat treatment. This increases the reliability of the light-emitting device.

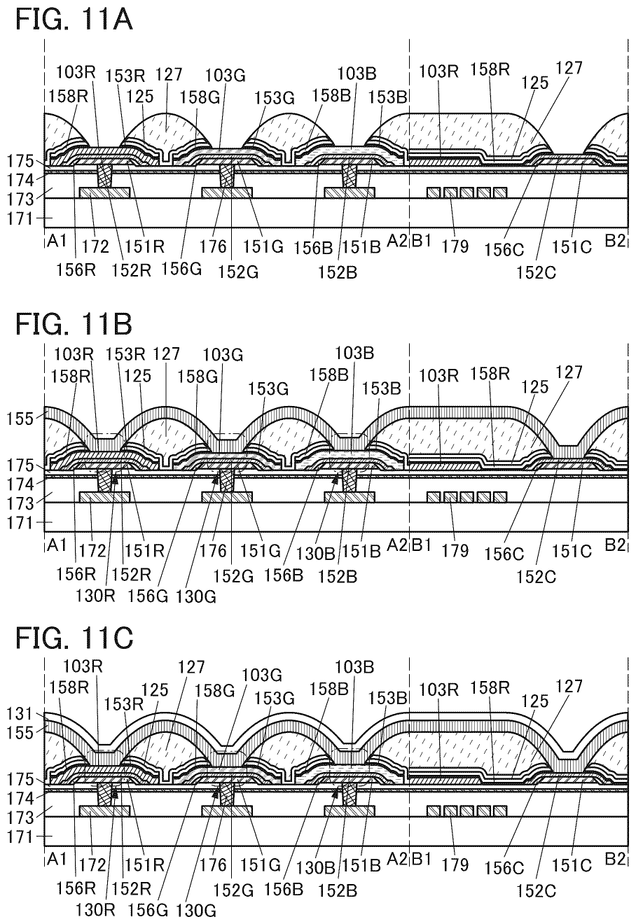

Next, as illustrated in FIG. 11A, etching treatment is performed with the insulating layer 127 as a mask to remove part of the sacrificial layer 158R, the sacrificial layer 158G, and the sacrificial layer 158B. Thus, openings are formed in the sacrificial layer 158R, the sacrificial layer 158G, and the sacrificial layer 158B, and the top surfaces of the organic compound layer 103R, the organic compound layer 103G, the organic compound layer 103B, and the conductive layer 152C are exposed. Note that this etching treatment may be hereinafter referred to as second etching treatment.

An end portion of the inorganic insulating layer 125 is covered with the insulating layer 127. FIG. 11A illustrates an example in which part of an end portion of the sacrificial layer 158G (specifically, a tapered portion formed by the first etching treatment) is covered with the insulating layer 127 and a tapered portion formed by the second etching treatment is exposed.

The second etching treatment is performed by wet etching. The use of a wet etching method can reduce damage to the organic compound layer 103R, the organic compound layer 103G, and the organic compound layer 103B, as compared to the case of using a dry etching method. Wet etching can be performed using an alkaline solution or an acidic solution, for example. An aqueous solution is preferable in order that the organic compound layer 103 is not dissolved.

Next, as illustrated in FIG. 11B, a common electrode 155 is formed over the organic compound layer 103R, the organic compound layer 103G, the organic compound layer 103B, the conductive layer 152C, and the insulating layer 127. The common electrode 155 can be formed by a sputtering method, a vacuum evaporation method, or the like. In this case, a stacked-layer structure of the first EL layer 104 and the second EL layer 105 may be formed as the organic compound layer 103 as illustrated in FIG. 5B, and the common electrode 155 may be formed thereover.

Next, as illustrated in FIG. 11C, the protective layer 131 is formed over the common electrode 155. The protective layer 131 can be formed by a vacuum evaporation method, a sputtering method, a CVD method, an ALD method, or the like.

Then, the substrate 120 is bonded over the protective layer 131 using the resin layer 122, so that the display apparatus can be fabricated. In the method for fabricating the display apparatus of one embodiment of the present invention, the insulating layer 156 is provided to include a region overlapping with the side surface of the conductive layer 151 and the conductive layer 152 is formed to cover the conductive layer 151 and the insulating layer 156 as described above. This can increase the yield of the display apparatus and inhibit generation of defects.

As described above, in the method for fabricating the display apparatus in one embodiment of the present invention, the island-shaped organic compound layer 103R, the island-shaped organic compound layer 103G, and the island-shaped organic compound layer 103B are formed not by using a fine metal mask but by processing a film formed on the entire surface; thus, the island-shaped layers can be formed to have a uniform thickness. Consequently, a high-resolution display apparatus or a display apparatus with a high aperture ratio can be obtained. Furthermore, even when the resolution or the aperture ratio is high and the distance between the subpixels is extremely short, the organic compound layer 103R, the organic compound layer 103G, and the organic compound layer 103B can be inhibited from being in contact with each other in the adjacent subpixels. As a result, generation of leakage current between the subpixels can be inhibited. This can prevent crosstalk, so that a display apparatus with extremely high contrast can be obtained. Moreover, even a display apparatus that includes tandem light-emitting devices fabricated by a photolithography method can be provided as a display apparatus having favorable characteristics.

### Embodiment 4

In this embodiment, a display apparatus of one embodiment of the present invention will be described.

The display apparatus in this embodiment can be a high-resolution display apparatus. Thus, the display apparatus in this embodiment can be used for display portions of information terminal devices (wearable devices) such as watch-type and bracelet-type information terminal devices and display portions of wearable devices that can be worn on the head, such as a VR device like a head mounted display (HMD) and a glasses-type AR device.

The display apparatus in this embodiment can be a high-definition display apparatus or a large-sized display apparatus. Accordingly, the display apparatus in this embodiment can be used for display portions of a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

### [Display Module]

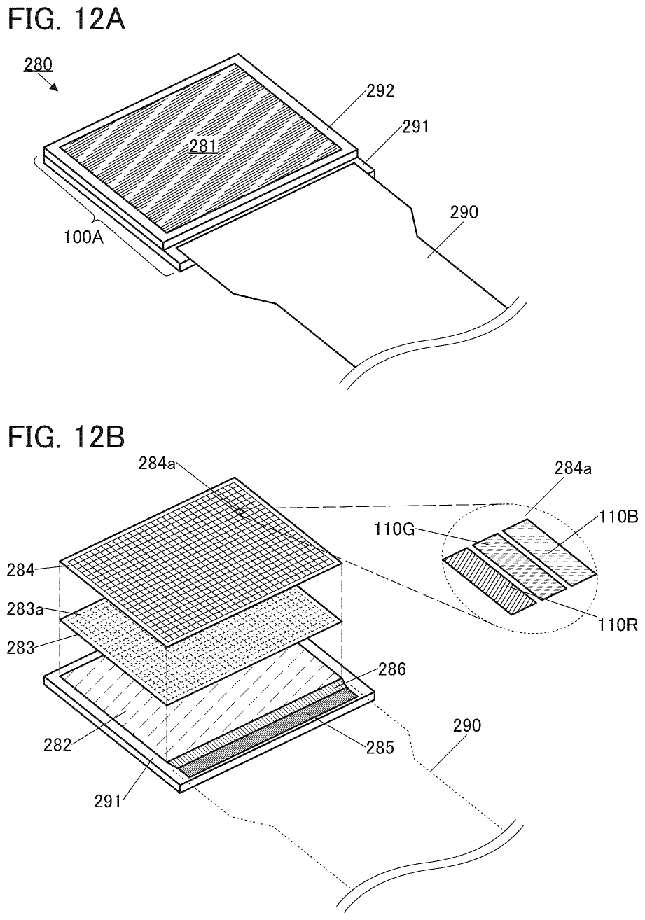

FIG. 12A is a perspective view of a display module 280. The display module 280 includes a display apparatus 100A and an FPC 290. Note that the display apparatus included in the display module 280 is not limited to the display apparatus 100A and may be any of a display apparatus 100B and a display apparatus 100E described later.

The display module 280 includes a substrate 291 and a substrate 292. The display module 280 includes a display portion 281. The display portion 281 is a region of the display module 280 where an image is displayed, and is a region where light from pixels provided in a pixel portion 284 described later can be seen.

FIG. 12B illustrates a schematic perspective view of the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 12B. The pixels 284a can employ any of the structures described in the above embodiments. FIG. 12B illustrates an example where the pixel 284a has a structure similar to that of the pixel 178 illustrated in FIG. 5.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, the circuit portion 282 preferably includes one or both of agate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has an extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic appliances including a relatively small display portion.

### [Display Apparatus 100A]

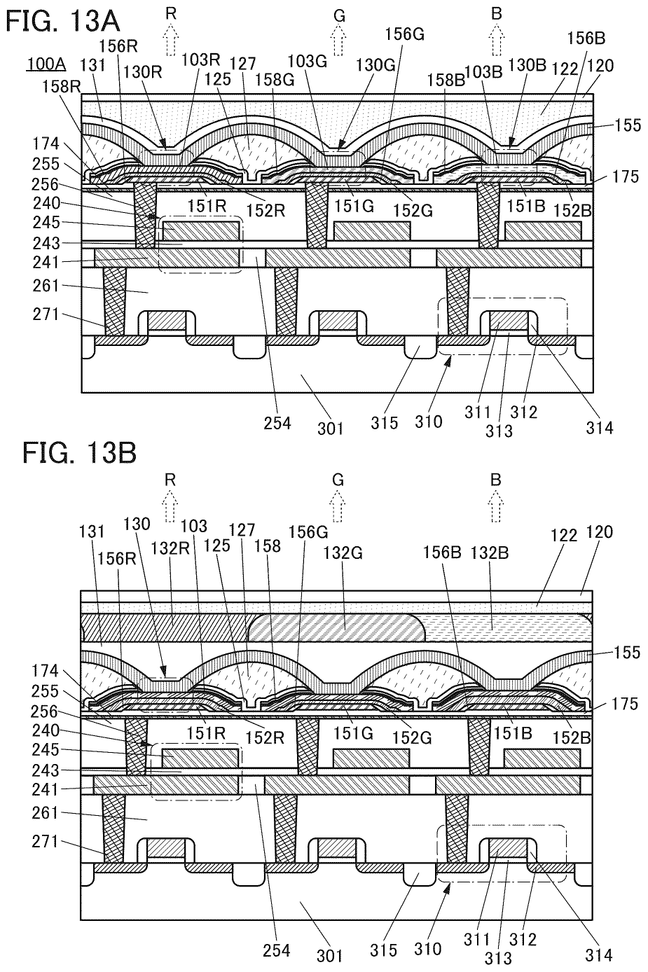

The display apparatus 100A illustrated in FIG. 13A includes a substrate 301, the light-emitting device 130R, the light-emitting device 130G, the light-emitting device 130B, a capacitor 240, and a transistor 310.

The substrate 301 corresponds to the substrate 291 in FIG. 12A and FIG. 12B. The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting device 130R, the light-emitting device 130G, and the light-emitting device 130B are provided over the insulating layer 175. An insulator is provided in regions between adjacent light-emitting devices.

The insulating layer 156R is provided to include a region overlapping with the side surface of the conductive layer 151R. The insulating layer 156G is provided to include a region overlapping with the side surface of the conductive layer 151G. The insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. The sacrificial layer 158R is positioned over the organic compound layer 103R. The sacrificial layer 158G is positioned over the organic compound layer 103G. The sacrificial layer 158B is positioned over the organic compound layer 103B.

Each of the conductive layer 151R, the conductive layer 151G, and the conductive layer 151B is electrically connected to one of the source and the drain of the transistor 310 through a plug 256 embedded in the insulating layer 243, the insulating layer 255, the insulating layer 174, and the insulating layer 175, the conductive layer 241 embedded in the insulating layer 254, and the plug 271 embedded in the insulating layer 261. Any of a variety of conductive materials can be used for the plugs.

The protective layer 131 is provided over the light-emitting device 130R, the light-emitting device 130G, and the light-emitting device 130B. The substrate 120 is bonded to the protective layer 131 with the resin layer 122. Embodiment 3 can be referred to for the details of the light-emitting device 130 and the components thereover up to the substrate 120. The substrate 120 corresponds to the substrate 292 in FIG. 12A.

FIG. 13B is a variation example of the display apparatus 100A illustrated in FIG. 13A. The display apparatus illustrated in FIG. 13B includes a coloring layer 132R, a coloring layer 132G, and a coloring layer 132B, and each of the light-emitting devices 130 includes a region overlapping with one of the coloring layer 132R, the coloring layer 132G, and the coloring layer 132B. In the display apparatus illustrated in FIG. 13B, the light-emitting device 130 can emit white light, for example. The coloring layer 132R, the coloring layer 132G, and the coloring layer 132B can transmit red light, green light, and blue light, respectively, for example.

### [Display Apparatus 100B]

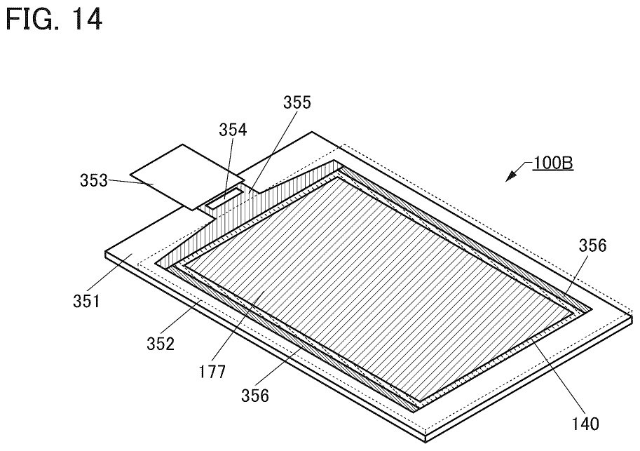

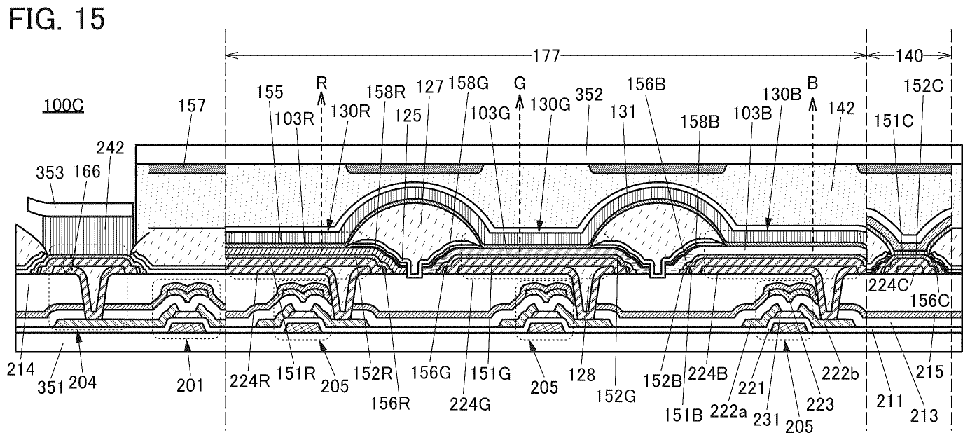

FIG. 14 illustrates a perspective view of the display apparatus 100B, and FIG. 15 illustrates a cross-sectional view of the display apparatus 100B.

In the display apparatus 100B, a substrate 352 and a substrate 351 are bonded to each other. In FIG. 14, the substrate 352 is denoted by a dashed line.

The display apparatus 100B includes the pixel portion 177, the connection portion 140, a circuit 356, a wiring 355, and the like. FIG. 14 illustrates an example in which an IC 354 and an FPC 353 are mounted on the display apparatus 100B. Thus, the structure illustrated in FIG. 14 can be regarded as a display module including the display apparatus 100B, the IC (integrated circuit), and the FPC. Here, a display apparatus in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 14 illustrates an example in which the IC 354 is provided over the substrate 351 by a COG (Chip On Glass) method, a COF (Chip on Film) method, or the like. An IC including a scan line driver circuit, a signal line driver circuit, or the like can be used as the IC 354, for example. Note that the display apparatus 100B and the display module are not necessarily provided with an IC. Alternatively, the IC may be mounted on the FPC by a COF method, for example.

FIG. 15 illustrates an example of cross sections of part of a region including the FPC 353, part of the circuit 356, part of the pixel portion 177, part of the connection portion 140, and part of a region including an end portion of the display apparatus 100B.

### [Display Apparatus 100C]

The display apparatus 100C illustrated in FIG. 15 includes a transistor 201, a transistor 205, the light-emitting device 130R that emits red light, the light-emitting device 130G that emits green light, the light-emitting device 130B that emits blue light, and the like between the substrate 351 and the substrate 352.

Embodiment 1 to Embodiment 3 can be referred to for the details of the light-emitting device 130R, the light-emitting device 130G, and the light-emitting device 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through an opening provided in an insulating layer 214. An end portion of the conductive layer 151R is positioned outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layer 224G, the conductive layer 151G, the conductive layer 152G, and the insulating layer 156G in the light-emitting device 130G and the conductive layer 224B, the conductive layer 151B, the conductive layer 152B, and the insulating layer 156B in the light-emitting device 130B are not described in detail because they are respectively similar to the conductive layer 224R, the conductive layer 151R, the conductive layer 152R, and the insulating layer 156R in the light-emitting device 130R.

In each of the conductive layer 224R, the conductive layer 224G, and the conductive layer 224B, a depression portion is formed to cover the opening provided in the insulating layer 214. A layer 128 is embedded in the depression portion.

The layer 128 has a function of filling the depression portions of the conductive layer 224R, the conductive layer 224G, and the conductive layer 224B to obtain planarity. Over the conductive layer 224R, the conductive layer 224G, the conductive layer 224B, and the layer 128, the conductive layer 151R, the conductive layer 151G, and the conductive layer 151B that are respectively electrically connected to the conductive layer 224R, the conductive layer 224G, and the conductive layer 224B are provided. Thus, the regions overlapping with the depression portions of the conductive layer 224R, the conductive layer 224G, and the conductive layer 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material that can be used for the above-described insulating layer 127, for example.

The protective layer 131 is provided over the light-emitting device 130R, the light-emitting device 130G, and the light-emitting device 130B. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 15, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided not to overlap with the light-emitting device. Furthermore, the space may be filled with a resin other than the frame-like adhesive layer 142.

FIG. 15 illustrates an example in which the connection portion 140 includes a conductive layer 224C obtained by processing the same conductive film as the conductive layer 224R, the conductive layer 224G, and the conductive layer 224B; the conductive layer 151C obtained by processing the same conductive film as the conductive layer 151R, the conductive layer 151G, and the conductive layer 151B; and the conductive layer 152C obtained by processing the same conductive film as the conductive layer 152R, the conductive layer 152G, and the conductive layer 152B. In the example illustrated in FIG. 15, the insulating layer 156C is provided to include a region overlapping with the side surface of the conductive layer 151C.

The display apparatus 100B has a top-emission structure. Light from the light-emitting device is emitted toward the substrate 352. For the substrate 352, a material having a high visible-light-transmitting property is preferably used. In the case where the light-emitting device emits infrared or near-infrared light, a material having a high transmitting property with respect to infrared or near-infrared light is preferably used. The pixel electrode contains a material that reflects visible light, and the counter electrode (the common electrode 155) contains a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

An inorganic insulating film is preferably used as each of the insulating layer 211, the insulating layer 213, and the insulating layer 215.

An organic insulating layer is suitable for the insulating layer 214 functioning as a planarization layer.

Each of the transistor 201 and the transistor 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate.

A connection portion 204 is provided in a region of the substrate 351 not overlapping with the substrate 352. In the connection portion 204, the source electrode or the drain electrode of the transistor 201 is electrically connected to the FPC 353 through a conductive layer 166 and a connection layer 242. As an example, the conductive layer 166 has a stacked-layer structure of a conductive film obtained by processing the same conductive film as the conductive layer 224R, the conductive layer 224G, and the conductive layer 224B; a conductive film obtained by processing the same conductive film as the conductive layer 151R, the conductive layer 151G, and the conductive layer 151B; and a conductive film obtained by processing the same conductive film as the conductive layer 152R, the conductive layer 152G, and the conductive layer 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided between adjacent light-emitting devices, in the connection portion 140, in the circuit 356, and the like. A variety of optical members can be arranged on the outer surface of the substrate 352.

A material that can be used for the substrate 120 can be used for each of the substrate 351 and the substrate 352.

A material that can be used for the resin layer 122 can be used for the adhesive layer 142.

As the connection layer 242, an anisotropic conductive film (ACF), an anisotropic conductive paste (ACP), or the like can be used.

### [Display Apparatus 100D]

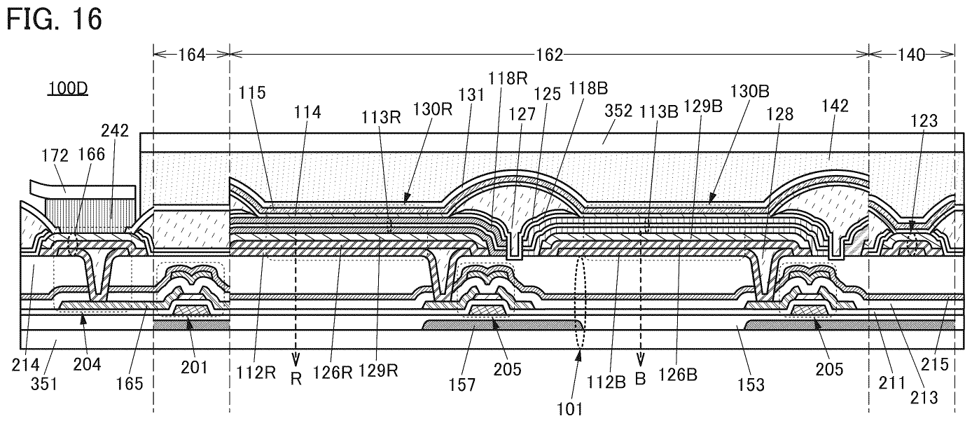

The display apparatus 100D illustrated in FIG. 16 differs from the display apparatus 100C illustrated in FIG. 15 mainly in having a bottom-emission structure.

Light from the light-emitting device is emitted toward the substrate 351. For the substrate 351, a material having a high visible-light-transmitting property is preferably used. By contrast, there is no limitation on the light-transmitting property of a material used for the substrate 352.

A light-blocking layer is preferably formed between the substrate 351 and the transistor 201 and between the substrate 351 and the transistor 205. FIG. 16 illustrates an example in which a light-blocking layer 157 is provided over the substrate 351, an insulating layer 153 is provided over the light-blocking layer, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material having a high visible-light-transmitting property is used for each of the conductive layers 112R, 112B, 126R, 126B, 129R, and 129B. A material that reflects visible light is preferably used for the common electrode 155.

Although the light-emitting device 130G is not illustrated in FIG. 16, the light-emitting device 130G is also provided.

Although FIG. 16 and the like illustrate an example in which the top surface of the layer 128 includes a flat portion, the shape of the layer 128 is not particularly limited.

### [Display Apparatus 100E]

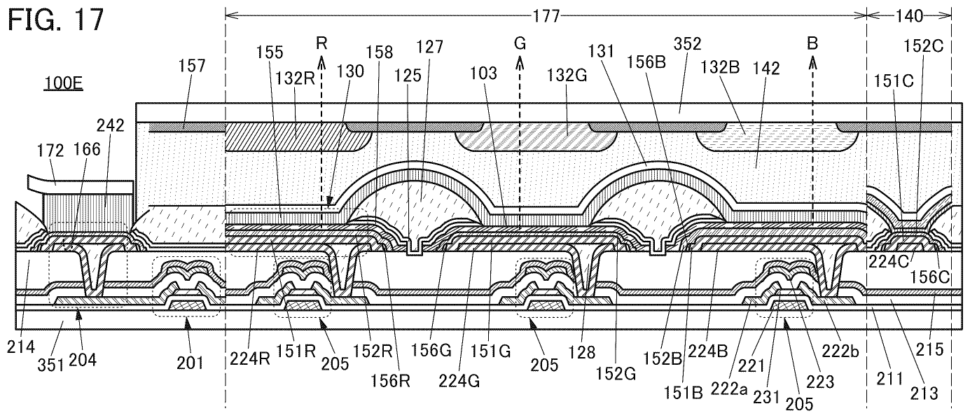

The display apparatus 100E illustrated in FIG. 17 is a variation example of the display apparatus 100C illustrated in FIG. 15 and differs from the display apparatus 100C mainly in including the coloring layer 132R, the coloring layer 132G, and the coloring layer 132B.

In the display apparatus 100E, the light-emitting device 130 includes a region overlapping with one of the coloring layer 132R, the coloring layer 132G, and the coloring layer 132B. The coloring layer 132R, the coloring layer 132G, and the coloring layer 132B can be provided on the surface of the substrate 352 on the substrate 351 side. An end portion of the coloring layer 132R, an end portion of the coloring layer 132G, and an end portion of the coloring layer 132B can overlap with the light-blocking layer 157.

In the display apparatus 100E, the light-emitting device 130 can emit white light, for example. The coloring layer 132R, the coloring layer 132G, and the coloring layer 132B can transmit red light, green light, and blue light, respectively, for example. Note that in the structure of the display apparatus 100E, the coloring layer 132R, the coloring layer 132G, and the coloring layer 132B may be provided between the protective layer 131 and the adhesive layer 142.

Although FIG. 15, FIG. 17, and the like illustrate an example in which the top surface of the layer 128 includes a flat portion, the shape of the layer 128 is not particularly limited.

This embodiment can be combined as appropriate with the other embodiments or the examples. In this specification, in the case where a plurality of structure examples are shown in one embodiment, the structure examples can be combined as appropriate.

### Embodiment 5

In this embodiment, electronic appliances of embodiments of the present invention will be described.

Electronic appliances of this embodiment include the display apparatus of one embodiment of the present invention in their display portions. The display apparatus of one embodiment of the present invention has high display performance and can be easily increased in resolution and definition. Thus, the display apparatus of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

In particular, the display apparatus of one embodiment of the present invention can have a high resolution, and thus can be favorably used for an electronic appliance having a relatively small display portion. Examples of such an electronic appliance include watch-type and bracelet-type information terminal devices (wearable devices) and wearable devices that can be worn on the head, such as a VR device like a head-mounted display, a glasses-type AR device, and an MR device.

The electronic appliance in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

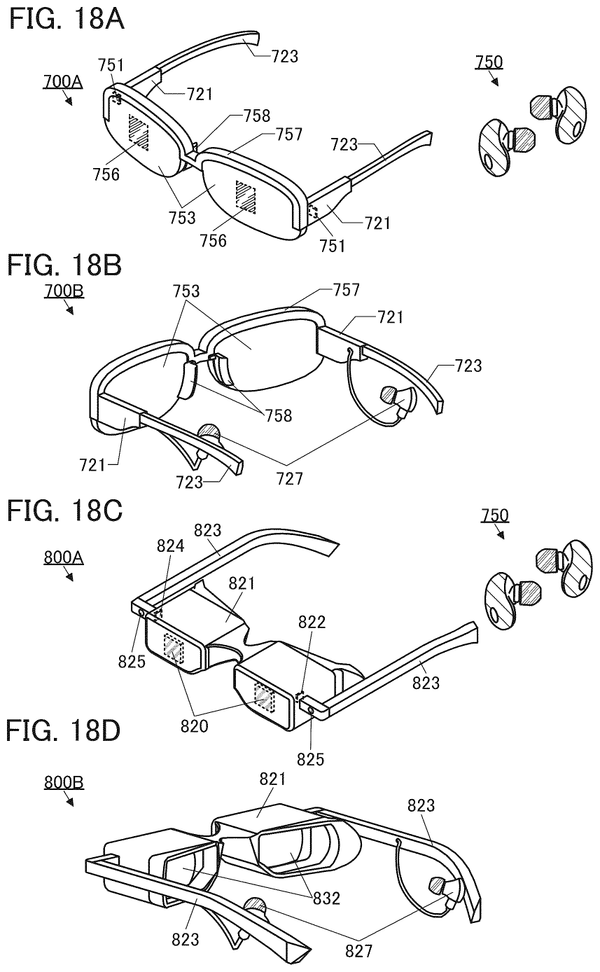

Examples of wearable devices that can be worn on the head are described with reference to FIG. 18A to FIG. 18D.

An electronic appliance 700A illustrated in FIG. 18A and an electronic appliance 700B illustrated in FIG. 18B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic appliances can be highly reliable.

The electronic appliance 700A and the electronic appliance 700B can each project images displayed on the display panels 751 onto display regions 756 of the optical members 753. Since the optical members 753 have a light-transmitting property, the user can see images displayed on the display regions, which are superimposed on transmission images seen through the optical members 753.

In the electronic appliance 700A and the electronic appliance 700B, a camera capable of capturing images of the front side may be provided as the image capturing portion. Furthermore, when the electronic appliance 700A and the electronic appliance 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliance 700A and the electronic appliance 700B are provided with a battery, so that they can be charged wirelessly and/or by wire.

A touch sensor module may be provided in the housing 721.

Various touch sensors can be applied to the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

An electronic appliance 800A illustrated in FIG. 18C and an electronic appliance 800B illustrated in FIG. 18D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used in the display portions 820. Thus, the electronic appliances can be highly reliable.

The display portions 820 are positioned inside the housing 821 so as to be seen through the lenses 832. When the pair of display portions 820 display different images, three-dimensional display using parallax can be performed.

The electronic appliance 800A and the electronic appliance 800B preferably include a mechanism for adjusting the lateral positions of the lenses 832 and the display portions 820 so that the lenses 832 and the display portions 820 are positioned optimally in accordance with the positions of the user's eyes.

The electronic appliance 800A or the electronic appliance 800B can be mounted on the user's head with the wearing portions 823.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

The electronic appliance 800A may include a vibration mechanism that functions as bone-conduction earphones.

The electronic appliance 800A and the electronic appliance 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750.

The electronic appliance may include an earphone portion. The electronic appliance 700B in FIG. 18B includes earphone portions 727. Part of a wiring that connects the earphone portion 727 and the control portion may be positioned inside the housing 721 or the mounting portion 723.

Similarly, the electronic appliance 800B illustrated in FIG. 18D includes earphone portions 827. For example, a structure can be employed in which the earphone portion 827 is connected to the control portion 824 by wire.

As described above, both the glasses-type device (e.g., the electronic appliance 700A and the electronic appliance 700B) and the goggles-type device (e.g., the electronic appliance 800A and the electronic appliance 800B) are preferable as the electronic appliance of one embodiment of the present invention.

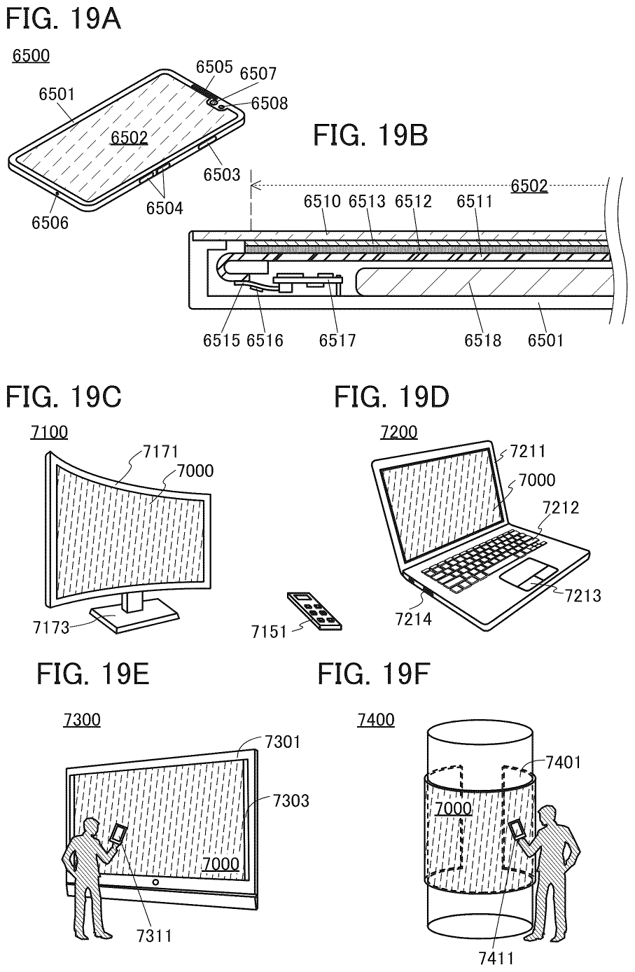

An electronic appliance 6500 illustrated in FIG. 19A is a portable information terminal device that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502. Thus, the electronic appliance can be highly reliable.

FIG. 19B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display apparatus of one embodiment of the present invention can be used in the display panel 6511. Thus, the electronic appliance can be extremely lightweight. Since the display panel 6511 is extremely thin, the battery 6518 with high capacity can be mounted without an increase in the thickness of the electronic appliance. Moreover, part of the display panel 6511 is folded back so that a connection portion with the FPC 6515 is provided on the back side of the pixel portion, whereby the electronic appliance can have a narrow bezel.

FIG. 19C illustrates an example of a television device. In a television device 7100, a display portion 7000 is incorporated in a housing 7171. Here, a structure in which the housing 7171 is supported by a stand 7173 is illustrated.

The display apparatus of one embodiment of the present invention can be used in the display portion 7000. Thus, the electronic appliance can be highly reliable.

Operation of the television device 7100 illustrated in FIG. 19C can be performed with an operation switch provided in the housing 7171 and a separate remote controller 7151.

FIG. 19D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The display apparatus of one embodiment of the present invention can be used in the display portion 7000. Thus, the electronic appliance can be highly reliable.

FIG. 19E and FIG. 19F illustrate examples of digital signage.

Digital signage 7300 illustrated in FIG. 19E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 19F illustrates digital signage 7400 attached to a cylindrical pillar 7401. The digital signage 7400 includes the display portion 7000 provided along a curved surface of the pillar 7401.

In FIG. 19E and FIG. 19F, the display apparatus of one embodiment of the present invention can be used in the display portions 7000. Thus, the electronic appliances can be highly reliable.

A larger area of the display portion 7000 can increase the amount of information that can be provided at a time. The display portion 7000 having a larger area attracts more attention, so that the effectiveness of the advertisement can be increased, for example.

As illustrated in FIG. 19E and FIG. 19F, it is preferable that the digital signage 7300 or the digital signage 7400 can work with an information terminal device 7311 or an information terminal device 7411, such as a smartphone that a user has, through wireless communication.

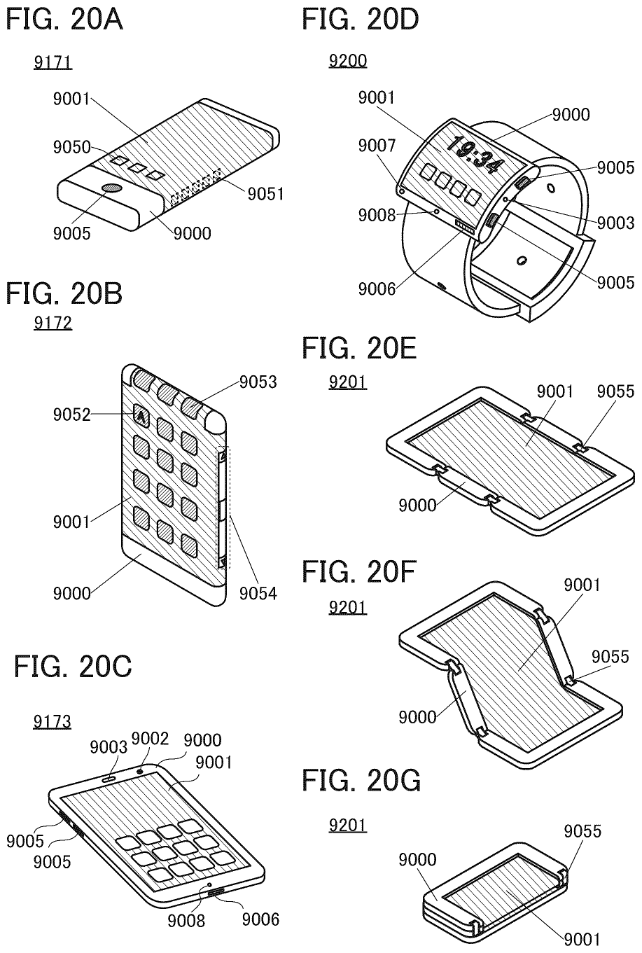

Electronic appliances illustrated in FIG. 20A to FIG. 20G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic appliances illustrated in FIG. 20A to FIG. 20G have a variety of functions. For example, the electronic appliances can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium.

The electronic appliances in FIG. 20A to FIG. 20G are described in detail below.

FIG. 20A is a perspective view illustrating a portable information terminal 9171. The portable information terminal 9171 can be used as a smartphone, for example. Note that the portable information terminal 9171 may include the speaker 9003, the connection terminal 9006, the sensor 9007, or the like. The portable information terminal 9171 can display text and image information on its plurality of surfaces. FIG. 20A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 20B is a perspective view illustrating a portable information terminal 9172. The portable information terminal 9172 has a function of displaying information on three or more surfaces of the display portion 9001. Here, information 9052, information 9053, and information 9054 are displayed on different surfaces. For example, the user of the portable information terminal 9172 can check the information 9053 displayed such that it can be seen from above the portable information terminal 9172, with the portable information terminal 9172 put in a breast pocket of his/her clothes.

FIG. 20C is a perspective view illustrating a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface thereof.

FIG. 20D is a perspective view illustrating a watch-type portable information terminal 9200. The portable information terminal 9200 can be used as a Smartwatch (registered trademark), for example. The display surface of the display portion 9001 is curved, and display can be performed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 20E to FIG. 20G are perspective views illustrating a foldable portable information terminal 9201. FIG. 20E is a perspective view of an opened state of the portable information terminal 9201, FIG. 20G is a perspective view of a folded state thereof, and FIG. 20F is a perspective view of a state in the middle of change from one of FIG. 20E and FIG. 20G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature of greater than or equal to 0.1 mm and less than or equal to 150 mm, for example.

This embodiment can be combined as appropriate with the other embodiments or the examples. In this specification, in the case where a plurality of structure examples are shown in one embodiment, the structure examples can be combined as appropriate.

### Example 1

Described in this example are specific methods for fabricating a light-emitting device 1 of one embodiment of the present invention, and a comparative light-emitting device 1-1 to a comparative light-emitting device 1-3, and characteristics of the light-emitting devices. Structural formulae of compounds mainly used in this example are shown below.

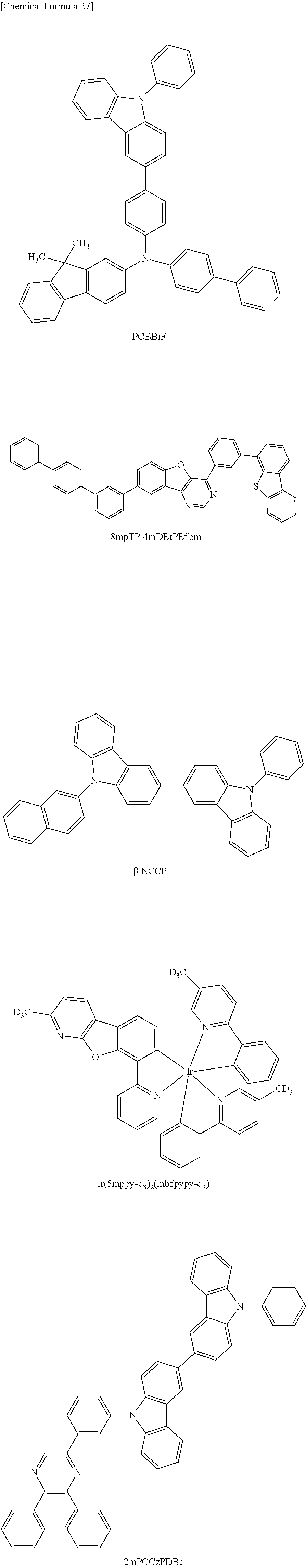

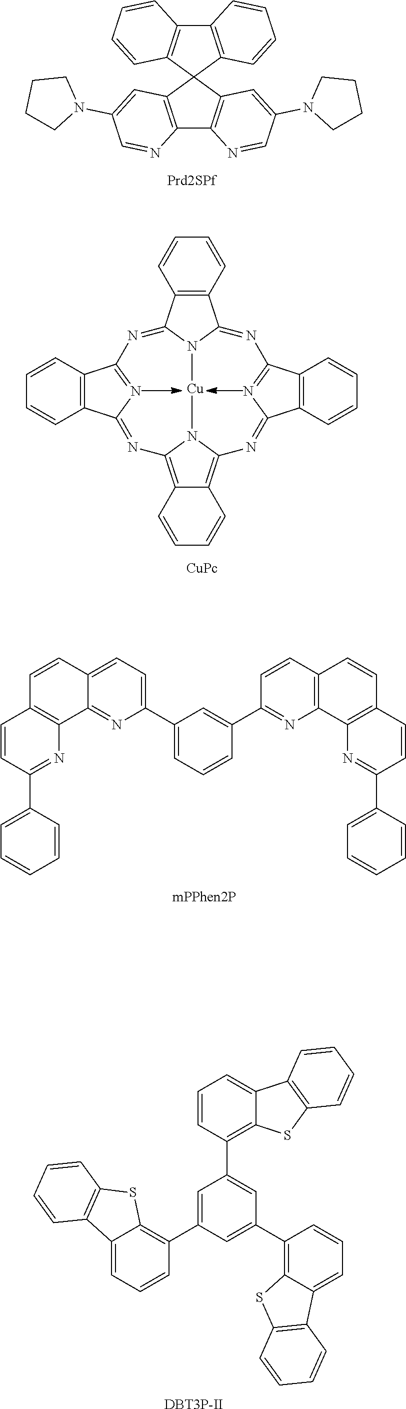

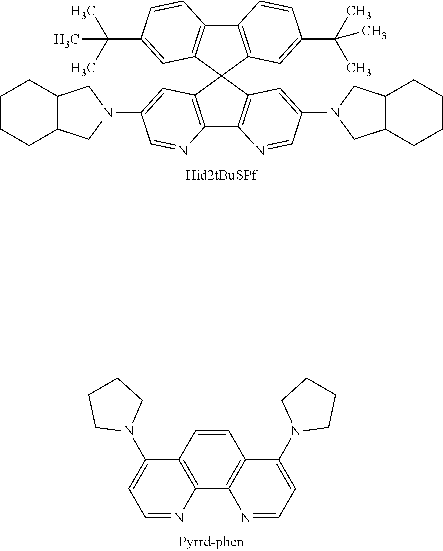 [SMILES: CC(C)(C)c1ccc2c(c1)C1(c3cc(C(C)(C)C)ccc3-2)c2cc(N3CC4CCCCC4C3)cnc2-c2ncc(N3CC4CCCCC4C3)cc21 ; c1cc(N2CCCC2)c2ccc3c(N4CCCC4)ccnc3c2n1]

### (Method for Fabricating Light-Emitting Device 1)

First, 100-nm-thick silver (Ag) as a reflective electrode and 85-nm-thick indium tin oxide containing silicon oxide (ITSO) as a transparent electrode were stacked over a glass substrate sequentially from the substrate side by a sputtering method, whereby the first electrode 101 with a size of 2 mm×2 mm was formed. Note that the transparent electrode functions as an anode, and the transparent electrode and the reflective electrode can be collectively regarded as the first electrode 101.

Next, in pretreatment for forming the light-emitting device over the substrate, a surface of the substrate was washed with water and baking was performed at 200 °C for one hour.

After that, the substrate was transferred into a vacuum evaporation apparatus in which the pressure was reduced to approximately 1×10⁻⁴ Pa, vacuum baking was performed at 170 °C for 30 minutes in a heating chamber of the vacuum evaporation apparatus, and then the substrate was cooled down for approximately 30 minutes.

Then, the substrate was fixed to a substrate holder provided in the vacuum evaporation apparatus such that the surface over which the first electrode 101 was formed faced downward. Over the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron-acceptor material with a molecular weight of 672 (OCHD-003) were deposited by co-evaporation to a thickness of 10 nm such that the weight ratio of PCBBiF to OCHD-003 was 1:0.03, whereby a hole-injection layer 111 was formed.

Over the hole-injection layer 111, PCBBiF was deposited by evaporation to a thickness of 80 nm, whereby a first hole-transport layer was formed.

Then, over the first hole-transport layer, the first light-emitting layer was formed by co-evaporation of 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm) represented by Structural Formula (ii) above, 9-(2-naphthyl)-9′-phenyl-9H,9′H-3,3′-bicarbazole (abbreviation: PNCCP) represented by Structural Formula (iii) above, and [2-d3-methyl-8-(2-pyridinyl-kN)benzofuro[2,3-b]pyridine-κC]bis[2-(5-d₃-methyl-2-pyridinyl-kN²)phenyl-κC]iridium(III) (abbreviation: Ir(5mppy-d₃)₂(mbfpypy-d₃)) represented by Structural Formula (iv) above to a thickness of 40 nm at the weight ratio of 0.5:0.5:0.1 (=8mpTP-4mDBtPBfpm:βNCCP:Ir(5mppy-d₃)₂(mbfpypy-d₃)).

After that, 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (v) above was deposited by evaporation to a thickness of 10 nm, whereby a first electron-transport layer was formed.

After the first electron-transport layer was formed, 2,2′-(1,3-phenylene)bis(9-phenyl-1,10-phenanthroline) (abbreviation: mPPhen2P) represented by Structural Formula (vi) above and 1-(2′,7′-di-tert-butyl-9,9′-spirobi[9H-fluoren]-2-yl)-1,3,4,6,7,8-hexahydro-2H-pyrimido[1,2-a]pyrimidine (abbreviation: 2′,7′tBu-2hppSF) represented by Structural Formula (vii) above were deposited by co-evaporation to a thickness of 5 nm at the weight ratio of 1:1 (=mPPhen2P:2′,7′tBu-2hppSF) to form a first layer (DLL); mPPhen2P was deposited by evaporation to a thickness of 2 nm to form a second layer (ISL); and PCBBiF and OCHD-003 were deposited by co-evaporation to a thickness of 10 nm at the weight ratio of 1:0.15 (=PCBBiF:OCHD-003) to form a third layer (P-type CGL). In this manner, an intermediate layer was formed.

Next, over the intermediate layer, PCBBiF was deposited by evaporation to a thickness of 55 nm, whereby a second hole-transport layer was formed.

Over the second hole-transport layer, 8mpTP-4mDBtPBfpm, PNCCP, and Ir(5mppy-d₃)₂(mbfpypy-d₃) were deposited by co-evaporation to a thickness of 40 nm at the weight ratio of 0.5:0.5:0.1 (=8mpTP-4mDBtPBfpm:PNCCP:Ir(5mppy-d₃)₂(mbfpypy-d₃)), whereby a second light-emitting layer was formed.

After that, 2mPCCzPDBq was deposited by evaporation to a thickness of 20 nm and mPPhen2P was further deposited by evaporation to a thickness of 20 nm, whereby a second electron-transport layer was formed.

After that, lithium fluoride (LiF) and ytterbium (Yb) were deposited by co-evaporation to a thickness of 1.5 nm such that the volume ratio of LiF to Yb was 1:0.5, and then, silver (Ag) and magnesium (Mg) were deposited by co-evaporation to a thickness of 15 nm such that the volume ratio of Ag to Mg was 1:0.1 to form the second electrode 102. Over the second electrode 102, 4,4′,4″-(benzene-1,3,5-triyl)tri(dibenzothiophene) (abbreviation: DBT3P-II) represented by Structural Formula (viii) above was deposited to a thickness of 70 nm as a cap layer to improve light extraction efficiency.

The light-emitting device was sealed using a glass substrate in a glove box containing a nitrogen atmosphere so as not to be exposed to atmospheric air (a UV curable sealing material was applied to surround the elements, only the sealing material was irradiated with UV while the light-emitting device was prevented from being irradiated with the UV, and heat treatment was performed at 80 °C under an atmospheric pressure for one hour), so that the light-emitting device 1 was formed.

### (Method for Fabricating Comparative Light-Emitting Device 1-1)

The comparative light-emitting device 1-1 was fabricated in a manner similar to that of the light-emitting device 1 except that the second layer (ISL) in the light-emitting device 1 was not formed.

### (Method for Fabricating Comparative Light-Emitting Device 1-2)

The comparative light-emitting device 1-2 was fabricated in a manner similar to that of the light-emitting device 1 except that the material contained in the second layer (ISL) in the light-emitting device 1 was replaced by 3,4,9,10-perylenetetracarboxyl-bis-benzimidazole (abbreviation: PTCBI) represented by Structural Formula (ix) above.

### (Method for Fabricating Comparative Light-Emitting Device 1-3)

The comparative light-emitting device 1 was fabricated in a manner similar to that of the light-emitting device 1 except that the material contained in the second layer (ISL) in the light-emitting device 1 was replaced by zinc phthalocyanine (abbreviation: ZnPc) represented by Structural Formula (x) above.

The device structures of the light-emitting device 1 and the comparative light-emitting device 1-1 to the comparative light-emitting device 1-3 are listed below.

TABLE 2

| Thickness | Light-emitting | Comparative light-emitting device | | |
|---|---|---|---|---|
| (nm) | device 1 | 1-1 | 1-2 | 1-3 |

| Cap layer | | 70 | DBT3P-II |
|---|---|---|---|
| Second electrode | | 15 | Ag:Mg (1:0.1) |
| | | 1.5 | LiF:Yb (1:0.5) |
| Second electron- | 2 | 20 | mPPhen2P |
| transport layer | 1 | 20 | 2mPCCzPDBq |

| Second light-emitting layer | | 40 | 8mpTP-4mDBtPBfpm:βNCCP:Ir(5mppy-d₃)₂(mbfpypy-d₃) | | | |
|---|---|---|---|---|---|---|
| | | | (0.5:0.5:0.1) | | | |
| Second hole-transport layer | | 55 | PCBBiF | | | |
| Intermediate | Third layer | 10 | PCBBiF:OCHD-003 (1:0.15) | | | |
| layer | Second layer | 2 | mPPhen2P | — | PTCBI | ZnPc |

| | | |
|---|---|---|
| First layer | 5 | mPPhen2P:2′,7′tBu-2hppSF (1:1) |

| First electron-transport layer | | 10 | 2mPCCzPDBq |
|---|---|---|---|
| First light-emitting layer | | 40 | 8mpTP-4mDBtPBfpm:βNCCP:Ir(5mppy-d₃)₂(mbfpypy-d₃) |
| | | | (0.5:0.5:0.1) |
| First hole-transport layer | | 80 | PCBBiF |
| Hole-injection layer | | 10 | PCBBiF:OCHD-003 (1:0.03) |
| First electrode | Transparent electrode | 85 | ITSO |
| | Reflective electrode | 100 | Ag |

The HOMO levels and the LUMO levels of the compounds used in the first layer (DLL) and the second layer (ISL) in the light-emitting device 1 and the comparative light-emitting device 1-1 to the comparative light-emitting device 1-3 are listed below.

TABLE 3

| | HOMO level | LUMO level |
|---|---|---|
| | (eV) | (eV) |
| mPPhen2P | — | −2.71 |
| PTCBI | — | −4.02 |
| ZnPc | −5.16 | −3.67 |
| 2′7′tBu-2hppSF | −5.30 | −1.89 |

The values of the HOMO levels and the LUMO levels were obtained by cyclic voltammetry (CV) measurement.

In the cyclic voltammetry (CV) measurement, the values (E) of the HOMO levels and the LUMO levels were calculated on the basis of an oxidation peak potential (Eₚₐ) and a reduction peak potential (E_{pc}), which are obtained by changing the potential of a working electrode with respect to a reference electrode. In the measurement, a HOMO level and a LUMO level were obtained by potential scanning in positive direction and potential scanning in negative direction, respectively. The scanning speed in the measurement was 0.1 V/sec.

Specifically, a standard oxidation-reduction potential (Eₒ) (=(Eₚₐ+E_{pc})/2) was calculated from an oxidation peak potential (Eₚₐ) and a reduction peak potential (E_{pc}), which were obtained by the cyclic voltammogram of a material. Then, the standard oxidation-reduction potential (Eₒ) was subtracted from the potential energy (Eₓ) of the reference electrode with respect to a vacuum level, whereby the value (E) (=Eₓ−Eₒ) of each of a HOMO level and a LUMO level were obtained.

Note that the reversible oxidation-reduction wave was obtained in the above case; in the case where an irreversible oxidation-reduction wave was obtained, the HOMO level was calculated as follows: a value obtained by subtracting a predetermined value (0.1 eV) from an oxidation peak potential (Eₚₐ) was assumed to be a reduction peak potential (E_{pc}), and a standard oxidation-reduction potential (Eₒ) was calculated to one decimal place. The LUMO level was calculated as follows: a value obtained by adding a predetermined value (0.1 eV) to a reduction peak potential (E_{pc}) was assumed to be an oxidation peak potential (Eₚₐ), and a standard oxidation-reduction potential (Eₒ) was calculated to one decimal place.

Note that the oxidation peak potentials of mPPhen2P and PTCBI were not observed, and the HOMO levels thereof were found to be as low as approximately −6.0 eV.

The layer of mmPPhen2P: 2′,7′tBu-2hppSF=1:1 formed as the first layer in each of the light-emitting device 1 and the comparative light-emitting device 1-1 to the comparative light-emitting device 1-3 is a layer blocking holes as described in Embodiment 1 with reference to FIG. 29. Furthermore, 2′,7′tBu-2hppSF has an acid dissociation constant pKa of 14.18 and is an organic compound having strong basicity with a pKa of 8 or more.

When an electron spin resonance spectrum of a thin film of mPPhen2P and 2′,7′tBu-2hppSF that was co-evaporated to a thickness of 100 nm over a quartz substrate at the weight ratio of 1:1 (mPPhen2P:2′,7′tBu-2hppSF) was measured, a signal was not observed at a g-factor of around 2.00, revealing that the spin density was lower than 1×10¹⁶ spins/cm³, which is the detection limit. Note that measurements of electron spin resonance spectra using an ESR method were performed with an electron spin resonance measuring device E500 (produced by Bulker Corporation). The measurements were performed at room temperature under the conditions where the resonance frequency was 9.56 GHz, the output power was 1 mW, the modulated magnetic field was 50 mT, the modulation width was 0.5 mT, the time constant was 0.04 s, and the sweep time was 1 min. This means that 2′,7′tBu-2hppSF does not exhibit an electron-donating property with respect to mPPhen2P. In other words, the first layer in the intermediate layer in each of the light-emitting device 1 and the comparative light-emitting device 1-1 to the comparative light-emitting device 1-3 is a layer that has a spin density lower than 1×10¹⁶ spins/cm³ and does not generate charge.

The third layer is a layer including PCBBiF, which is an organic compound having a hole-transport property, and OCHD-003 exhibiting an electron-accepting property and is a charge-generation layer in which charge separation occurs by voltage application.

When an electron spin resonance spectrum of a thin film of PCBBiF and OCHD-003 that was co-evaporated to a thickness of 100 nm over a quartz substrate at the weight ratio of 1:0.1 (PCBBiF:OCHD-003) was measured, a signal was observed at ag-factor of around 2.00, revealing that the spin density was lower than 5×10¹⁹ spins/cm³. Note that measurements of electron spin resonance spectra using an ESR method were performed with an electron spin resonance spectrometer JES FA300 (produced by JEOL Ltd.). The measurement was performed at room temperature under the conditions where the resonance frequency was 9.18 GHz, the output power was 1 mW, the modulated magnetic field was 50 mT, the modulation width was 0.5 mT, the time constant was 0.03 s, and the sweep time was 1 min. This shows that OCHD-003 has an electron-accepting property with respect to PCBBiF and the layer containing PCBBiF and OCHD-003 has a function of a charge-generation layer.

Thus, the light-emitting device 1 was revealed to be a light-emitting device in which the spin density of the first layer was lower than or equal to 1×10¹⁷ spins/cm³ and the absolute value of the difference between the LUMO level of the material (mPPhen2P) included in the second layer and the HOMO level of the first substance (2′,7′tBu-2hppSF) was 2.59 eV, which is greater than or equal to 2.10 eV. Furthermore, the LUMO level of the material (mPPhen2P) included in the second layer of the light-emitting device 1 was −2.71 eV, which is greater than −3.00 eV. In the light-emitting device 1, the HOMO level of the material (mPPhen2P) included in the second layer was found to be lower than the HOMO level of the first substance (2′,7′tBu-2hppSF). Also in the light-emitting device 1, the HOMO level of the material (mPPhen2P) included in the second layer was lower than the HOMO level (−5.36 eV) of the material having a hole-transport property (PCBBiF) in the third layer (P-type CGL). Thus, the light-emitting device 1 is the light-emitting device of one embodiment of the present invention.

According to ionization potential measurement (IP measurement), the measurement results of the HOMO levels of the thin films of mPPhen2P and PCBiF were −5.88 eV and −5.55 eV, respectively. The IP measurement was performed in atmospheric air using an atmospheric photoemission yield spectrometer (manufactured by Riken Keiki Co., Ltd., AC-3).

In the comparative light-emitting device 1, the second layer (ISL) was not formed. In the comparative light-emitting device 2, the absolute value of the difference between the LUMO level of the material (PTCBI) included in the second layer and the HOMO level of the first substance (2′,7′tBu-2hppSF) was 1.28 eV, which is less than or equal to 2.10 eV; and the LUMO level of the material (PTCBI) included in the second layer was lower than or equal to −4.02 eV, which is lower than or equal to −3.00 eV. In the comparative light-emitting device 3, the absolute value of the difference between the LUMO level of the material (ZnPc) included in the second layer and the HOMO level of the first substance (2′,7′tBu-2hppSF) was 1.63 eV, which is less than or equal to 2.10 eV; and the LUMO level of the material (ZnPc) included in the second layer was −3.67 eV, which is lower than or equal to −3.00 eV. As described above, it can be said that the comparative light-emitting device 1-1 to the comparative light-emitting device 1-3 each have the first layer with a spin density lower than or equal to 1×10¹⁷ spins/cm³ but are not the light-emitting devices of the present invention.

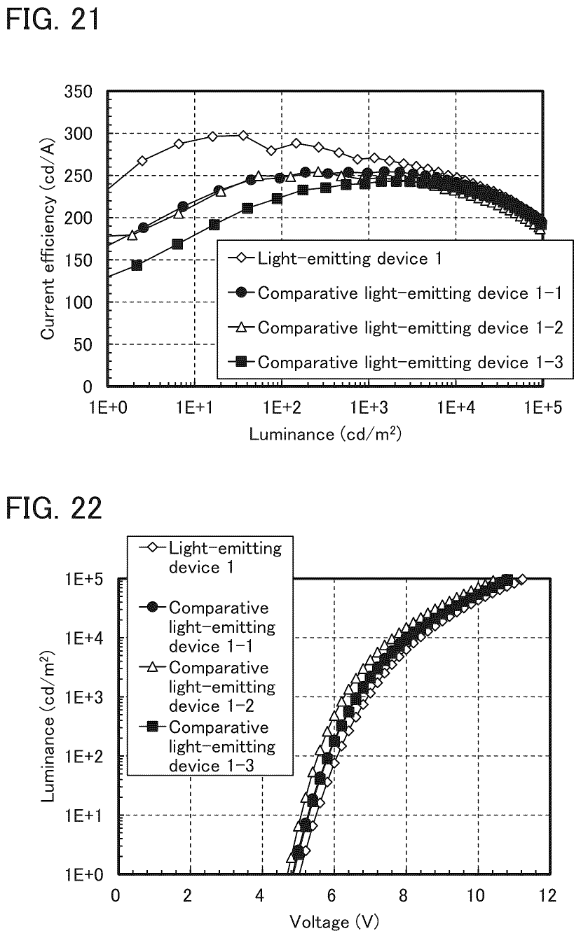

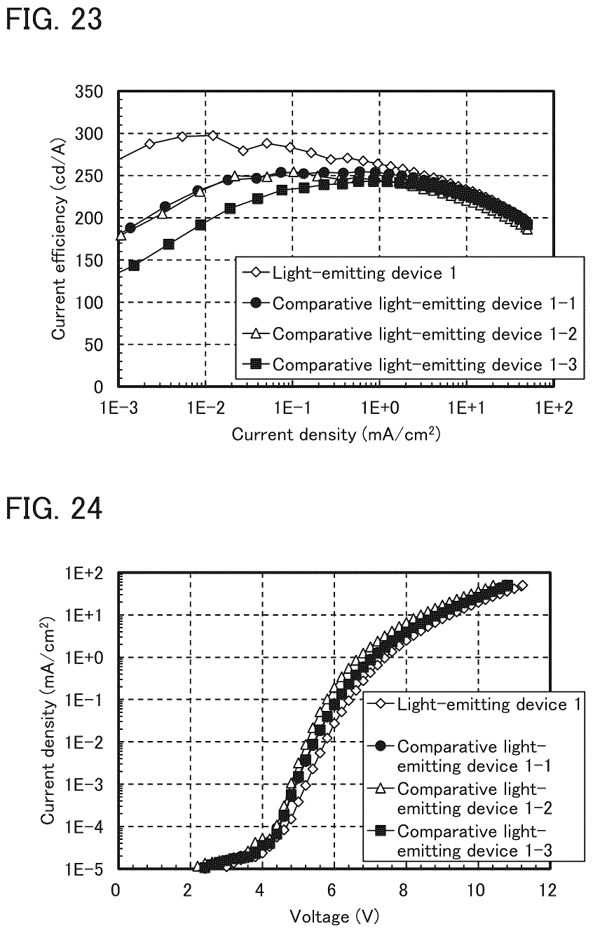

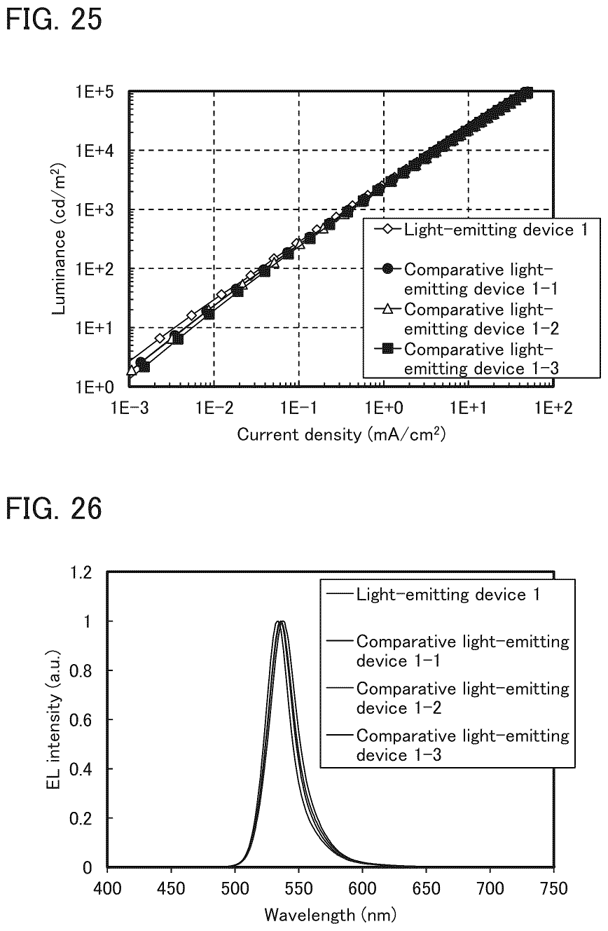

FIG. 21 shows the current efficiency-luminance characteristics of the light-emitting device 1 and the comparative light-emitting device 1-1 to the comparative light-emitting device 1-3. FIG. 22 shows the luminance-voltage characteristics thereof. FIG. 23 shows the current efficiency-current density characteristics thereof. FIG. 24 shows the current density-voltage characteristics thereof. FIG. 25 shows the luminance-current density characteristics thereof. FIG. 26 shows the electroluminescence spectra thereof. Table 4 shows the main characteristics at around 1000 cd/m². Note that the luminance, CIE chromaticity, and emission spectra were measured at normal temperature with a spectroradiometer (SR-UL1R manufactured by TOPCON CORPORATION).

TABLE 4

| | | | Current | | | Current |
|---|---|---|---|---|---|---|
| | Voltage | Current | density | Chromaticity | Chromaticity | efficiency |
| | (V) | (mA) | (mA/cm²) | x | y | (cd/A) |
| Light-emitting device1 | 7.0 | 0.02 | 0.4 | 0.27 | 0.71 | 270.8 |
| Comparative light-emitting device 1 | 6.6 | 0.02 | 0.4 | 0.24 | 0.73 | 252.9 |
| Comparative light-emitting device 2 | 6.2 | 0.01 | 0.3 | 0.26 | 0.72 | 245.6 |
| Comparative light-emitting device 3 | 6.6 | 0.02 | 0.4 | 0.25 | 0.72 | 240.2 |

FIG. 26 (spectra) shows that the light-emitting device 1 and the light-emitting device 1-1 to the comparative light-emitting device 1-3 each exhibit green light emission derived from Ir(5mppy-d₃)₂(mbfpypy-d₃). Furthermore, FIG. 21 (current efficiency-luminance characteristics) and FIG. 23 (current efficiency-current density characteristics) indicate that the light-emitting device 1 and the comparative light-emitting device 1-1 to the comparative light-emitting device 1-3 each exhibit favorable efficiency in a practical luminance region and function as a tandem light-emitting device. Note that it was found that the light-emitting device 1 in particular exhibited favorable emission efficiency even in a low-luminance region.

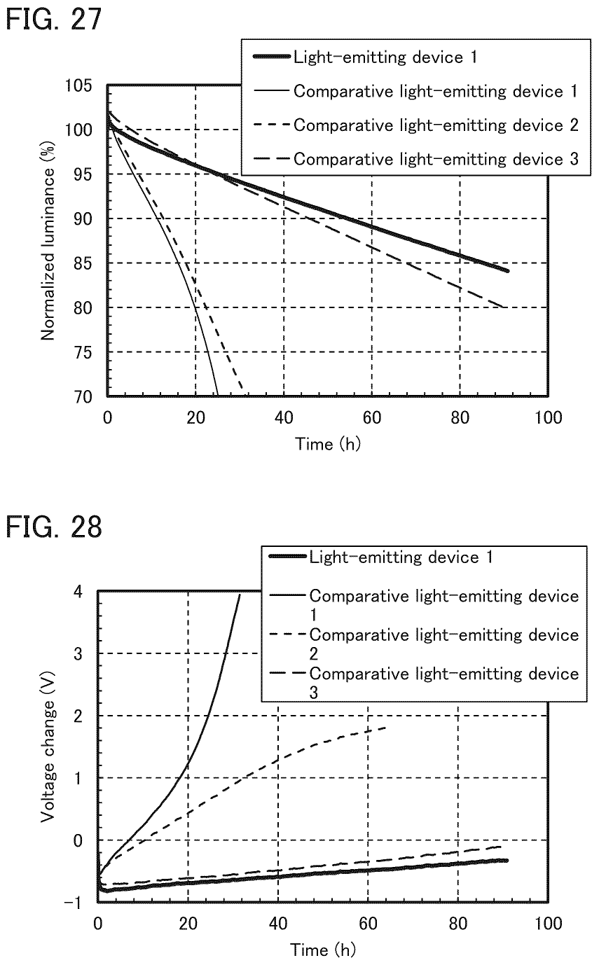

Regarding the light-emitting device 1 and the comparative light-emitting device 1-1 to the comparative light-emitting device 1-3, FIG. 27 shows the measurement results of the luminance changes over driving time when the devices were driven at a current density of 50 mA/cm², and FIG. 28 shows the measurement results of the voltage changes. As can be seen from FIG. 27 and FIG. 28, massive changes in luminance and voltage were exhibited in the comparative light-emitting device 1, in which the second layer was not formed, and the comparative light-emitting device 2, in which the material (PTCBI) with a LUMO level as deep as −4.02 eV was used as the material included in the second layer (ISL). The comparative light-emitting device 1-3, in which the material (ZuPc) with a LUMO level of −3.67 was used as the material included in the second layer (ISL), appears to exhibit changes in voltage and luminance equivalent to those of the light-emitting device 1; however, the comparative light-emitting device 1-3 has an increase in luminance at the start of driving and a large slope of long-term decay, which indicates that the light-emitting device 1 has higher reliability.

The above demonstrates that using a material with a high LUMO level to form the second layer in the intermediate layer results in improved reliability. Furthermore, emission efficiency was also found to be improved.

Thus, the use of the structure of one embodiment of the present invention was able to provide the tandem light-emitting devices having favorable characteristics, i.e., low drive voltage and high reliability and/or high emission efficiency.

### Example 2

Described in this example are specific methods for fabricating a light-emitting device 2-1 and a light-emitting device 2-2 of one embodiment of the present invention and a comparative light-emitting device 2, and characteristics of the light-emitting devices. Structural formulae of compounds mainly used in this example are shown below.

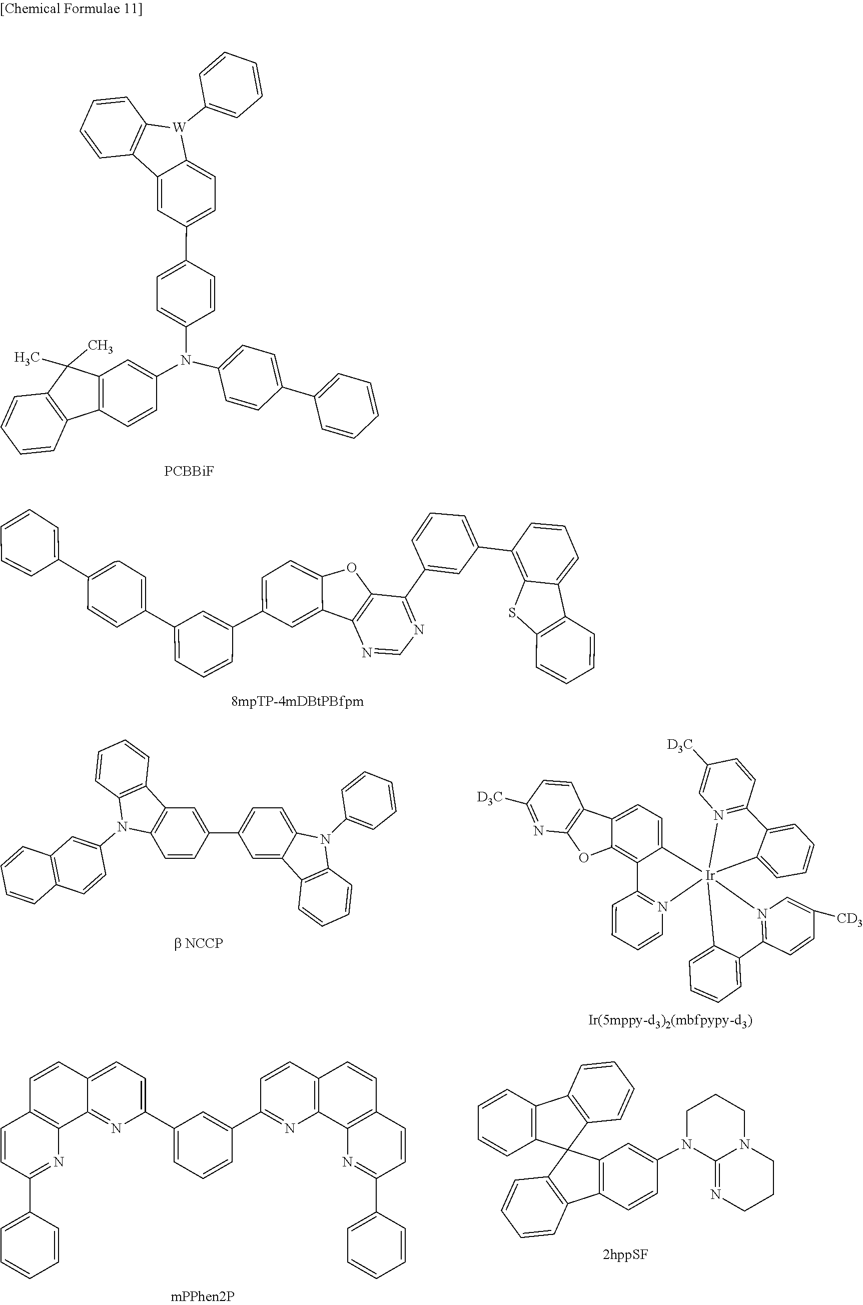

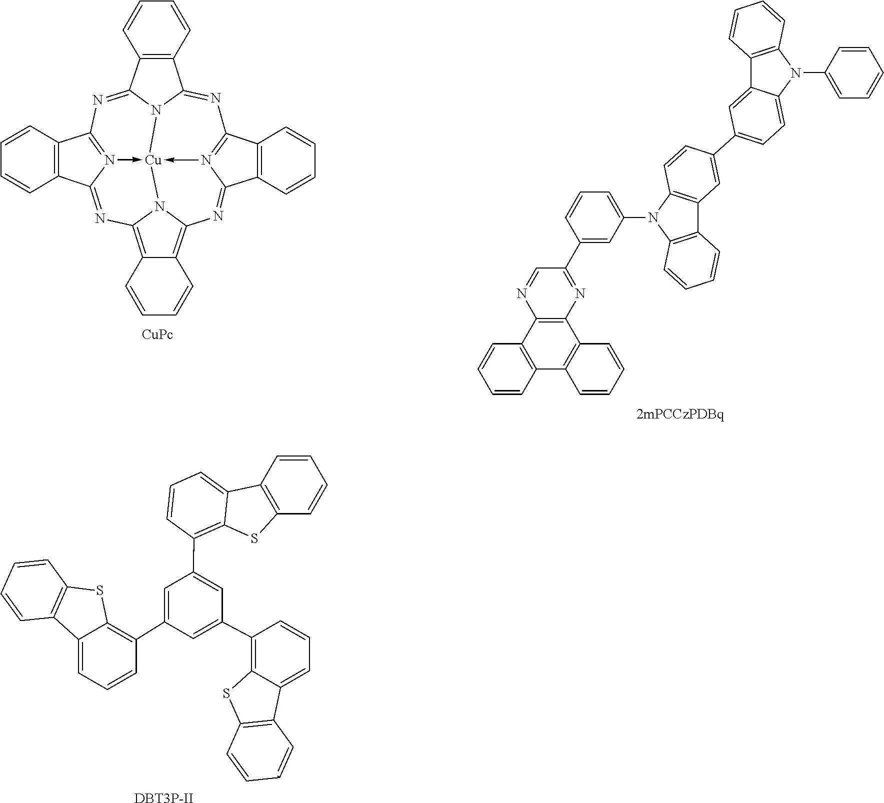

### (Method for Fabricating Light-Emitting Device 2-1)

First, 100-nm-thick silver (Ag) as a reflective electrode and 85-nm-thick indium tin oxide containing silicon oxide (ITSO) as a transparent electrode were stacked over a glass substrate sequentially from the substrate side by a sputtering method, whereby the first electrode 101 with a size of 2 mm×2 mm was formed. Note that the transparent electrode functions as an anode, and the transparent electrode and the reflective electrode can be collectively regarded as the first electrode 101.

Next, in pretreatment for forming the light-emitting device over the substrate, a surface of the substrate was washed with water and baking was performed at 200 °C for one hour.

After that, the substrate was transferred into a vacuum evaporation apparatus in which the pressure was reduced to approximately 1×10⁻⁴ Pa, vacuum baking was performed at 170 °C for 30 minutes in a heating chamber of the vacuum evaporation apparatus, and then the substrate was cooled down for approximately 30 minutes.

Then, the substrate was fixed to a substrate holder provided in the vacuum evaporation apparatus such that the surface over which the first electrode 101 was formed faced downward. Over the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron-acceptor material with a molecular weight of 672 (OCHD-003) were deposited by co-evaporation to a thickness of 10 nm such that the weight ratio of PCBBiF to OCHD-003 was 1:0.03, whereby a hole-injection layer 111 was formed.

Over the hole-injection layer 111, PCBBiF was deposited by evaporation to a thickness of 90 nm, whereby a first hole-transport layer was formed.

Then, over the first hole-transport layer, the first light-emitting layer was formed by co-evaporation of 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm) represented by Structural Formula (ii) above, 9-(2-naphthyl)-9′-phenyl-9H,9′H-3,3′-bicarbazole (abbreviation: PNCCP) represented by Structural Formula (iii) above, and [2-d3-methyl-8-(2-pyridinyl-kN)benzofuro[2,3-b]pyridine-κC]bis[2-(5-d3-methyl-2-pyridinyl-kN²)phenyl-κC]iridium(III) (abbreviation: Ir(5mppy-d₃)₂(mbfpypy-d₃)) represented by Structural Formula (iv) above to a thickness of 40 nm at the weight ratio of 0.5:0.5:0.1 (=8mpTP-4mDBtPBfpm:βNCCP:Ir(5mppy-d₃)₂(mbfpypy-d₃)).

After that, 3,6-bis(diphenylamino)-9-[4-(4,6-diphenyl-1,3,5-triazin-2-yl)phenyl]-9H-carbazole (abbreviation: DACT-II) represented by Structural Formula (xi) above was deposited by evaporation to a thickness of 10 nm, whereby a first electron-transport layer was formed.

After the first electron-transport layer was formed, N-phenyl-2-[4-(dibenzothiophen-4-yl)phenyl]benzimidazole (abbreviation: DBTBIm-II) represented by Structural Formula (xii) above and 1-(9,9′-spirobi[9H-fluoren]-2-yl)-1,3,4,6,7,8-hexahydro-2H-pyrimido[1,2-a]pyrimidine (abbreviation: 2hppSF) represented by Structural Formula (xiii) above were deposited by co-evaporation to a thickness of 8 nm at the weight ratio of 1:1 (=DBTBIm-II:2hppSF) to form a first layer (DLL); mPPhen2P was deposited by evaporation to a thickness of 2 nm to form a second layer (ISL); and PCBBiF and OCHD-003 were deposited by co-evaporation to a thickness of 10 nm at the weight ratio of 1:0.15 (=PCBBiF:OCHD-003) to form a third layer (P-type CGL). In this manner, an intermediate layer was formed.

Next, over the intermediate layer, PCBBiF was deposited by evaporation to a thickness of 55 nm, whereby a second hole-transport layer was formed.

Over the second hole-transport layer, 8mpTP-4mDBtPBfpm, βNCCP, and Ir(5mppy-d₃)₂(mbfpypy-d₃) were deposited by co-evaporation to a thickness of 40 nm at the weight ratio of 0.5:0.5:0.1 (=8mpTP-4mDBtPBfpm:βNCCP:Ir(5mppy-d₃)₂(mbfpypy-d₃)), whereby a second light-emitting layer was formed.

After that, 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (v) above was deposited by evaporation to a thickness of 20 nm and mPPhen2P was further deposited by evaporation to a thickness of 20 nm, whereby a second electron-transport layer was formed.

After that, lithium fluoride (LiF) and ytterbium (Yb) were deposited by co-evaporation to a thickness of 1.5 nm such that the volume ratio of LiF to Yb was 1:0.5, and then, silver (Ag) and magnesium (Mg) were deposited by co-evaporation to a thickness of 15 nm such that the volume ratio of Ag to Mg was 1:0.1 to form the second electrode 102. Over the second electrode 102, 4,4′,4″-(benzene-1,3,5-triyl)tri(dibenzothiophene) (abbreviation: DBT3P-II) represented by Structural Formula (viii) above was deposited to a thickness of 70 nm as a cap layer to improve light extraction efficiency.

The light-emitting device was sealed using a glass substrate in a glove box containing a nitrogen atmosphere so as not to be exposed to atmospheric air (a UV curable sealing material was applied to surround the elements, only the sealing material was irradiated with UV while the light-emitting device was prevented from being irradiated with the UV, and heat treatment was performed at 80 °C under an atmospheric pressure for one hour), so that the light-emitting device 2-1 was formed.

### (Fabrication Method of Light-Emitting Device 2-2)

The light-emitting device 2-2 was fabricated in a manner similar to that for the light-emitting device 2-1 except that the material of the second layer (ISL) included in the light-emitting device 2-1 was replaced with DBTBIm-II.

### (Method for Fabricating Comparative Light-Emitting Device 2)

The comparative light-emitting device 2 was fabricated in a manner similar to that of the light-emitting device 2-1 except that the material contained in the second layer (ISL) in the light-emitting device 2-1 was replaced by zinc phthalocyanine (abbreviation: ZnPc) represented by Structural Formula (x) above.

The device structures of the light-emitting device 2-1, the light-emitting device 2-2, and the comparative light-emitting device 2 are listed below.

TABLE 5

| | | | | | Compar- |
|---|---|---|---|---|---|
| | | | | | ative |
| | | | | | light- |
| | | Thick- | Light-emitting | | emitting |
| | | ness | device | | device |
| | | (nm) | 2-1 | 2-2 | 2 |
| Cap layer | | 70 | DBT3P-II | | |
| Second electrode | | 15 | Ag:Mg (1:0.1) | | |
| | | 1.5 | LiF:Yb (1:0.5) | | |
| Second | 2 | 20 | mPPhen2P | | |
| electron- | 1 | 20 | 2mPCCzPDBq | | |
| transport | | | | | |
| layer | | | | | |
| Second light- | | 40 | 8mpTP- | | |
| emitting layer | | | 4mDBtPBfpm:βNCCP:Ir(5mppy- | | |
| | | | d₃)₂(mbfpypy-d₃) | | |
| | | | (0.5:0.5:0.1) | | |
| Second hole- | | 55 | PCBBiF | | |
| transport layer | | | | | |
| Intermediate | Third | 10 | PCBBiF:OCHD-003 | | |
| layer | layer | | (1:0.15) | | |
| | Second | 2 | mPPhen2P | DBTBIm- | ZnPc |
| | layer | | | II | |

| | First layer | 8 | DBTBIm-II:2hppSF |
|---|---|---|---|
| | | | (1:1) |
| First electron- | | 10 | DACT-II |
| transport layer | | | |
| First light- | | 40 | 8mpTP- |
| emitting layer | | | 4mDBtPBfpm:βNCCP:Ir(5mppy- |
| | | | d₃)₂(mbfpypy-d₃) |
| | | | (0.5:0.5:0.1) |
| First hole- | | 90 | PCBBiF |
| transport layer | | | |
| hole-injection layer | | 10 | PCBBiF:OCHD-003 |
| | | | (1:0.03) |
| First | Transparent | 85 | ITSO |
| electrode | electrode | | |
| | Reflective | 100 | Ag |
| | electrode | | |

The HOMO levels and the LUMO levels of the compounds used in the first layer (DLL) and the second layer (ISL) in the light-emitting device 2-1, the light-emitting device 2-2, and the comparative light-emitting device 2 are listed below.

TABLE 6

| | HOMO level | LUMO level |
|---|---|---|
| | (eV) | (eV) |
| mPPhen2P | — | −2.71 |
| DBTBIm-II | — | −2.52 |
| ZnPc | −5.16 | −3.67 |
| 2hppSF | −5.30 | — |

The values of the HOMO levels and the LUMO levels were obtained by cyclic voltammetry (CV) measurement.

In the cyclic voltammetry (CV) measurement, the values (E) of the HOMO levels and the LUMO levels were calculated on the basis of an oxidation peak potential (Eₚₐ) and a reduction peak potential (E_{pc}), which are obtained by changing the potential of a working electrode with respect to a reference electrode. In the measurement, a HOMO level and a LUMO level were obtained by potential scanning in positive direction and potential scanning in negative direction, respectively. The scanning speed in the measurement was 0.1 V/sec.

Specifically, a standard oxidation-reduction potential (Eₒ) (=(Eₚₐ+E_{pc})/2) was calculated from an oxidation peak potential (Eₚₐ) and a reduction peak potential (E_{pc}), which were obtained by the cyclic voltammogram of a material. Then, the standard oxidation-reduction potential (Eₒ) was subtracted from the potential energy (Eₓ) of the reference electrode with respect to a vacuum level, whereby the value (E) (=Eₓ−Eₒ) of each of a HOMO level and a LUMO level were obtained.

Note that the reversible oxidation-reduction wave was obtained in the above case; in the case where an irreversible oxidation-reduction wave was obtained, the HOMO level was calculated as follows: a value obtained by subtracting a predetermined value (0.1 eV) from an oxidation peak potential (Eₚₐ) was assumed to be a reduction peak potential (E_{pc}), and a standard oxidation-reduction potential (Eₒ) was calculated to one decimal place. The LUMO level was calculated as follows: a value obtained by adding a predetermined value (0.1 eV) to a reduction peak potential (E_{pc}) was assumed to be an oxidation peak potential (Eₚₐ), and a standard oxidation-reduction potential (Eₒ) was calculated to one decimal place.

Note that the oxidation peak potentials of mPPhen2P and DBTBIm-II were not observed, and the HOMO levels thereof were found to be lower than −6.0 eV.

A layer where DBTBIm-II:2hppSF=1:1 formed in each of the first layers of the light-emitting device 2-1, the light-emitting device 2-2, and the comparative light-emitting device 2 is a layer blocking holes. Furthermore, 2hppSF has an acid dissociation constant pKa of 13.95 and is an organic compound having strong basicity with a pKa of 8 or more.

When an electron spin resonance spectrum of a thin film of DBTBIm-II and 2hppSF that was co-evaporated to a thickness of 50 nm over a quartz substrate at the weight ratio of 1:1 (DBTBIm-II:2hppSF) was measured, a signal was not observed at a g-factor of around 2.00, revealing that the spin density was lower than 8×10¹⁶ spins/cm³, which is the detection limit. Note that measurements of electron spin resonance spectra using an ESR method were performed with an electron spin resonance measuring device E500 (produced by Bulker Corporation). The measurements were performed at room temperature under the conditions where the resonance frequency was 9.56 GHz, the output power was 1 mW, the modulated magnetic field was 50 mT, the modulation width was 0.5 mT, the time constant was 0.04 s, and the sweep time was 1 min. This means that 2hppSF does not exhibit an electron-donating property with respect to DBTBIm-II. In other words, the first layer in the intermediate layer in each of the light-emitting device 2-1, the light-emitting device 2-2, and the comparative light-emitting device 2 is a layer that has a spin density lower than or equal to 1×10¹⁷ spins/cm³ and does not generate charge.

The third layer is a layer including PCBBiF, which is an organic compound having a hole-transport property, and OCHD-003 exhibiting an electron-accepting property and is a charge-generation layer in which charge separation occurs by voltage application.

When an electron spin resonance spectrum of a thin film of PCBBiF and OCHD-003 that was co-evaporated to a thickness of 100 nm over a quartz substrate at the weight ratio of 1:0.1 (PCBBiF:OCHD-003) was measured, a signal was observed at ag-factor of around 2.00, revealing that the spin density was lower than 5×10¹⁹ spins/cm³. Note that measurements of electron spin resonance spectra using an ESR method were performed with an electron spin resonance spectrometer JES FA300 (produced by JEOL Ltd.). The measurement was performed at room temperature under the conditions where the resonance frequency was 9.18 GHz, the output power was 1 mW, the modulated magnetic field was 50 mT, the modulation width was 0.5 mT, the time constant was 0.03 s, and the sweep time was 1 min. This shows that OCHD-003 has an electron-accepting property with respect to PCBBiF and the layer containing PCBBiF and OCHD-003 has a function of a charge-generation layer.

Thus, the light-emitting device 2-1 was revealed to be a light-emitting device in which the spin density of the first layer was lower than or equal to 1×10¹⁷ spins/cm³ and the absolute value of the difference between the LUMO level of the material (mPPhen2P) included in the second layer and the HOMO level of the first substance (2hppSF) was 2.59 eV, which is greater than or equal to 2.10 eV. Furthermore, the LUMO level of the material (mPPhen2P) included in the second layer of the light-emitting device 2-1 was −2.71 eV, which is greater than −3.00 eV. In the light-emitting device 2-1, the HOMO level of the material (mPPhen2P) included in the second layer was found to be lower than the HOMO level of the first substance (2hppSF). Also in the light-emitting device 2-1, the HOMO level of the material (mPPhen2P) included in the second layer was lower than the HOMO level (−5.36 eV) of the material having a hole-transport property (PCBBiF) in the third layer (P-type CGL). Thus, the light-emitting device 2-1 is the light-emitting device of one embodiment of the present invention.

According to ionization potential measurement (IP measurement), the measurement results of the HOMO levels of the thin films of mPPhen2P and PCBBiF were −5.88 eV and −5.55 eV, respectively. The IP measurement was performed in atmospheric air using an atmospheric photoemission yield spectrometer (manufactured by Riken Keiki Co., Ltd., AC-3).

Thus, the light-emitting device 2-2 was revealed to be a light-emitting device in which the spin density of the first layer was lower than or equal to 1×10¹⁷ spins/cm³ and the absolute value of the difference between the LUMO level of the material (DBTBIm-II) included in the second layer and the HOMO level of the first substance (2hppSF) was 2.78 eV, which is greater than or equal to 2.10 eV. Furthermore, the LUMO level of the material (DBTBIm-II) included in the second layer of the light-emitting device 2-2 was −2.52 eV, which is greater than −3.00 eV. In the light-emitting device 2-2, the HOMO level of the material (DBTBIm-II) included in the second layer was found to be lower than the HOMO level of the first substance (2hppSF). Also in the light-emitting device 2-2, the HOMO level of the material (DBTBIm-II) included in the second layer was lower than the HOMO level (−5.36 eV) of the material having a hole-transport property (PCBBiF) in the third layer (P-type CGL). Thus, the light-emitting device 2-2 is the light-emitting device of one embodiment of the present invention.

According to ionization potential measurement (IP measurement), the measurement results of the HOMO levels of the thin films of DBTBIm-II and PCBBiF were −5.83 eV and −5.55 eV, respectively. The IP measurement was performed in atmospheric air using an atmospheric photoemission yield spectrometer (manufactured by Riken Keiki Co., Ltd., AC-3).

In the comparative light-emitting device 2, the absolute value of the difference between the LUMO level of the material (ZnPc) included in the second layer and the HOMO level of the first substance (2hppSF) was 1.63 eV, which is less than or equal to 2.10 eV; and the LUMO level of the material (ZnPc) included in the second layer was −3.67 eV, which is lower than or equal to −3.00 eV. As described above, it can be said that the comparative light-emitting device 2 has the first layer with a spin density lower than or equal to 1×10¹⁷ spins/cm³ but is not the light-emitting device of the present invention.

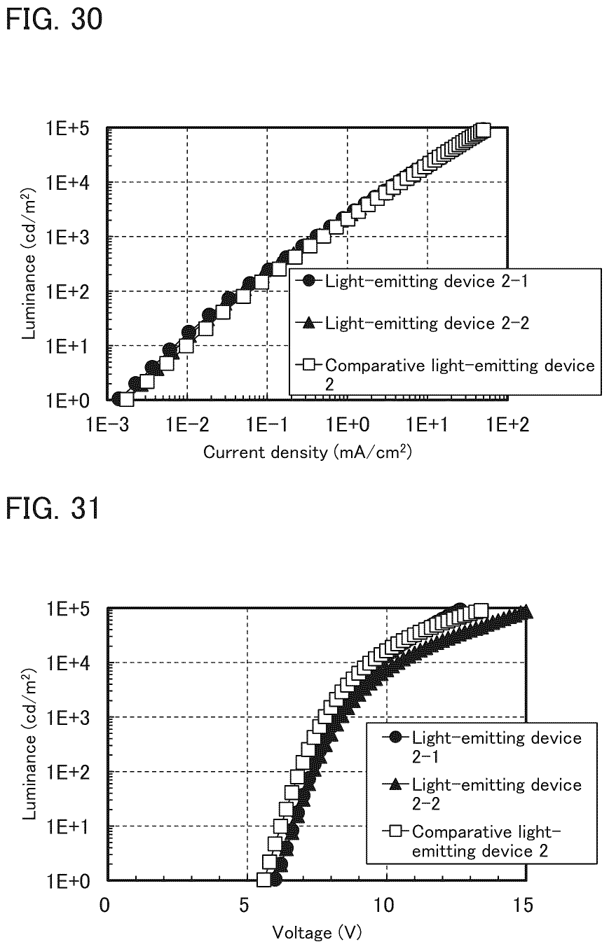

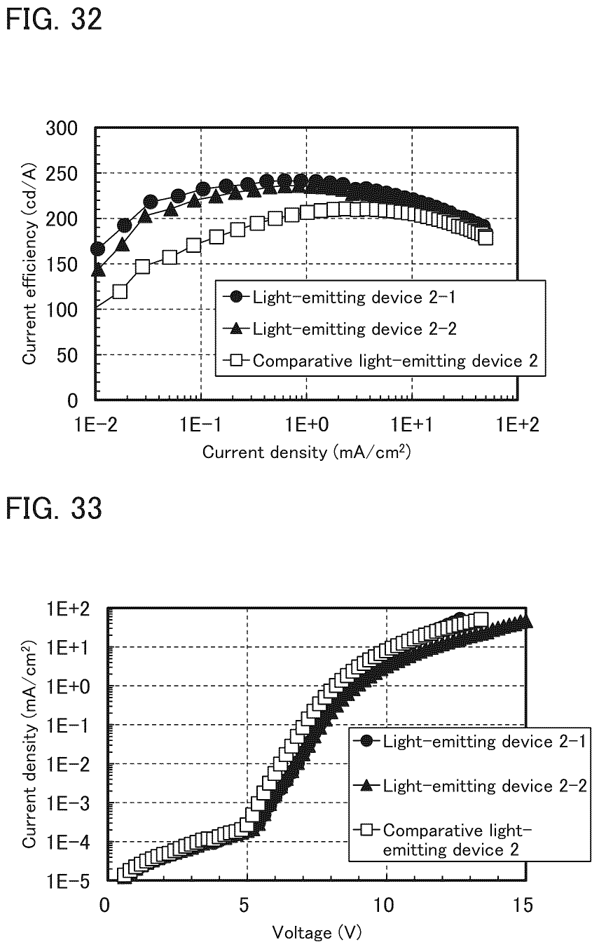

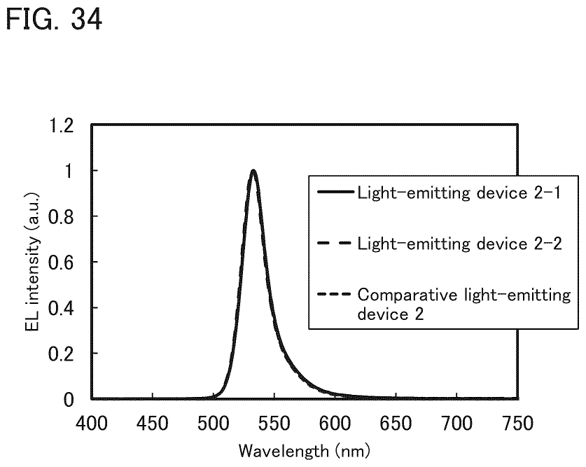

FIG. 30 shows the luminance-current density characteristics the light-emitting device 2-1, the light-emitting device 2-2, and the comparative light-emitting device 2. FIG. 31 shows the luminance-voltage density characteristics thereof. FIG. 32 shows the current efficiency-current density characteristics thereof. FIG. 33 shows the current density-voltage characteristics thereof. FIG. 34 shows the electroluminescence spectra thereof.

Table 7 shows the main characteristics at around 1000 cd/m². Note that the luminance, CIE chromaticity, and emission spectra were measured at normal temperature with a spectroradiometer (SR-UL1R manufactured by TOPCON CORPORATION).

TABLE 7

| | | | Current | | | Current |
|---|---|---|---|---|---|---|
| | Voltage | Current | density | Chromaticity | Chromaticity | efficiency |
| | (V) | (mA) | (mA/cm²) | x | y | (cd/A) |
| Light-emitting device 2-1 | 8.2 | 0.02 | 0.4 | 0.25 | 0.72 | 240.8 |
| Light-emitting device 2-2 | 8.4 | 0.02 | 0.5 | 0.25 | 0.72 | 234.6 |
| Comparative light-emitting device 2 | 7.8 | 0.02 | 0.5 | 0.25 | 0.72 | 199.7 |

FIG. 34 (electroluminescence spectra) shows that the light-emitting device 2-1, the light-emitting device 2-2, and the comparative light-emitting device 2 each exhibit green light emission derived from Ir(5mppy-d₃)₂(mbfpypy-d₃). Furthermore, FIG. 32 (current efficiency-current density characteristics) reveals that the light-emitting device 2-1, the light-emitting device 2-2, and the comparative light-emitting device 2 each exhibit high current efficiency and function as a tandem light-emitting device. In particular, the light-emitting devices device 2-1 and the light-emitting device 2-2 are found to exhibit higher current efficiency in a range from a low-current-density region to a high-current-density region than the comparative light-emitting device 2.

Thus, the use of the structure of one embodiment of the present invention was able to provide the tandem light-emitting devices having favorable characteristics, i.e., high emission efficiency.

### REFERENCE NUMERALS

100A: display apparatus, 100B: display apparatus, 100C: display apparatus, 100E: display apparatus, 100D: display apparatus, 100: insulator, 101c: first electrode, 101d: first electrode, 101B: first electrode, 101G: first electrode, 101R: first electrode, 101: first electrode, 102: second electrode, 103B: organic compound layer, 103Bf organic compound film, 103c: organic compound layer, 103d: organic compound layer, 103G: organic compound layer, 103Gf organic compound film, 103R: organic compound layer, 103Rf: organic compound film, 103: organic compound layer, 104: first EL layer, 104R: first EL layer, 104G: first EL layer, 104B: first EL layer, 105: second EL layer, 110B: subpixel, 110G: subpixel, 110R: subpixel, 110: subpixel, 111c: hole-injection layer, 111d: hole-injection layer, 111: hole-injection layer, 112: hole-transport layer, 112c_1: hole-transport layer, 112c_2: hole-transport layer, 112d_1: hole-transport layer, 112d_2: hole-transport layer, 112R: conductive layer, 112B: conductive layer, 113: light-emitting layer, 113c_1: light-emitting layer, 113c_2: light-emitting layer, 113d_1: light-emitting layer, 113d_2: light-emitting layer, 114: electron-transport layer, 114c_1: electron-transport layer, 114c_2: electron-transport layer, 114d_1: electron-transport layer, 114d_2: electron-transport layer, 115: electron-injection layer, 116: intermediate layer, 116c: intermediate layer, 116d: intermediate layer, 117: third layer, 117c: third layer, 117d: third layer, 118: second layer, 118c: second layer, 118d: second layer, 119: first layer, 119c: first layer, 119d: first layer, 120: substrate, 122: resin layer, 125f inorganic insulating film, 125: inorganic insulating layer, 126R: conductive layer, 126B: conductive layer, 127a: insulating layer, 127f insulating film, 127: insulating layer, 128: layer, 129R: conductive layer, 129B: conductive layer, 130B: light-emitting device, 130c: light-emitting device, 130d: light-emitting device, 130G: light-emitting device, 130R: light-emitting device, 130: light-emitting device, 131: protective layer, 132B: coloring layer, 132G: coloring layer, 132R: coloring layer, 140: connection portion, 141: region, 142: adhesive layer, 151B: conductive layer, 151C: conductive layer, 151f conductive film, 151G: conductive layer, 151R: conductive layer, 151: conductive layer, 152B: conductive layer, 152C: conductive layer, 152f conductive film, 152G: conductive layer, 152R: conductive layer, 152: conductive layer, 153: insulating layer, 155: common electrode, 156B: insulating layer, 156C: insulating layer, 156f insulating film, 156G: insulating layer, 156R: insulating layer, 156: insulating layer, 157: light-blocking layer, 158B: sacrificial layer, 158Bf sacrificial film, 158G: sacrificial layer, 158Gf sacrificial film, 158R: sacrificial layer, 158Rf sacrificial film, 159B: mask layer, 159Bf mask film, 159G: mask layer, 159Gf mask film, 159R: mask layer, 159Rf: mask film, 166: conductive layer, 171: insulating layer, 172: conductive layer, 173: insulating layer, 174: insulating layer, 175: insulating layer, 176: plug, 177: pixel portion, 178: pixel, 179: conductive layer, 190B: resist mask, 190G: resist mask, 190R: resist mask, 191: resist mask, 201: transistor, 204: connection portion, 205: transistor, 211: insulating layer, 213: insulating layer, 214: insulating layer, 215: insulating layer, 221: conductive layer, 222a: conductive layer, 222b: conductive layer, 223: conductive layer, 224B: conductive layer, 224C: conductive layer, 224G: conductive layer, 224R: conductive layer, 231: semiconductor layer, 240: capacitor, 241: conductive layer, 242: connection layer, 243: insulating layer, 245: conductive layer, 254: insulating layer, 255: insulating layer, 256: plug, 261: insulating layer, 271: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301: substrate, 310: transistor, 311: conductive layer, 312: low-resistance region, 313: insulating layer, 314: insulating layer, 315: element isolation layer, 351: substrate, 352: substrate, 353: FPC, 354: IC, 355: wiring, 356: circuit, 411: strongly basic material, 412: material having electron-transport property, 421: material included in ISL, 431: material having acceptor property, 432: material having hole-transport property, 501: first light-emitting unit, 501c: first light-emitting unit, 501d: first light-emitting unit, 502: second light-emitting unit, 502c: second light-emitting unit, 502d: second light-emitting unit, 700A: electronic appliance, 700B: electronic appliance, 721: housing, 723: wearing portion, 727: earphone portion, 750: earphone, 751: display panel, 753: optical member, 756: display region, 757: frame, 758: nose pad, 800A: electronic appliance, 800B: electronic appliance, 820: display portion, 821: housing, 822: communication portion, 823: wearing portion, 824: control portion, 825: image capturing portion, 827: earphone portion, 832: lens, 6500: electronic appliance, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7151: remote controller, 7171: housing, 7173: stand, 7200: notebook personal computer, 7211: housing, 7212: keyboard, 7213: pointing device, 7214: external connection port, 7300: digital signage, 7301: housing, 7303: speaker, 7311: information terminal device, 7400: digital signage, 7401: pillar, 7411: information terminal device, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9171: portable information terminal, 9172: portable information terminal, 9173: tablet terminal, 9200: portable information terminal, 9201: portable information terminal

1. A light-emitting device comprising:
a first electrode;
a second electrode; and
an organic compound layer between the first electrode and the second electrode,
wherein the organic compound layer comprises a first light-emitting unit, an intermediate layer, and a second light-emitting unit in this order from a first electrode side,
wherein the first light-emitting unit comprises a first light-emitting layer,
wherein the second light-emitting unit comprises a second light-emitting layer,
wherein the intermediate layer comprises a first layer, a second layer, and a third layer in contact with each other in this order from the first electrode side,
wherein the first layer comprises a first substance,
wherein a spin density of the first layer is lower than or equal to 1×10¹⁷ spins/cm³, and
wherein an absolute value of a difference between a LUMO level of a material included in the second layer and a HOMO level of the first substance is greater than or equal to 2.10 eV.

2. A light-emitting device comprising:
a first electrode;
a second electrode; and
an organic compound layer between the first electrode and the second electrode,
wherein the organic compound layer comprises a first light-emitting unit, an intermediate layer, and a second light-emitting unit in this order from a first electrode side,
wherein the first light-emitting unit comprises a first light-emitting layer,
wherein the second light-emitting unit comprises a second light-emitting layer,
wherein the intermediate layer comprises a first layer, a second layer, and a third layer in contact with each other in this order from the first electrode side,
wherein the first layer comprises a first substance,
wherein a spin density of the first layer is lower than or equal to 1×10¹⁷ spins/cm³, and
wherein a LUMO level of a material included in the second layer is higher than −3.00 eV.

3. The light-emitting device according to claim 2,
wherein the LUMO level of the material included in the second layer is lower than or equal to −2.00 eV.

4. The light-emitting device according to claim 1,
wherein the first layer further comprises a second substance, and
wherein the second substance is an organic compound having an electron-transport property.

5. The light-emitting device according to claim 1,
wherein an acid dissociation constant pKa of the first substance is higher than or equal to 8.

6. The light-emitting device according to claim 1,
wherein the first substance is an organic compound comprising any one of a pyrrolidine skeleton, a piperidine skeleton, and a hexahydropyrimydopyrimidine skeleton.

7. The light-emitting device according to claim 1,
wherein the first substance is an organic compound comprising a 1,3,4,6,7,8-hexahydro-2H-pyrimido[1,2-a]pyrimidine skeleton.

8. The light-emitting device according to claim 4,
wherein an absolute value of a difference between a LUMO level of the second substance and the LUMO level of the material included in the second layer is higher than or equal to 0.00 eV and lower than or equal to 0.30 eV.

9. The light-emitting device according to claim 4,
wherein the second substance is the same organic compound as the material included in the second layer.

10. The light-emitting device according to claim 1,
wherein the third layer comprises an organic compound having a hole-transport property and a material having an acceptor property.

11. The light-emitting device according to claim 1,
wherein a HOMO level of the material included in the second layer is lower than the HOMO level of the first substance.

12. The light-emitting device according to claim 10,
wherein a HOMO level of the material included in the second layer is lower than a HOMO level of the organic compound having a hole-transport property

13. The light-emitting device according to claim 2,
wherein the first layer further comprises a second substance, and
wherein the second substance is an organic compound having an electron-transport property.

14. The light-emitting device according to claim 2,
wherein an acid dissociation constant pKa of the first substance is higher than or equal to 8.

15. The light-emitting device according to claim 13,
wherein an absolute value of a difference between a LUMO level of the second substance and the LUMO level of the material included in the second layer is higher than or equal to 0.00 eV and lower than or equal to 0.30 eV.

16. The light-emitting device according to claim 2,
wherein the third layer comprises an organic compound having a hole-transport property and a material having an acceptor property.

17. A light-emitting device comprising:
a first electrode;
a second electrode; and
an organic compound layer between the first electrode and the second electrode,
wherein the organic compound layer comprises a first light-emitting unit, an intermediate layer, and a second light-emitting unit in this order from a first electrode side,
wherein the first light-emitting unit comprises a first light-emitting layer,
wherein the second light-emitting unit comprises a second light-emitting layer,
wherein the intermediate layer comprises a first layer, a second layer, and a third layer in contact with each other in this order from the first electrode side,
wherein the first layer comprises a first substance,
wherein an acid dissociation constant pKa of the first substance is higher than or equal to 8, and
wherein an absolute value of a difference between a LUMO level of a material included in the second layer and a HOMO level of the first substance is greater than or equal to 2.10 eV.

18. The light-emitting device according to claim 17,
wherein the first layer further comprises a second substance, and
wherein the second substance is an organic compound having an electron-transport property.

19. The light-emitting device according to claim 18,
wherein an absolute value of a difference between a LUMO level of the second substance and the LUMO level of the material included in the second layer is higher than or equal to 0.00 eV and lower than or equal to 0.30 eV.

20. The light-emitting device according to claim 17,
wherein the third layer comprises an organic compound having a hole-transport property and a material having an acceptor property.
